(19) United States
(12) Patent Application Publication
(10) Pub. No.: US 2024/0268102 A1
(43) Pub. Date: Aug. 8, 2024

(54) SEMICONDUCTOR DEVICE AND A METHOD OF MANUFACTURING THE SAME

(71) Applicant: Samsung Electronics Co., Ltd., Suwon-si (KR)

(72) Inventors: Kiseok LEE, Suwon-si (KR); Seung-Bo KO, Suwon-si (KR); Jongmin KIM, Suwon-si (KR); Hui-Jung KIM, Suwon-si (KR); SangJae PARK, Suwon-si (KR); Taejin PARK, Suwon-si (KR); Chan-Sic YOON, Suwon-si (KR); Myeong-Dong LEE, Suwon-si (KR); Hongjun LEE, Suwon-si (KR); Minju KANG, Suwon-si (KR); Keunnam KIM, Suwon-si (KR)

(73) Assignee: Samsung Electronics Co., Ltd., Suwon-si (KR)

(21) Appl. No.: 18/471,583

(22) Filed: Sep. 21, 2023

(30) Foreign Application Priority Data
Feb. 6, 2023 (KR) 10-2023-0015797

(51) Int. Cl. H10B 12/00

(52) U.S. Cl. CPC H10B 12/485; H10B 12/482; H10B 12/488

(57) ABSTRACT

A semiconductor device includes first and second active patterns extending in a first direction and arranged in a second direction intersecting the first direction, each of the first and second active patterns including first and second edge portions spaced apart from each other in the first direction, a first storage node pad and a first storage node contact sequentially provided on the first edge portion of the first active pattern, and a second storage node pad and a second storage node contact sequentially provided on the second edge portion of the second active pattern. Each of the first and second storage node contacts includes a metal material.

### CROSS-REFERENCE TO RELATED APPLICATIONS

This U.S. non-provisional patent application claims priority under 35 U.S.C. § 119 to Korean Patent Application No. 10-2023-0015797, filed on Feb. 6, 2023, in the Korean Intellectual Property Office, the entire contents of which are hereby incorporated by reference.

### BACKGROUND

Various example embodiments relate to a semiconductor device and/or a method of manufacturing the same.

Semiconductor devices are widely used in an electronic industry because of their small sizes, multi-functional characteristics, and/or low manufacturing costs. Semiconductor devices may be categorized as any one or more of semiconductor memory devices for storing logical data, semiconductor logic devices for processing logical data, and hybrid semiconductor devices having both the function of the semiconductor memory devices and the function of the semiconductor logic devices.

High-speed and/or low-voltage semiconductor devices have been demanded to satisfy characteristics (e.g., high operating speed and/or low power consumption) of electronic devices including semiconductor devices. Semiconductor devices have been highly integrated to meet these demands. Thus, various techniques for improving the integration density of semiconductor devices have been studied.

### SUMMARY

Various example embodiments may provide a semiconductor device capable of being more easily manufactured and/or of improving an integration density, and/or a method of manufacturing the same.

Alternatively or additionally, various example embodiments of inventive concepts may also provide a semiconductor device with improved electrical characteristics and/or reliability, and/or a method of manufacturing the same.

According to some example embodiments, a semiconductor device may include a first active pattern and a second active pattern extending in a first direction and arranged in a second direction intersecting the first direction, each of the first and second active patterns including a first edge portion and a second edge portion spaced apart from each other in the first direction; a first storage node pad and a first storage node contact sequentially provided on the first edge portion of the first active pattern; and a second storage node pad and a second storage node contact sequentially provided on the second edge portion of the second active pattern. Each of the first and second storage node contacts may include a metal material.

Alternatively or additionally according to some example embodiments, a semiconductor device may include a first active pattern and a second active pattern extending in a first direction and arranged in in a second direction intersecting the first direction, each of the first and second active patterns including a first edge portion and a second edge portion spaced apart from each other in the first direction; a first storage node pad and a first storage node contact sequentially provided on the first edge portion of the first active pattern; a second storage node pad and a second storage node contact sequentially provided on the second edge portion of the second active pattern; a first closed spacer surrounding the first storage node contact in a plan view; and a second closed spacer surrounding the second storage node contact in a plan view.

Alternatively or additionally according to some example embodiments, a semiconductor device may include a first active pattern and a second active pattern extending in a first direction and arranged in a second direction intersecting the first directions, each of the first and second active patterns including first and second edge portions spaced apart from each other in the first direction and a center portion between the first and second edge portions; a pair of word lines extending in the second direction to intersect the first active pattern and the second active pattern; a first storage node pad and a first storage node contact sequentially provided on the first edge portion of the first active pattern; a second storage node pad and a second storage node contact sequentially arranged on the second edge portion of the second active pattern; a first bit line extending in a third direction intersecting the first and second directions on the first active pattern; a second bit line extending in the third direction on the second active pattern; a fence pattern between the first storage node contact and the second storage node contact; landing pads on the first storage node contact and the second storage node contact; and data storage patterns on the landing pads. The first edge portion of the first active pattern and the first edge portion of the second active pattern may be adjacent to each other in the second direction. The first edge portion of the first active pattern and the second edge portion of the second active pattern may be adjacent to each other in the third direction. Each of the first and second storage node contacts may include a metal material.

Alternatively or additionally according to some example embodiments, a method of manufacturing a semiconductor device may include forming a first active pattern, a second active pattern, and a device isolation pattern surrounding each of the first and second active patterns in a plan view, the first and second active patterns extending in a first direction and adjacent to each other in a second direction intersecting the first direction, each of the first and second active patterns including a first edge portion and a second edge portion spaced apart from each other in the first direction; forming a first storage node pad on the first edge portion of the first active pattern and a second storage node pad on the second edge portion of the second active pattern; forming a first bit line extending in a third direction intersecting the first and second directions on the first active pattern and a second bit line extending in the third direction on the second active pattern; forming a fence pattern between the first and second bit lines; and forming a first storage node contact on the first storage node pad and a second storage node contact on the second storage node pad. The first storage node contact and the second storage node contact may be spaced apart from each other in the third direction with the fence pattern interposed therebetween.

### BRIEF DESCRIPTION OF THE DRAWINGS

Some example embodiments will be more clearly understood from the following brief description taken in conjunction with the accompanying drawings. The accompanying drawings represent non-limiting example embodiments as described herein.

FIG. 1 is a plan view illustrating a semiconductor device according to various example embodiments of inventive concepts.

FIG. 2 is an enlarged view of some components of FIG. 1.

FIGS. 3A, 3B, 3C and 3D are cross-sectional views corresponding to lines A-A′, B-B′, C-C′ and D-D′ of FIG. 1, respectively.

FIG. 4 is a plan view illustrating a semiconductor device according to various example embodiments of inventive concepts.

FIGS. 5A and 5B are cross-sectional views corresponding to lines C-C′ and D-D′ of FIG. 4, respectively.

FIG. 6 is a plan view illustrating a semiconductor device according to various example embodiments of inventive concepts.

FIG. 7 is a plan view illustrating a semiconductor device according to various example embodiments of inventive concepts.

FIGS. 8A, 8B, 8C and 8D are cross-sectional views corresponding to lines A-A′, B-B′, C-C′ and D-D′ of FIG. 7, respectively.

FIG. 9 is a plan view illustrating a semiconductor device according to various example embodiments of inventive concepts.

FIGS. 10A, 10B, 10C and 10D are cross-sectional views corresponding to lines A-A′, B-B′, C-C′ and D-D′ of FIG. 9, respectively.

FIGS. 11A and 11B are cross-sectional views corresponding to the lines B-B′ and C-C′ of FIG. 1, respectively, to illustrate a semiconductor device according to various example embodiments of inventive concepts.

FIGS. 12, 14 and 16 are plan views illustrating semiconductor devices according to various example embodiments of inventive concepts.

FIGS. 13A, 13B, 13C and 13D are cross-sectional views corresponding to lines A-A′, B-B′, C-C′ and D-D′ of FIG. 12, respectively.

FIGS. 15A, 15B, 15C and 15D are cross-sectional views corresponding to lines A-A′, B-B′, C-C′ and D-D′ of FIG. 14, respectively.

FIGS. 17A, 17B, 17C and 17D are cross-sectional views corresponding to lines A-A′,

B-B′, C-C′ and D-D′ of FIG. 16, respectively.

FIGS. 18 to 29D are views illustrating a method of manufacturing the semiconductor device of FIGS. 1 to 3D.

FIGS. 30A and 30B are views illustrating a method of manufacturing the semiconductor device of FIGS. 1 to 3D.

FIGS. 31 to 32B are views illustrating a method of manufacturing the semiconductor device of FIGS. 4 to 5B.

FIG. 33 is a plan view illustrating a method of manufacturing the semiconductor device of FIG. 6.

FIGS. 34 to 39D are views illustrating a method of manufacturing the semiconductor device of FIGS. 7 to 8D.

FIGS. 40 to 41D are views illustrating a method of manufacturing the semiconductor device of FIGS. 9 to 10D.

FIGS. 42A and 42B are cross-sectional views illustrating a method of manufacturing the semiconductor device of FIGS. 11A and 11B.

FIGS. 43 to 46D are views illustrating a method of manufacturing the semiconductor device of FIGS. 12 to 13D.

FIGS. 47 to 48D are views illustrating a method of manufacturing the semiconductor device of FIGS. 14 to 15D.

FIGS. 49 to 50D are views illustrating a method of manufacturing the semiconductor device of FIGS. 16 to 17D.

### DETAILED DESCRIPTION

Various example embodiments of inventive concepts will now be described more fully with reference to the accompanying drawings.

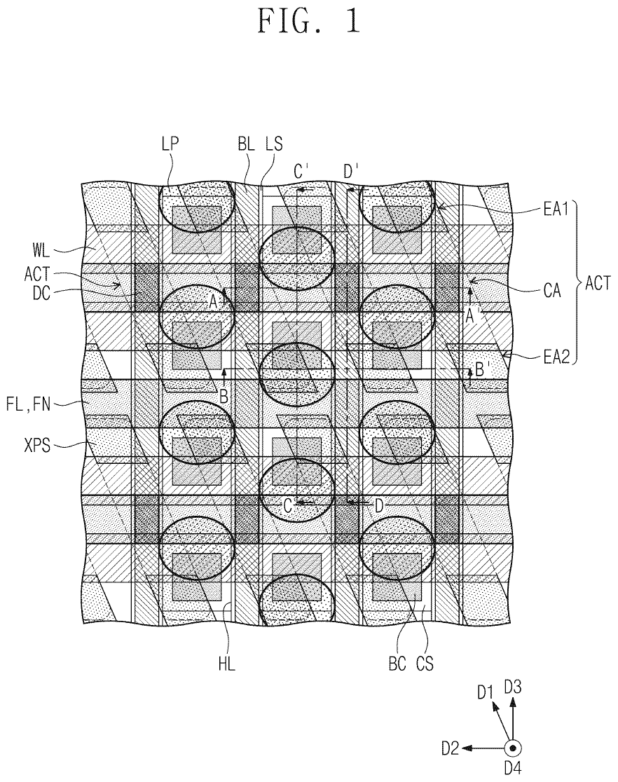

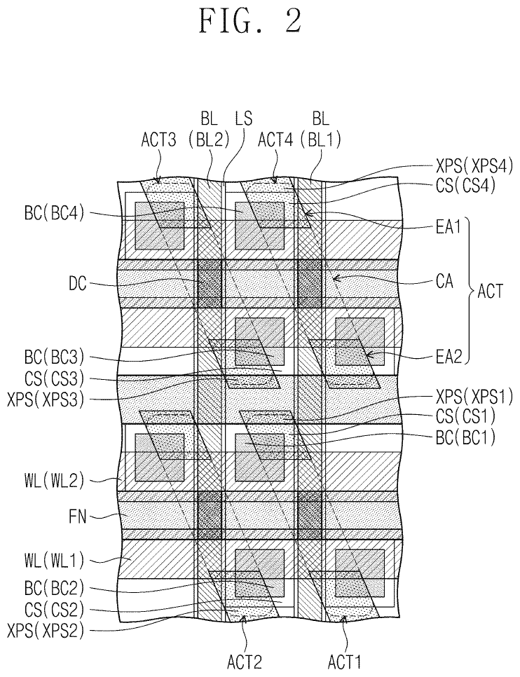

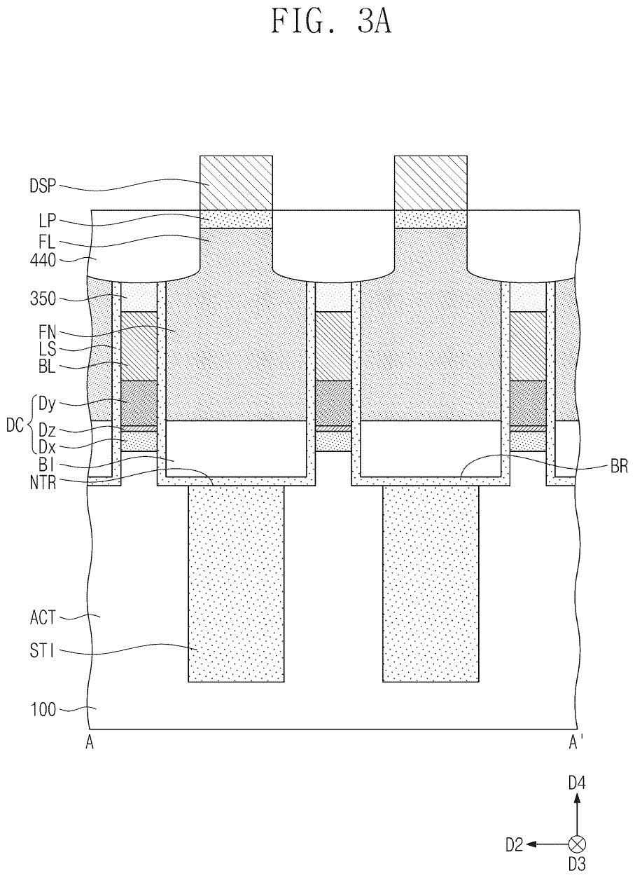

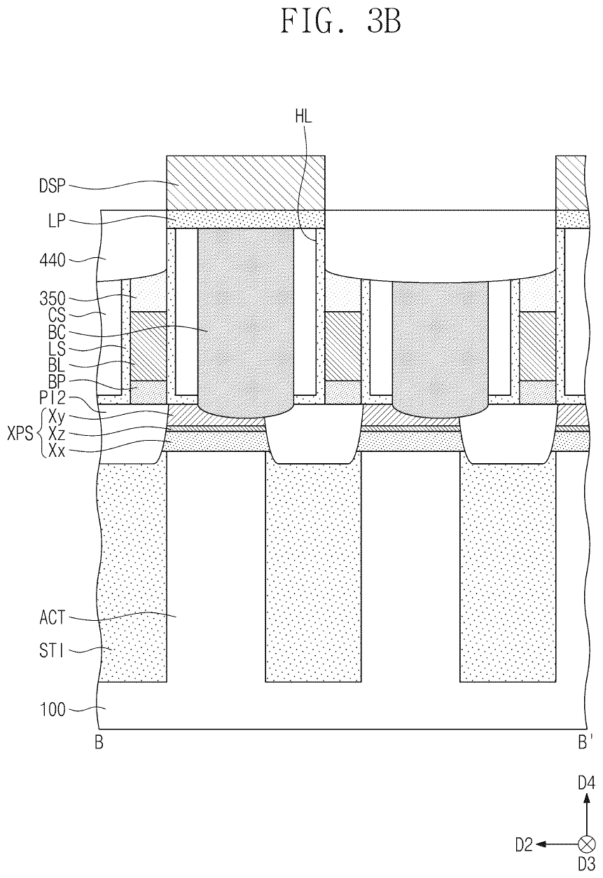

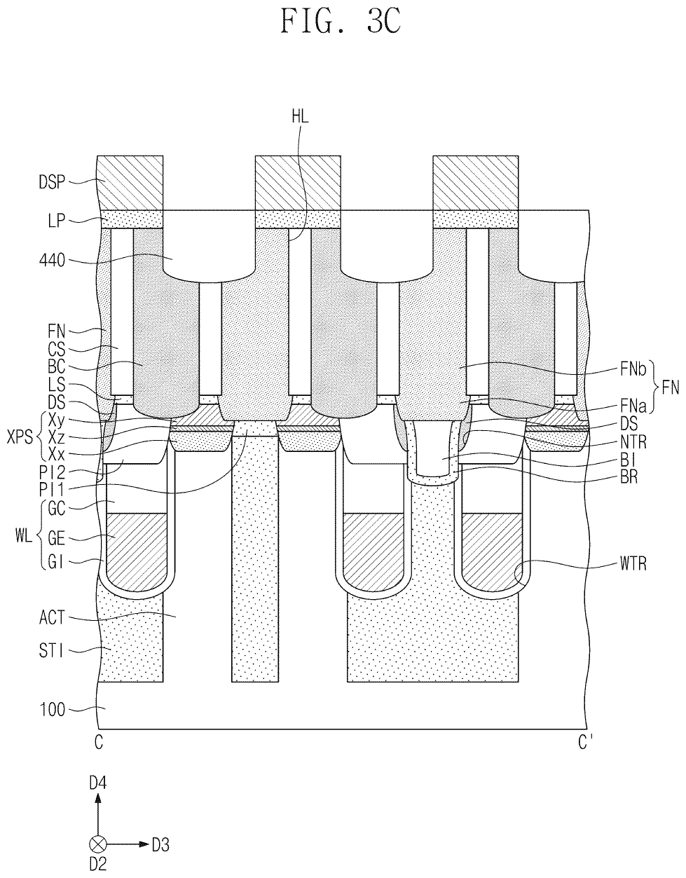

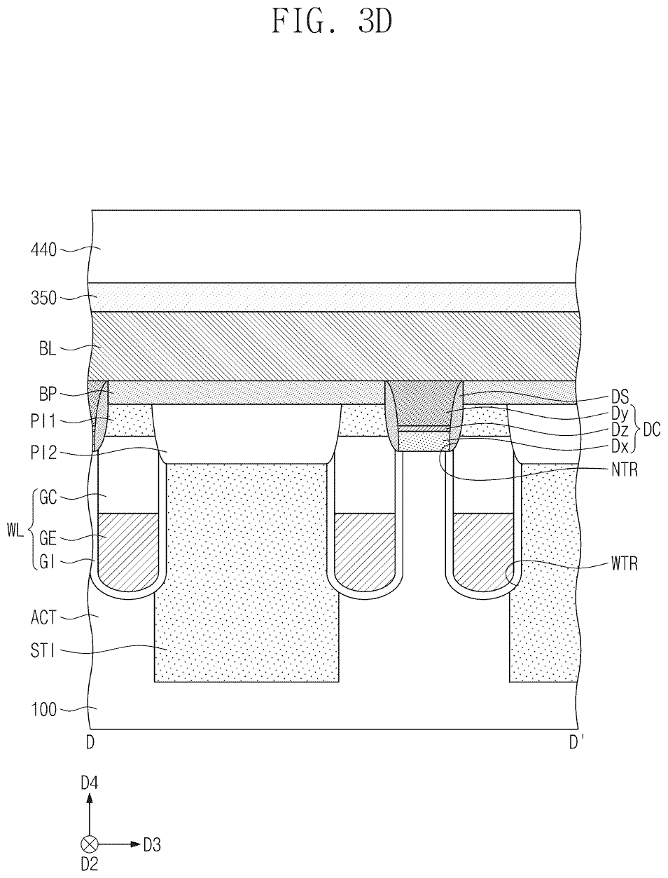

FIG. 1 is a plan view illustrating a semiconductor device according to various example embodiments of inventive concepts. FIG. 2 is an enlarged view of some components of FIG. 1. FIGS. 3A, 3B, 3C and 3D are cross-sectional views corresponding to lines A-A′, B-B′, C-C′ and D-D′ of FIG. 1, respectively.

Referring to FIGS. 1 to 3D, a substrate 100 may be provided. The substrate 100 may be a or include semiconductor substrate such as a silicon substrate, a germanium substrate, or a silicon-germanium substrate. The substrate 100 may be doped, e.g., may be lightly doped with boron and/or phosphorus; however, example embodiments are not limited thereto.

A device isolation pattern STI may be disposed in the substrate 100 and may define an active pattern ACT. The active pattern ACT may be provided in plurality. For example, the active patterns ACT may include portions of the substrate 100, which are surrounded by the device isolation pattern STI. As described herein, the substrate 100 may be defined as another portion of the substrate 100 except the portions of the substrate 100 defined by the device isolation pattern STI unless otherwise stated, for the purpose of ease and convenience in explanation.

Each of the active patterns ACT may have a long shape (long island) extending in a first direction D1 parallel to a bottom surface of the substrate 100. The active patterns ACT may be spaced apart from each other in a second direction D2 and a third direction D3 which are parallel to the bottom surface of the substrate 100 and intersect each other, e.g., are orthogonal to each other. The first to third directions D1, D2 and D3 may intersect each other. The first direction D1 may intersect the second direction D2 at an angle, e.g., at an angle of greater than 0 degrees and less than 90 degrees. Each of the active patterns ACT may have a shape protruding in a fourth direction D4 perpendicular to the surface of the substrate 100. For example, the active pattern ACT may include silicon (e.g., single-crystalline silicon such as but not limited to epitaxial silicon and/or Czochralski silicon).

The active pattern ACT may include a first edge portion EA1, a second edge portion EA2 spaced apart from the first edge portion EA1 in the first direction D1, and a center portion CA between the first edge portion EA1 and the second edge portion EA2. The first edge portion EA1 and the second edge portion EA2 may be both end portions of the active pattern ACT in the first direction D1. The center portion CA may be disposed between a pair of rows or word lines WL (to be described later) intersecting the active pattern ACT. The center portions CA of the active patterns ACT may be spaced apart from each other in the second and third directions D2 and D3. Dopants (e.g., n-type and/or p-type dopants and/or carbon dopants) may be provided in the first and second edge portions EA1 and EA2 and the center portion CA.

The active patterns ACT adjacent to each other may be arranged in a line in the first direction D1 (or an opposite direction thereto), the second direction D2 (or an opposite direction thereto) or the third direction D3 (or an opposite direction thereto). As used herein, it may be understood that when the active patterns ACT are arranged in a line in a direction, the center portions CA of the adjacent active patterns ACT may be arranged in the direction. In some example embodiments, as shown in FIG. 2, a first active pattern ACT1, a second active pattern ACT2, a third active pattern ACT3 and a fourth active pattern ACT4 may be arranged in a clockwise direction. The first active pattern ACT1 and the second active pattern ACT2 directly adjacent thereto may be arranged in a line in the second direction D2. The first active pattern ACT1 and the third active pattern ACT3 directly adjacent thereto may be arranged in a line in the first direction D1. The first active pattern ACT1 and the fourth active pattern ACT4 directly adjacent thereto may be arranged in a line in the third direction D3. Referring to FIG. 2, in some example embodiments, the first active pattern ACT1 may be collinear with the third active pattern ACT3; example embodiments are not limited thereto.

The first edge portion EA1 of the first active pattern ACT1 and the first edge portion EA1 of the second active pattern ACT2 may be adjacent to each other in the second direction D2. The first edge portion EA1 of the first active pattern ACT1 and the second edge portion EA2 of the second active pattern ACT2 may be adjacent to each other in the third direction D3. The first edge portion EA1 of the first active pattern ACT1 and the second edge portion EA2 of the third active pattern ACT3 may be adjacent to each other and may be spaced apart from each other (e.g., collinear with each other) in the first direction D1.

According to various inventive concepts, the active patterns ACT may be arranged in a line or be arranged collinearly in the first direction D1 (or the opposite direction thereto), the second direction D2 (or the opposite direction thereto) or the third direction D3 (or the opposite direction thereto), and thus arrangement of components in the semiconductor device may be simplified. As a result, difficulty of a patterning process, etc. of manufacturing the semiconductor device may be reduced to more easily manufacture the semiconductor device. Alternatively or additionally, the components may be relatively simply arranged to improve an integration density of the semiconductor device.

The device isolation pattern STI may include an insulating material (e.g., at least one of silicon oxide and silicon nitride). The device isolation pattern STI may be a single layer formed of a single material or a composite layer including two or more materials. As used herein, the term ‘A or B’, ‘at least one of A and B’, ‘at least one of A or B’, ‘A, B or C’, ‘at least one of A, B and C’, or ‘at least one of A, B, or C’ may include any and all combinations of one or more of the associated listed items.

A word line WL may intersect the active patterns ACT and the device isolation pattern STI. The word line WL may be provided in plurality. The word lines WL may extend in the second direction D2 and may be spaced apart from each other in the third direction D3. A pair of the word lines WL spaced apart from each other in the third direction D3 may intersect the active patterns ACT adjacent to each other in the second direction D2. For example, as shown in FIG. 2, a first word line WL1 and a second word line WL2 may be spaced apart from each other in the third direction D3 and may intersect the first and second active patterns ACT1 and ACT2 adjacent to each other in the second direction D2.

Each of the word lines WL may include a gate electrode GE, a gate dielectric pattern GI, and a gate capping pattern GC. The gate electrode GE may penetrate the active patterns ACT and the device isolation pattern STI in the second direction D2. The gate dielectric pattern GI may be disposed between the gate electrode GE and the active patterns ACT and between the gate electrode GE and the device isolation pattern STI. The gate capping pattern GC may be disposed on the gate electrode GE to cover (e.g. fully cover) a top surface of the gate electrode GE. For example, the gate electrode GE may include a conductive material such as but not limited to tungsten (W) and/or polysilicon such as doped polysilicon. Alternatively or additionally in some example embodiments, the gate dielectric pattern GI may include at least one of silicon oxide and a high-k dielectric material. In some example embodiments, the gate dielectric pattern GI may be or may include a thermally oxidized pattern; example embodiments are not limited thereto. In As used herein, the high-k dielectric material may be defined as a material having a dielectric constant higher than that of silicon oxide. In some example embodiments, the gate capping pattern GC may include silicon nitride.

Storage node pads XPS may be provided on the first and second edge portions EA1 and EA2 of the active patterns ACT. The storage node pads XPS may be spaced apart from each other in the first direction D1 and the second direction D2. The storage node pads XPS may be electrically connected to the first and second edge portions EA1 and EA2.

In some example embodiments, as shown in FIG. 2, each of the storage node pads XPS may be electrically connected to a corresponding one of the first and second edge portions EA1 and EA2. For example, a first storage node pad XPS1 may be connected to the first edge portion EA1 of the first active pattern ACT1. For example, a second storage node pad XPS2 may be connected to the second edge portion EA2 of the second active pattern ACT2. For example, a third storage node pad XPS3 may be connected to the second edge portion EA2 of the third active pattern ACT3. For example, a fourth storage node pad XPS4 may be connected to the first edge portion EA1 of the fourth active pattern ACT4.

For example, the storage node pad XPS may have a parallelogram shape when viewed in a plan view. For example, the storage node pad XPS may have two sides which extend in the first direction D1 and are opposite to each other, and other two sides which extend in the second direction D2 and are opposite to each other. However, various example embodiments of inventive concepts are not limited thereto.

A width of the storage node pad XPS may be changed depending on a direction and a level. For example, a width of the storage node pad XPS in the third direction D3 may decrease as a level decreases. For certain examples, a width of the storage node pad XPS in the second direction D2 may increase as a level decreases (e.g., decreases in the fourth direct D4). However, various example embodiments of inventive concepts are not limited thereto. For example, the storage node pad XPS may include at least one of silicon (e.g., doped polysilicon) and/or a metal material (e.g., one or more of Ti, Mo, W, Cu, Al, Ta, Ru, Ir, etc.).

For example, as shown in FIG. 3B, the storage node pad XPS may be formed of a composite layer including two or more materials and may include a lower pad Xx and an upper pad Xy on the lower pad Xx. For example, the lower pad Xx may include silicon (e.g., doped polysilicon), and the upper pad Xy may include a metal material (e.g., one or more of Ti, Mo, W, Cu, Al, Ta, Ru, Ir, etc.). For example, the storage node pad XPS may additionally or alternatively include an ohmic pad Xz between the lower pad Xx and the upper pad Xy. Alternatively, even though not shown in the drawings, the storage node pad XPS may be a single layer formed of a single material.

A digit line contact or bit line node contact DC may be provided on each of the active patterns ACT, and for example, the bit line node contact DC may be provided in plurality. The bit line node contacts DC may be electrically connected to the center portions CA of the active patterns ACT, respectively. The bit line node contacts DC may be spaced apart from each other in the second and third directions D2 and D3. The bit line node contacts DC may be disposed between the active patterns ACT and bit lines BL to be described later, respectively. Each of the bit line node contacts DC may electrically connect a corresponding one of the bit lines BL to the center portion CA of a corresponding one of the active patterns ACT. For example, the bit line node contact DC may include at least one of silicon (e.g., doped polysilicon) and a metal material (e.g., one or more of Ti, Mo, W, Cu, Al, Ta, Ru, Ir, etc.).

For example, as shown in FIG. 3A, the bit line node contact DC may be formed of a composite layer including two or more materials and may include a lower contact Dx and an upper contact Dy on the lower contact Dx. For example, the lower contact Dx may include silicon (e.g., doped polysilicon), and the upper contact Dy may include a metal material (e.g., Ti, Mo, W, Cu, Al, Ta, Ru, Ir, etc.). For example, the bit line node contact DC may further include an ohmic contact Dz between the lower contact Dx and the upper contact Dy. Alternatively, even though not shown in the drawings, the bit line node contact DC may be a single layer formed of a single material.

In some example embodiments, a first pad insulating pattern PI1 and a second pad insulating pattern PI2 may surround side surfaces of the storage node pads XPS and side surfaces of the bit line node contacts DC. The first pad insulating pattern PI1 and the second pad insulating pattern PI2 may electrically insulate the storage node pads XPS and the bit line node contacts DC from each other. For example, each of the first pad insulating pattern PI1 and the second pad insulating pattern PI2 may include an insulating material, and may or may not include the same material.

A bit line node contact spacer DS may be provided on the side surface of the bit line node contact DC. For example, a pair of the bit line node contact spacers DS may cover side surfaces of the bit line node contact DC, which face the third direction D3 and the opposite direction thereto, respectively. For example, the bit line node contact spacer DS may be disposed between the bit line node contact DC and the first pad insulating pattern PI1 adjacent thereto in the third direction D3. For example, the bit line node contact spacer DS may be provided on the side surface of one bit line node contact DC and may extend onto the side surface of another bit line node contact DC adjacent to the one bit line node contact DC in the second direction D2. The second pad insulating pattern PI2 may be disposed between the one bit line node contact DC and the adjacent bit line node contact DC, and the bit line node contact spacer DS may extend onto a side surface of the second pad insulating pattern PI2.

A column line or bit line BL may be provided on the bit line node contact DC. The bit line BL may extend in the third direction D3. The bit line BL may be provided in plurality. The bit lines BL may be spaced apart from each other in the second direction D2. The bit line BL may include a metal material. For example, the bit line BL may include doped polysilicon and/or a metal material (e.g., one or more of Ti, Mo, W, Cu, Al, Ta, Ru, Ir, etc.). For certain examples, the bit line BL may further include a metal silicide and/or a metal nitride.

The bit line BL may be disposed on the center portions CA of the active patterns ACT arranged in a line in the third direction D3 and may be electrically connected to the active patterns ACT arranged in a line through the bit line node contacts DC. For example, as shown in FIG. 2, a first bit line BL1 may be disposed on the center portions CA of the first active pattern ACT1 and the fourth active pattern ACT4 arranged in a line in the third direction D3 and may be electrically connected to the center portions CA of the first and fourth active patterns ACT1 and ACT4. For example, a second bit line BL2 may be disposed on the center portions CA of the second active pattern ACT2 and the third active pattern ACT3 arranged in a line in the third direction D3 and may be electrically connected to the center portions CA of the second and third active patterns ACT2 and ACT3.

A buffer pattern BP may be disposed under the bit line BL and may cover the substrate 100. For example, the buffer pattern BP may be disposed between the bit line BL and the first pad insulating pattern PI1 and between the bit line BL and the second pad insulating pattern PI2. For example, the buffer pattern BP may be disposed between the bit line node contacts DC adjacent to each other in the third direction D3. For example, the buffer pattern BP may include at least one of silicon oxide, silicon nitride, silicon oxynitride, or a high-k dielectric material. The buffer pattern BP may be a single layer formed of a single material or a composite layer including two or more materials. For example, the buffer pattern BP may be a composite layer including a lower buffer pattern and an upper buffer pattern.

A bit line capping pattern 350 may be provided on a top surface of the bit line BL. The bit line capping pattern 350 may extend in the third direction D3 together with the bit line BL. The bit line capping pattern 350 may be provided in plurality. The plurality of bit line capping patterns 350 may be spaced apart from each other in the second direction D2. The bit line capping pattern 350 may vertically overlap with the bit line BL. The bit line capping pattern 350 may be formed of a single layer or a plurality of layers. For example, the bit line capping pattern 350 may include a first capping pattern, a second capping pattern and a third capping pattern, which are sequentially stacked. Each of the first to third capping patterns may include silicon nitride, e.g., with each the same or different properties such as the same or different materials. There may or may not be a seam (not illustrated) between different ones of the first to third capping patterns. Alternatively, the bit line capping pattern 350 may include four or more stacked capping patterns.

A line spacer LS may be provided on a side surface of the bit line BL and a side surface of the bit line capping pattern 350. The line spacer LS may cover the side surface of the bit line BL and the side surface of the bit line capping pattern 350. The line spacer LS may extend in the third direction D3 on the side surface of the bit line BL. For example, the line spacers LS adjacent to each other in the second direction D2 may be connected to each other through a buried liner BR (to be described later) under a fence pattern FN to be described later, but embodiments of the inventive concepts are not limited thereto. For example, the line spacer LS may include at least one of silicon oxide (SiO₂), silicon nitride (SiN), silicon oxycarbide (SiOC), and silicon oxy-carbonitride (SiOCN). For example, the line spacer LS may be a single layer formed of a single material or a composite layer including two or more materials.

A fence pattern FN may be disposed between the bit lines BL adjacent to each other. The fence pattern FN and a storage node contact BC to be described later may be sequentially arranged in the third direction D3. The fence pattern FN may be disposed between the storage node contacts BC adjacent to each other in the third direction D3 and may separate the adjacent storage node contacts BC from each other. The fence pattern FN may be provided in plurality, and the plurality of fence patterns FN may be spaced apart from each other in the second and third directions D2 and D3.

The fence pattern FN may include a lower fence pattern FNa and an upper fence pattern FNb. The upper fence pattern FNb may be an upper portion of the fence pattern FN which is surrounded by a closed spacer CS to be described later, and the lower fence pattern FNa may be a lower portion of the fence pattern FN which is located at a level lower than the closed spacer CS. For example, at a level at which the lower fence pattern FNa is in contact with the upper fence pattern FNb, a width of the lower fence pattern FNa in the third direction D3 may be greater than a width of the upper fence pattern FNb in the third direction D3.

Fence lines FL may extend in the second direction D2 above the bit line capping pattern 350 and may be spaced apart from each other in the third direction D3. Each of the fence lines FL may be connected to the fence patterns FN arranged in a line in the second direction D2. For example, a filling pattern 440 to be described later may penetrate the fence line FL in the fourth direction D4.

Each of the fence pattern FN and the fence line FL may include at least one of silicon oxide (SiO₂), silicon nitride (SiN), silicon oxycarbide (SiOC), and silicon oxy-carbonitride (SiOCN).

For example, a buried insulating pattern BI may be provided between the bit line node contacts DC adjacent to each other in the second direction D2. The buried insulating pattern BI may be provided under the fence pattern FN. The buried insulating pattern BI may be disposed between the pair of bit line node contact spacers DS. The buried liner BR may be disposed between the buried insulating pattern BI and the bit line node contact spacer DS. For example, the buried insulating pattern BI may include at least one of silicon oxide (SiO₂) and silicon nitride (SiN). For example, the buried liner BR may include at least one of silicon oxide (SiO₂), silicon nitride (SiN), silicon oxycarbide (SiOC), and silicon oxy-carbonitride (SiOCN).

In certain example embodiments, at least one of the buried insulating pattern BI and the buried liner BR may not be provided.

The storage node contact BC may be provided between the bit lines BL adjacent to each other and between the fence patterns FN adjacent to each other in the third direction D3. For example, a hole HL may be defined between the bit lines BL adjacent to each other and between the fence patterns FN adjacent to each other in the third direction D3, and the storage node contact BC may fill the hole HL. The storage node contact BC may be provided in plurality. The plurality of storage node contacts BC may be spaced apart from each other in the second and third directions D2 and D3. The storage node contacts BC adjacent to each other may be arranged in the second or third directions D2 or D3. The storage node contacts BC may be provided on the storage node pads XPS. The storage node contacts BC may be electrically connected to the first and second edge portions EA1 and EA2 through the storage node pads XPS.

For example, as shown in FIG. 2, each of the storage node contacts BC may be electrically connected to a corresponding one of the first and second edge portions EA1 and EA2 through a corresponding one of the storage node pads XPS. For example, a first storage node contact BC1 may be electrically connected to the first edge portion EA1 of the first active pattern ACT1 through the first storage node pad XPS1. For example, a second storage node contact BC2 may be electrically connected to the second edge portion EA2 of the second active pattern ACT2 through the second storage node pad XPS2. For example, a third storage node contact BC3 may be electrically connected to the second edge portion EA2 of the third active pattern ACT3 through the third storage node pad XPS3. For example, a fourth storage node contact BC4 may be electrically connected to the first edge portion EA1 of the fourth active pattern ACT4 through the fourth storage node pad XPS4.

The first to fourth storage node contacts BC1, BC2, BC3 and BC4 may be disposed between the first bit line BL1 and the second bit line BL2. The first to fourth storage node contacts BC1, BC2, BC3 and BC4 may be arranged in a line in the third direction D3. For example, the second storage node contact BC2, the first storage node contact BC1, the third storage node contact BC3 and the fourth storage node contact BC4 may be arranged in a line in the third direction D3 and may be sequentially arranged in the third direction D3. For example, the storage node contact BC may include at least one of metal materials (e.g., one or more of Ti, Mo, W, Cu, Al, Ta, Ru, Ir, etc.).

According to various example embodiments, since the storage node pads XPS are provided, each of the storage node contacts BC may be more easily electrically connected to a corresponding one of the first and second edge portions EA1 and EA2. For example, even though the storage node contact BC is misaligned and thus does not vertically overlap with the corresponding edge portion, the storage node contact BC may be electrically connected to the corresponding edge portion through the storage node pad XPS. If the storage node contact BC is in direct contact with the corresponding edge portion, a contact resistance therebetween may be increased by misalignment. An increase in the contact resistance may deleteriously affect the sensing margin of the semiconductor device.

Alternatively or additionally, if the storage node contact BC including the metal material is in direct contact with the edge portion including silicon, an ohmic contact may not be easily formed. For example, a Schottky contact may be formed. The storage node contact BC may be more easily form an ohmic contact with the corresponding edge portion through the storage node pad XPS.

Thus, the storage node pad XPS may improve a contact resistance between the storage node contact BC and the corresponding edge portion. As a result, electrical characteristics and/or reliability of the semiconductor device may be improved.

The closed spacer CS may surround the storage node contact BC. For example, the closed spacer CS may surround a side surface of the storage node contact BC. The closed spacer CS may be provided in plurality, and each of the closed spacers CS may surround a corresponding one of the storage node contacts BC. The closed spacer CS may cover an inner side surface of the hole HL. The closed spacer CS may be disposed between the inner side surface of the hole HL and the storage node contact BC. For example, the closed spacer CS may be disposed between the storage node contact BC and the bit line BL and between the storage node contact BC and the fence pattern FN. The closed spacer CS may separate the storage node contact BC from the bit line BL and other storage node contact BC.

For example, as shown in FIG. 2, a first closed spacer CS1 may surround the first storage node contact BC1. A second closed spacer CS2 may surround the second storage node contact BC2. A third closed spacer CS3 may surround the third storage node contact BC3. A fourth closed spacer CS4 may surround the fourth storage node contact BC4. The first to fourth closed spacers CS1, CS2, CS3 and CS4 may be disposed between the first bit line BL1 and the second bit line BL2.

For example, the closed spacer CS may include at least one of silicon oxide (SiO₂), silicon nitride (SiN), silicon oxycarbide (SiOC), and silicon oxy-carbonitride (SiOCN). For example, the closed spacer CS may be a single layer formed of a single material or a composite layer including two or more materials.

A landing pad LP may be provided on the storage node contact BC. The landing pad LP may be provided in plurality. The plurality of landing pads LP may be spaced apart from each other in the second and third directions D2 and D3. Each of the landing pads LP may be electrically connected to a corresponding one of the first and second edge portions EA1 and EA2 through a corresponding one of the storage node contacts BC and a corresponding one of the storage node pads XPS.

Each of the landing pads LP may be shifted from the corresponding storage node contact BC in the third direction D3 (or the opposite direction thereto). For example, a portion of the landing pad LP may vertically overlap with the corresponding storage node contact BC, and another portion of the landing pad LP may not vertically overlap with the corresponding storage node contact BC. For example, the landing pad LP may include at least one of metal materials (e.g., one or more of Ti, Mo, W, Cu, Al, Ta, Ru, Ir, etc.).

A filling pattern 440 may surround the landing pad LP when viewed in a plan view. The filling pattern 440 may be disposed between the landing pads LP adjacent to each other. The filling pattern 440 may have a mesh shape including holes penetrated by the landing pads LP, when viewed in a plan view. For example, the filling pattern 440 may include at least one of silicon nitride, silicon oxide, silicon oxynitride, or any combination thereof. Alternatively, the filling pattern 440 may include an empty space (e.g., an air gap) including air such as but not limited to clean, dry air (CDA).

A data storage pattern DSP may be provided on the landing pad LP. The data storage pattern DSP may be provided in plurality. The plurality of data storage patterns DSP may be spaced apart from each other in the second and third directions D2 and D3. Each of the data storage patterns DSP may be electrically connected to a corresponding one of the first and second edge portions EA1 and EA2 through a corresponding one of the landing pads LP, a corresponding one of the storage node contacts BC and a corresponding one of the storage node pads XPS.

For some examples, the data storage pattern DSP may be or may include a capacitor including a lower electrode, a dielectric layer and an upper electrode. In this case, the semiconductor device according to inventive concepts may be a dynamic random access memory (DRAM) device. For certain examples, the data storage pattern DSP may include a magnetic tunnel junction pattern. In this case, the semiconductor device according to inventive concepts may be or include a magnetic random access memory (MRAM) device. For certain examples, the data storage pattern DSP may include a phase-change material and/or a variable resistance material. In this case, the semiconductor device according to inventive concepts may be or include a phase-change random access memory (PRAM) device or a resistive random access memory (ReRAM) device. However, example embodiments of inventive concepts are not limited thereto, and in certain example embodiments, the data storage pattern DSP may include at least one of other various structures and/or materials capable of storing data.

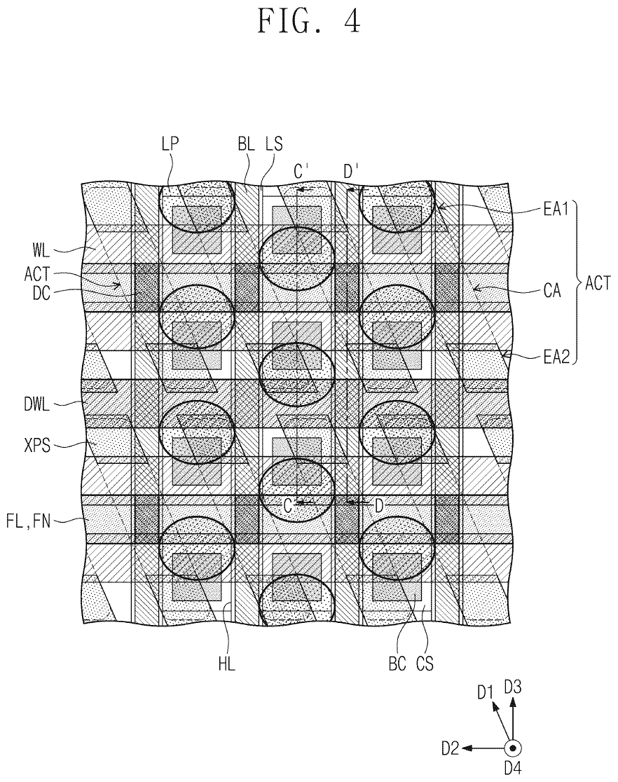

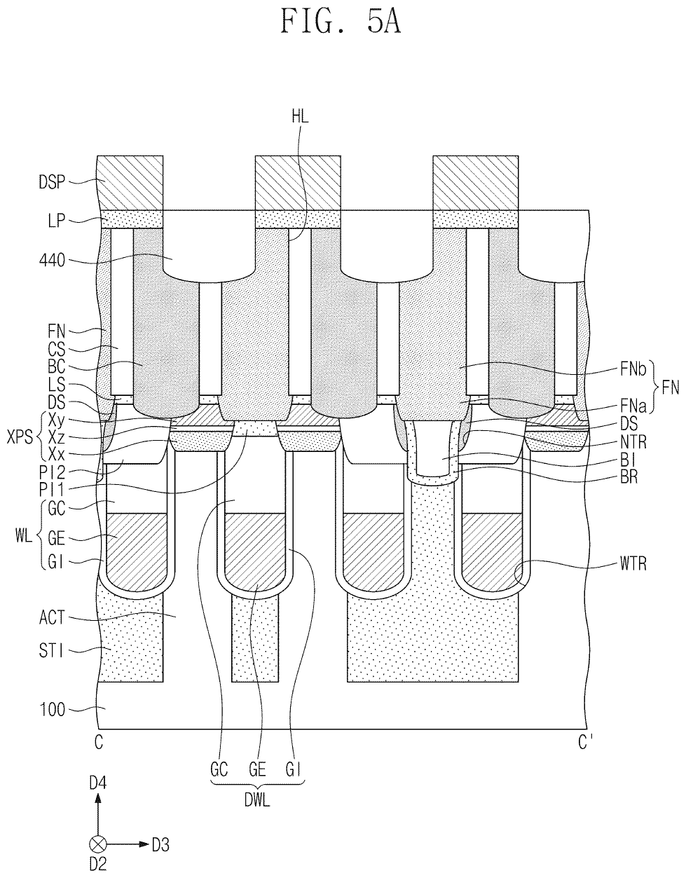

Hereinafter, example embodiments of inventive concepts will be described with reference to FIGS. 4 to 17D. In the following example embodiments, the descriptions to the same features as mentioned above will be omitted and differences between the following embodiments and the above embodiments will be mainly described, for the purpose of ease and convenience in explanation.

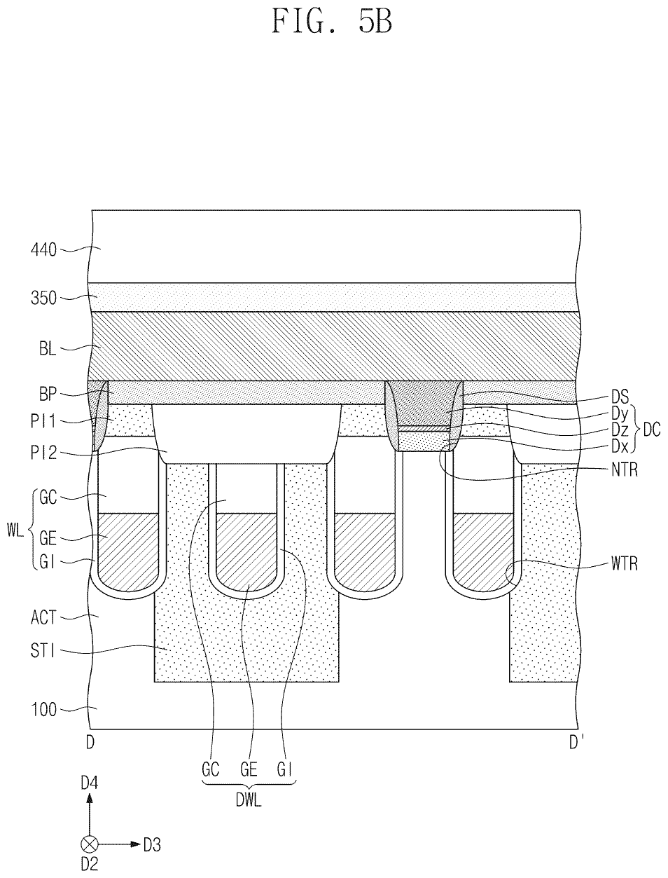

FIG. 4 is a plan view illustrating a semiconductor device according to various example embodiments of inventive concepts. FIGS. 5A and 5B are cross-sectional views corresponding to lines C-C′ and D-D′ of FIG. 4, respectively.

Referring to FIGS. 4 to 5B, a dummy word line DWL may be provided. The dummy word line DWL may extend in the second direction D2 and may be spaced apart from the word lines WL in the third direction D3. The dummy word line DWL may be disposed between the active patterns ACT adjacent to each other in the third direction D3. For example, a portion of the device isolation pattern STI may be disposed between the active patterns ACT adjacent to each other in the third direction D3, and the dummy word line DWL may intersect the adjacent active patterns ACT and the portion of the device isolation pattern STI. The dummy word line DWL may include a gate electrode GE, a gate dielectric pattern GI, and a gate capping pattern GC.

For example, distances between the word lines WL arranged in the third direction D3 may not be constant. The dummy word line DWL may be disposed between the word lines WL spaced apart from each other by a relatively great distance. Thus, a loading effect according to a patterning density may be prevented or reduced in likelihood of occurrence and/or in impact from occurring in a patterning process for forming the word lines WL. The dummy word line DWL may not be electrically active during operation of the semiconductor device. As a result, the word lines WL may be more easily formed.

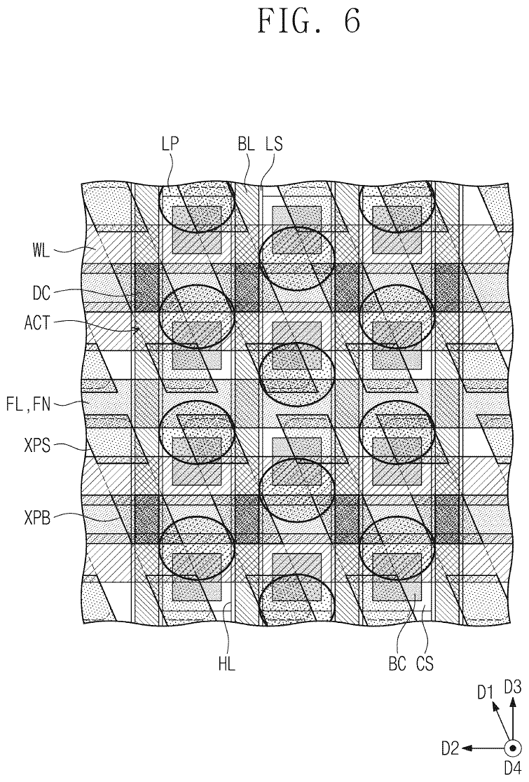

FIG. 6 is a plan view illustrating a semiconductor device according to various example embodiments of inventive concepts.

Referring to FIG. 6, a bit line node pad XPB may be provided on the center portion CA of the active pattern ACT. The bit line node pad XPB may be electrically connected to the center portion CA of the active pattern ACT. The bit line BL may be electrically connected to the center portion CA of the active pattern ACT through the bit line node contact DC and the bit line node pad XPB. The bit line node pad XPB may be provided in plurality, and the plurality of bit line node pads XPB may be spaced apart from each other in the second and third directions D2 and D3. Each of the bit line node contacts DC may be electrically connected to the center portion CA of a corresponding one of the active patterns ACT through a corresponding one of the bit line node pads XPB.

The bit line node pads XPB and the storage node pads XPS may be alternately arranged in the first direction D1 when viewed in a plan view. More particularly, one bit line node pad XPB and two storage node pads XPS may be repeatedly and alternately arranged in the first direction D1.

For example, the bit line node pad XPB may include at least one of silicon (e.g., doped polysilicon) and a metal material (e.g., Ti, Mo, W, Cu, Al, Ta, Ru, Ir, etc.). For example, the bit line node pad XPB may be a single layer formed of a single material or a composite layer including two or more materials.

At least one of the bit line node pad XPB and the storage node pad XPS may further include a metal material. For some examples, both the bit line node pad XPB and the storage node pad XPS may include the metal material. For certain example examples, one of the bit line node pad XPB and the storage node pad XPS may include the metal material.

Since the bit line node pads XPB are provided, the bit line BL may be more easily electrically connected to the center portion CA of the active pattern ACT.

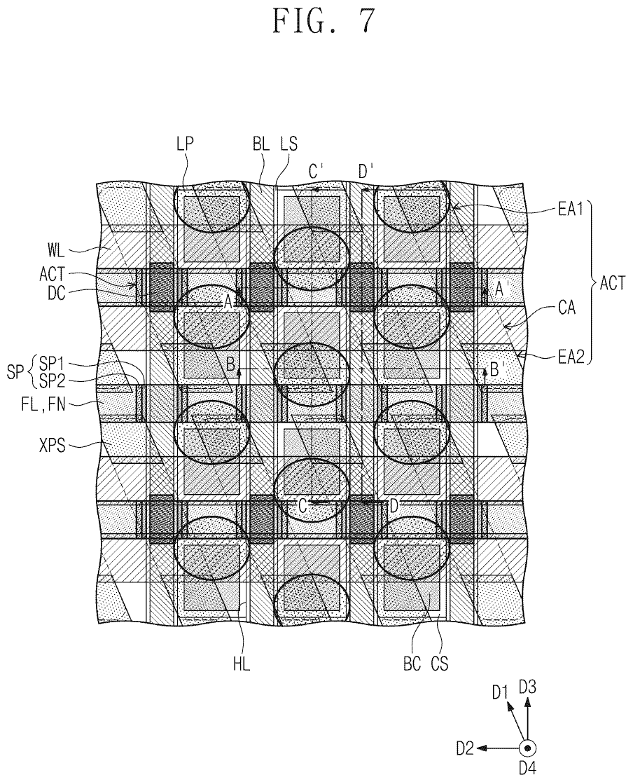

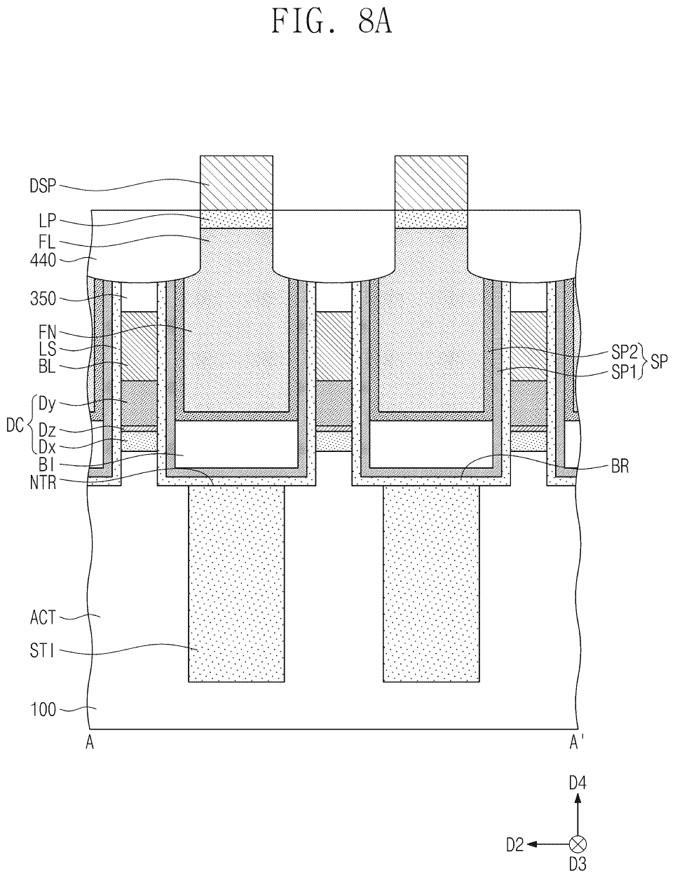

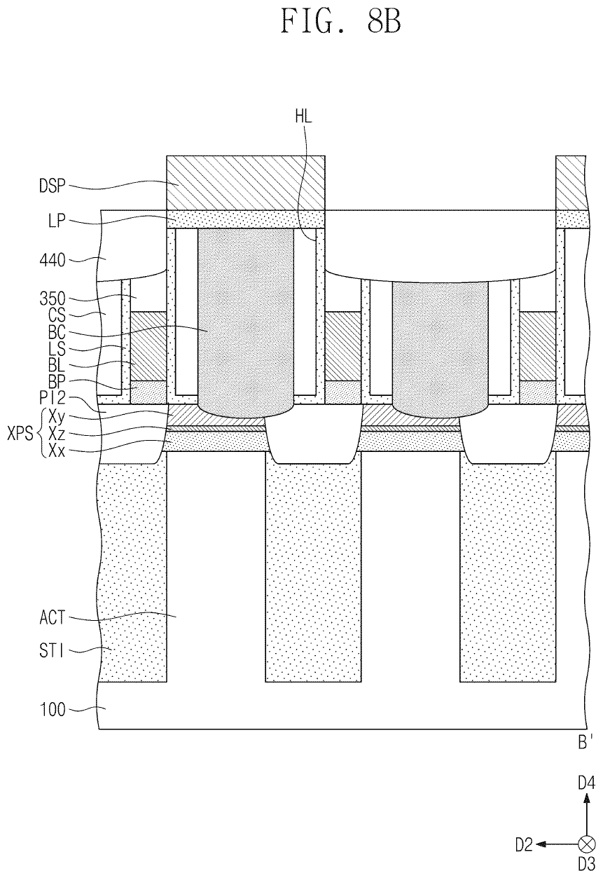

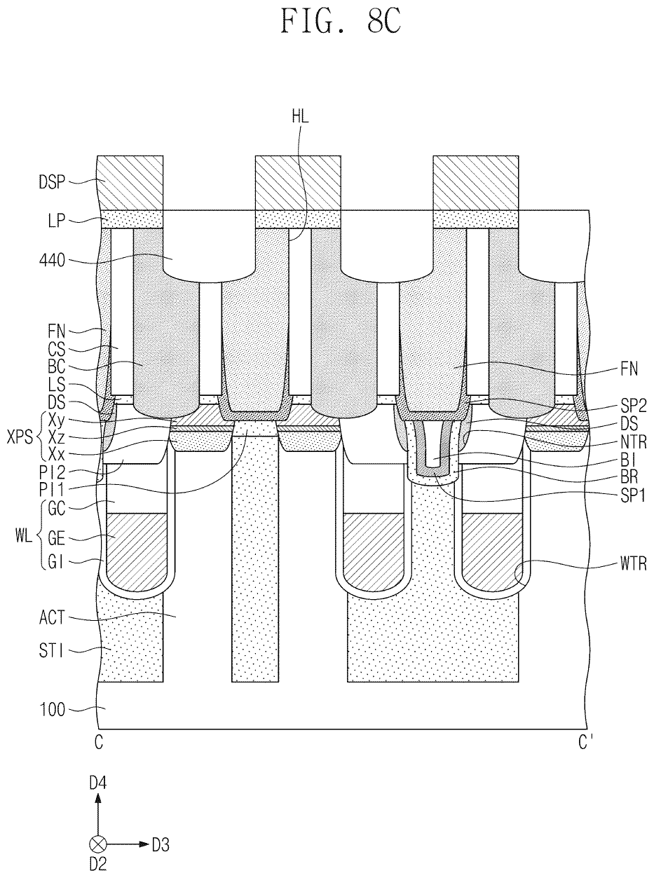

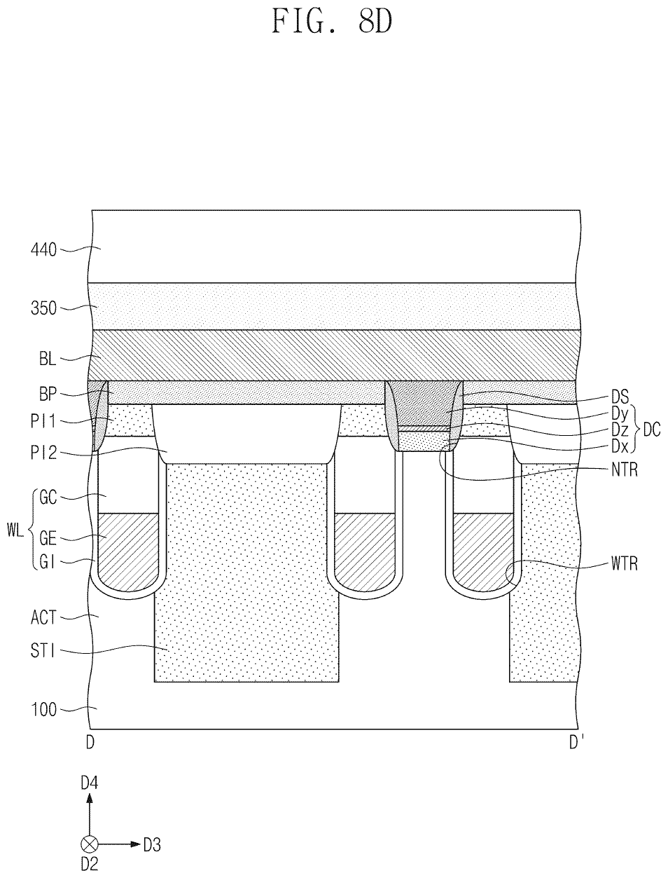

FIG. 7 is a plan view illustrating a semiconductor device according to various example embodiments of inventive concepts. FIGS. 8A, 8B, 8C and 8D are cross-sectional views corresponding to lines A-A′, B-B′, C-C′ and D-D′ of FIG. 7, respectively.

Referring to FIGS. 7 to 8D, a sacrificial pattern SP may be provided on the side surface of the bit line BL. For example, the sacrificial pattern SP may be disposed between the side surface of the bit line BL and the fence pattern FN. For example, the sacrificial pattern SP may be disposed between the storage node contacts BC adjacent to each other in the third direction D3. For example, the sacrificial pattern SP may extend onto a side surface of the bit line node contact DC.

For example, the sacrificial pattern SP may include a first sacrificial pattern SP1 and a second sacrificial pattern SP2. The first sacrificial pattern SP1 may be disposed between the side surface of the bit line BL and the fence pattern FN, and the second sacrificial pattern SP2 may be disposed between the first sacrificial pattern SP1 and the fence pattern FN. For example, the first sacrificial patterns SP1 adjacent to each other in the second direction D2 may be connected to each other under the fence pattern FN. For example, the second sacrificial patterns SP2 adjacent to each other in the second direction D2 may be connected to each other under the fence pattern FN. Under the fence pattern FN, the buried insulating pattern BI may be disposed between the first sacrificial pattern SP1 and the second sacrificial pattern SP2. For example, each of the first sacrificial pattern SP1 and the second sacrificial pattern SP2 may include a material having an etch selectivity with respect to the line spacer LS or the fence pattern FN. For example, each of the first sacrificial pattern SP1 and the second sacrificial pattern SP2 may independently or jointly include at least one of silicon oxide (SiO₂) and silicon nitride (SiN).

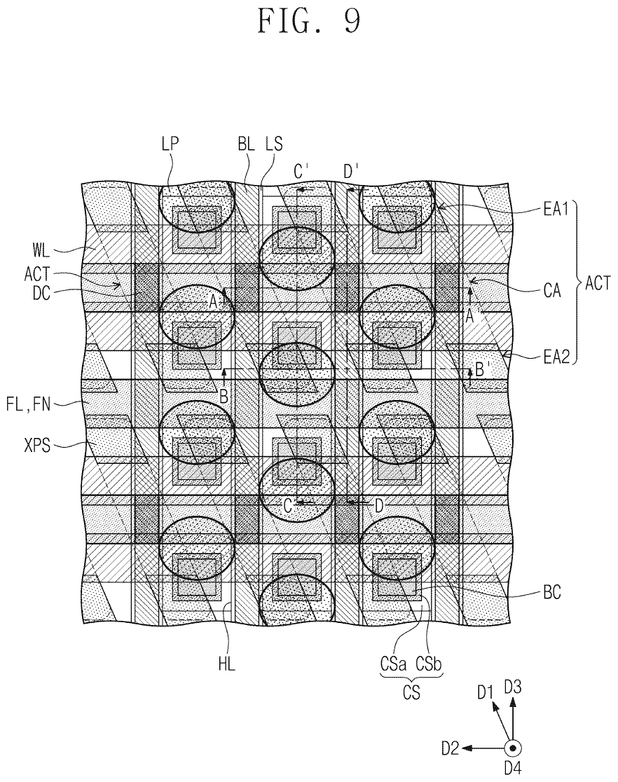

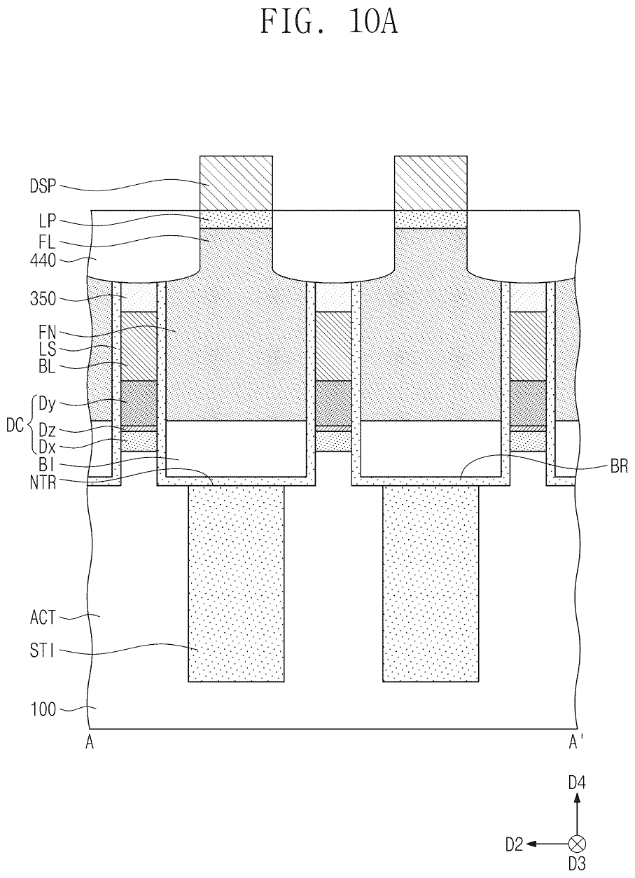

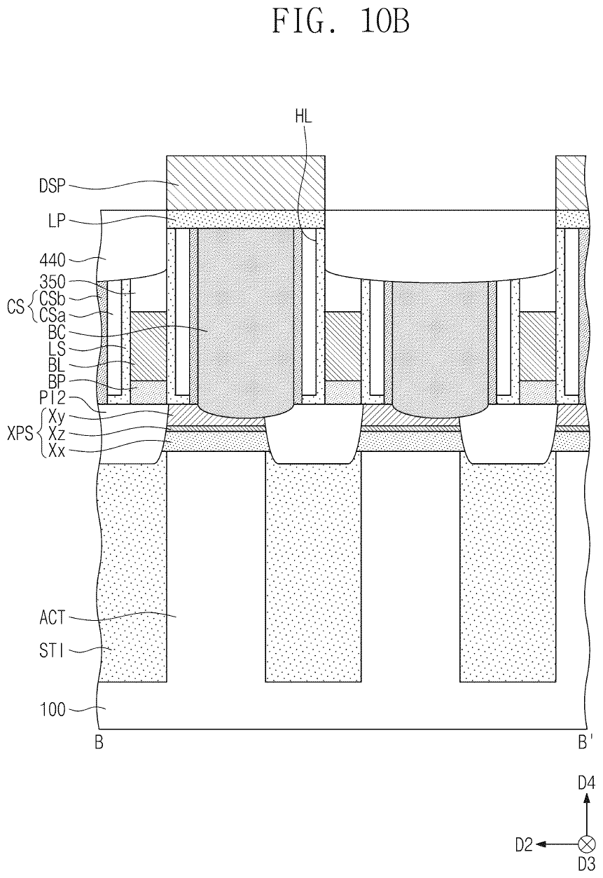

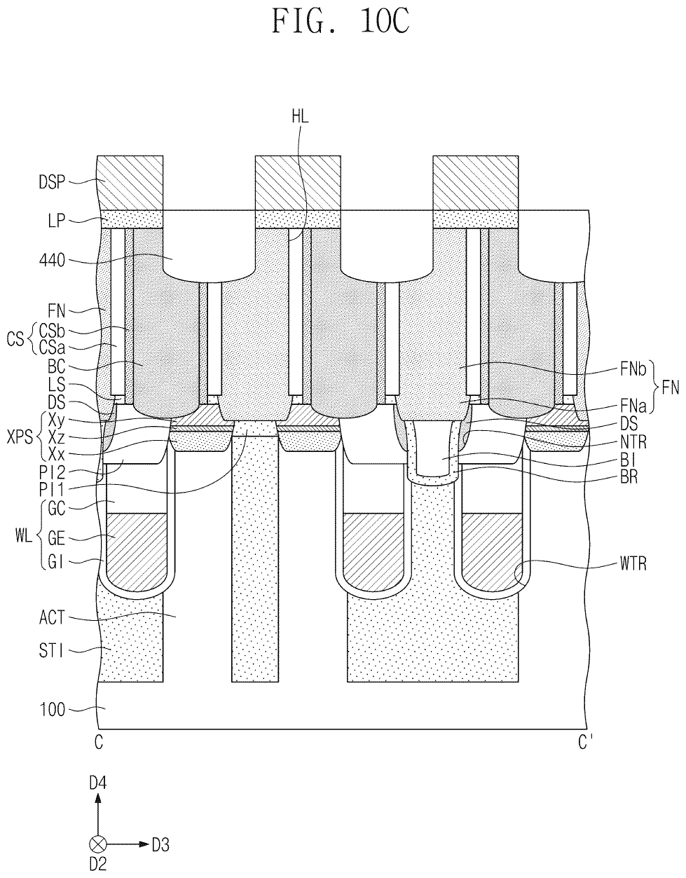

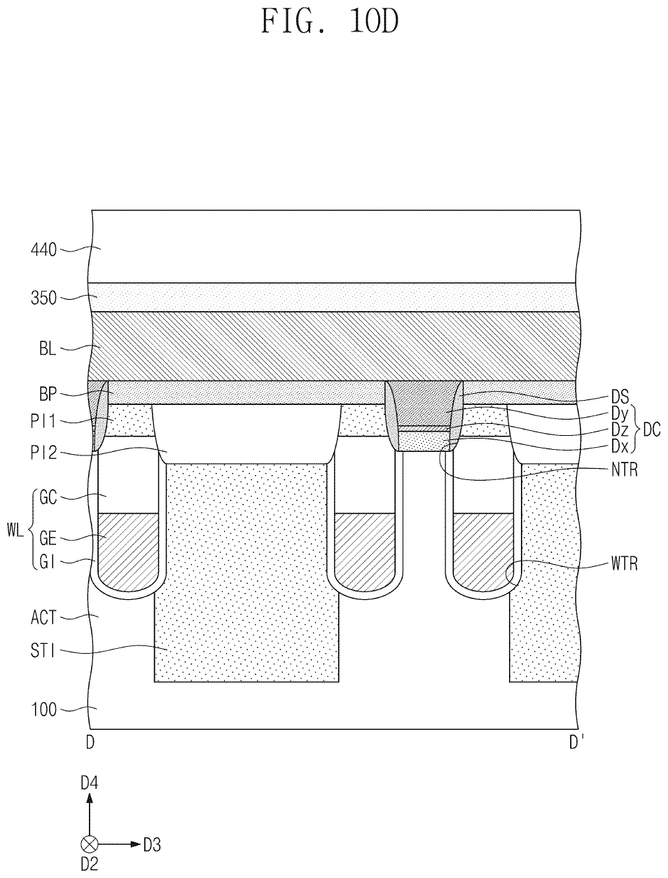

FIG. 9 is a plan view illustrating a semiconductor device according to various example embodiments of inventive concepts. FIGS. 10A, 10B, 10C and 10D are cross-sectional views corresponding to lines A-A′, B-B′, C-C′ and D-D′ of FIG. 9, respectively.

Referring to FIGS. 9 to 10D, each of closed spacers CS may include a first closed sub-spacer CSa and a second closed sub-spacer CSb. The first closed sub-spacer CSa may surround the storage node contact BC when viewed in a plan view. The second closed sub-spacer CSb may be disposed between the storage node contact BC and the first closed sub-spacer CSa and may surround the storage node contact BC in a plan view. For example, the first closed sub-spacer CSa and the second closed sub-spacer CSb may include different materials, e.g., may not include a common material. For example, each of the first closed sub-spacer CSa and the second closed sub-spacer CSb may include at least one of silicon oxide (SiO₂), silicon nitride (SiN), silicon oxycarbide (SiOC), and silicon oxy-carbonitride (SiOCN).

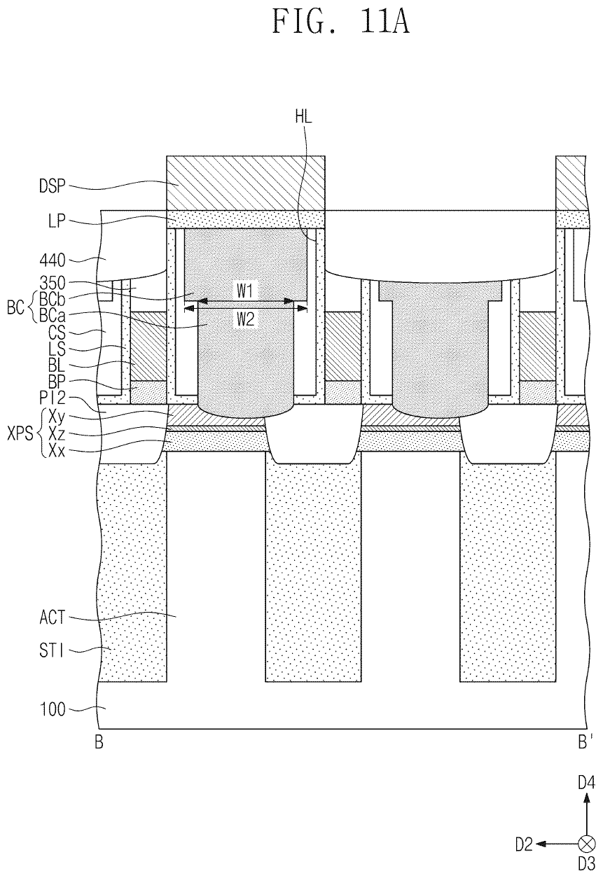

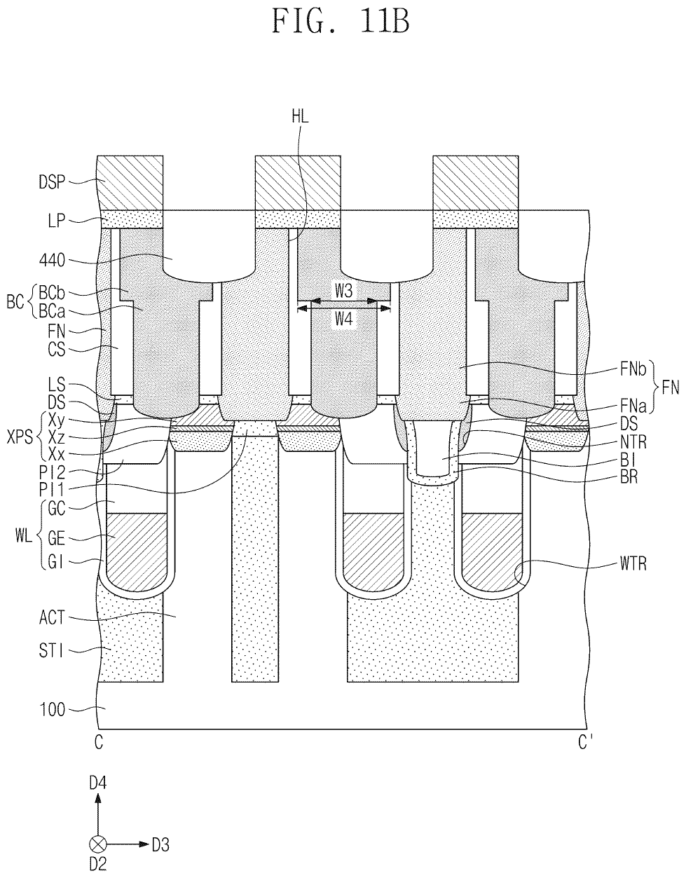

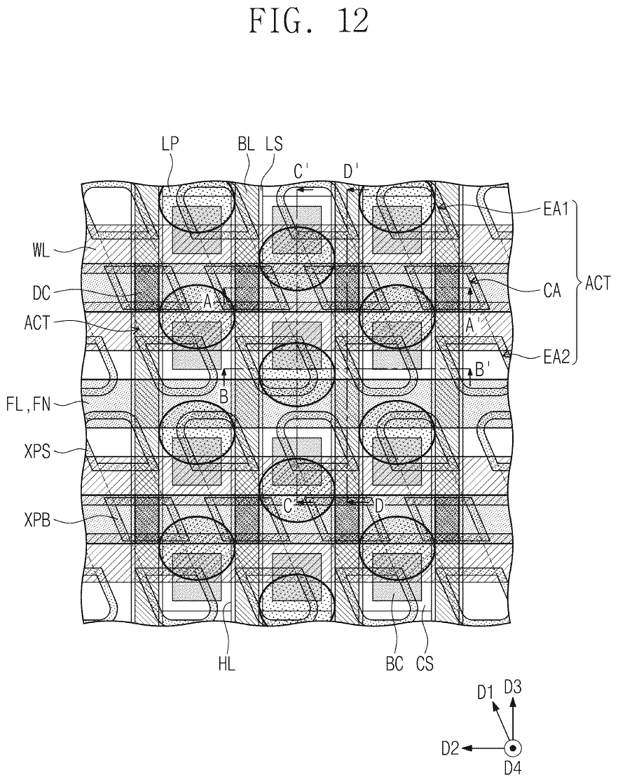

FIGS. 11A and 11B are cross-sectional views corresponding to the lines B-B′ and C-C′ of FIG. 1, respectively, to illustrate a semiconductor device according to various example embodiments of inventive concepts.

Referring to FIGS. 11A and 11B, a storage node contact BC may include a lower storage node contact BCa and an upper storage node contact BCb. A width of the lower storage node contact BCa may be different from a width of the upper storage node contact BCb. For example, as shown in FIG. 11A, a width W1 of the lower storage node contact BCa in the second direction D2 may be less than a width W2 of the upper storage node contact BCb in the second direction D2 at a level at which the lower storage node contact BCa and the upper storage node contact BCb are in contact with each other. For example, as shown in FIG. 11B, a width W3 of the lower storage node contact BCa in the third direction D3 may be less than a width W4 of the upper storage node contact BCb in the third direction D3 at a level at which the lower storage node contact BCa and the upper storage node contact BCb are in contact with each other. For example, a width of the storage node contact BC in the second or third direction D2 or D3 may be discontinuously changed at the level at which the lower storage node contact BCa and the upper storage node contact BCb are in contact with each other.

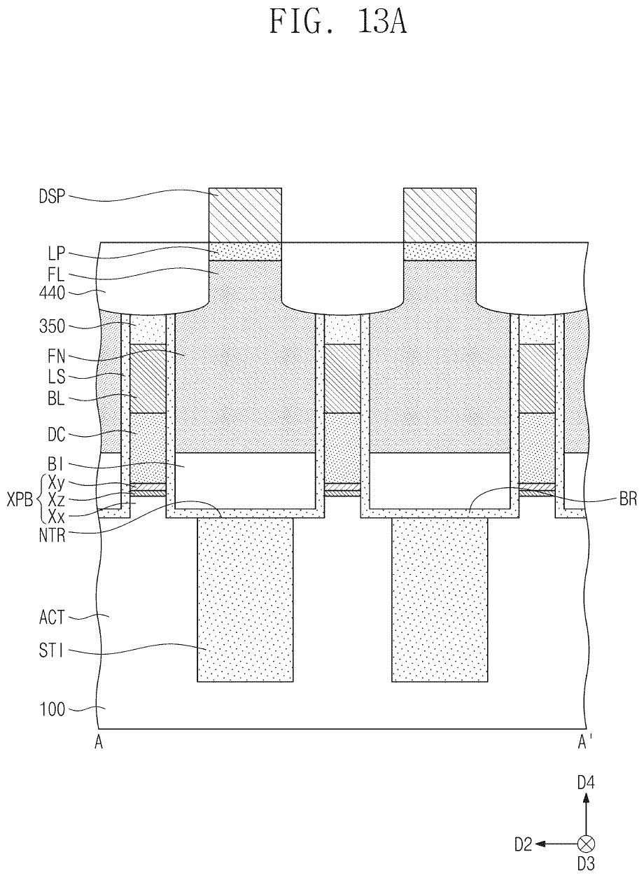

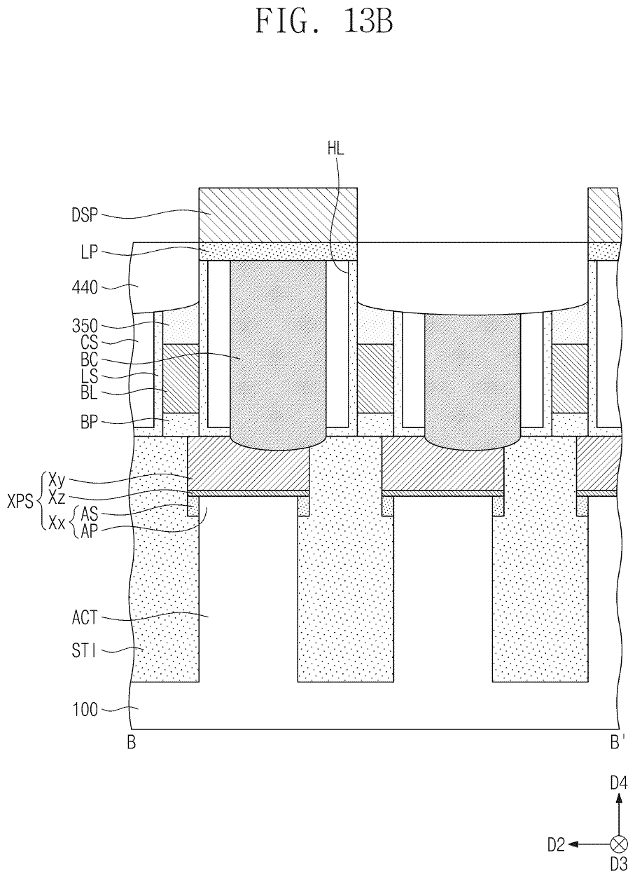

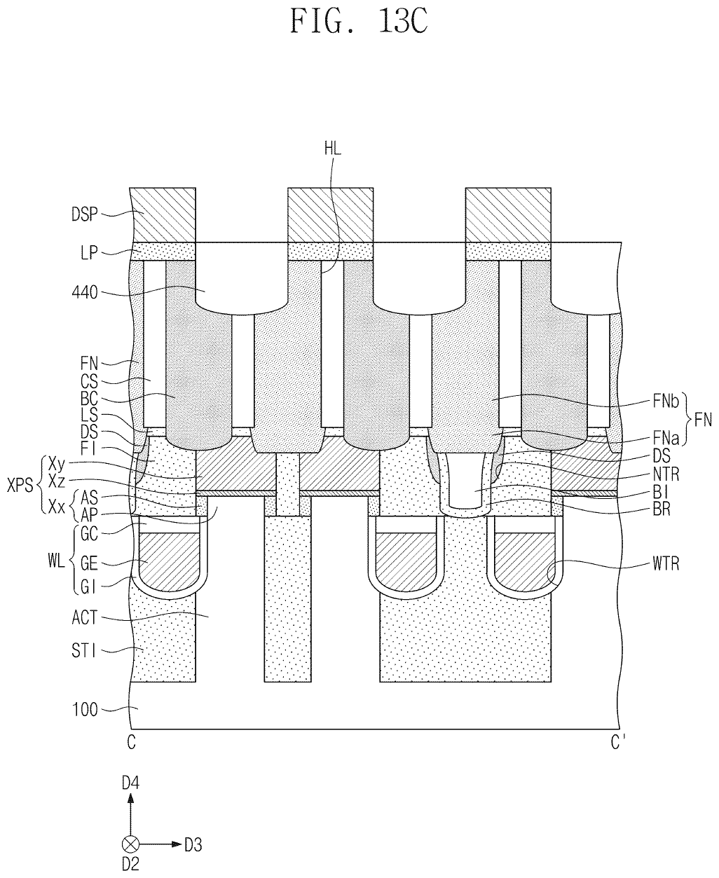

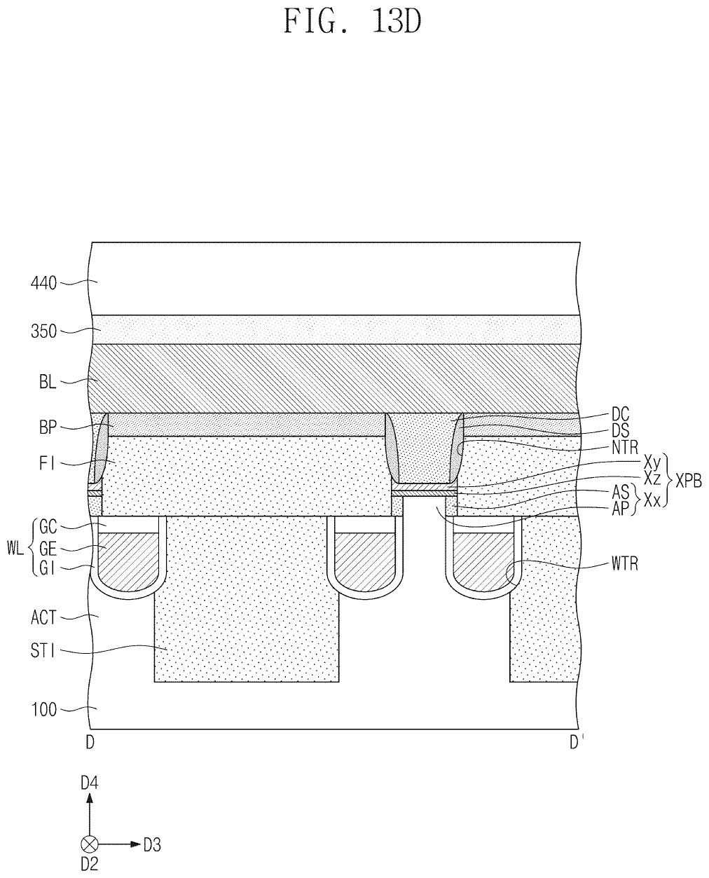

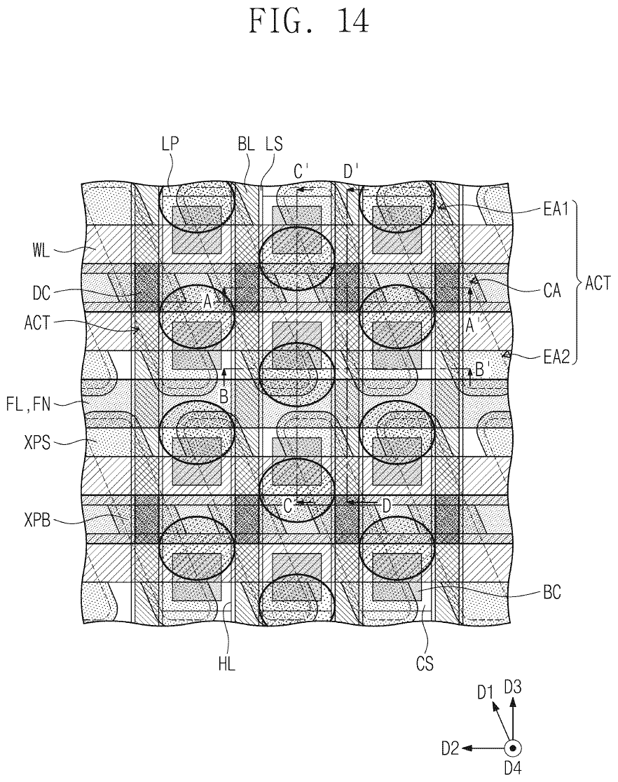

FIG. 12 is a plan view illustrating a semiconductor device according to various example embodiments of inventive concepts. FIGS. 13A, 13B, 13C and 13D are cross-sectional views corresponding to lines A-A′, B-B′, C-C′ and D-D′ of FIG. 12, respectively.

Referring to FIGS. 12 to 13D, each of a storage node pad XPS and a bit line node pad XPB may include a lower pad Xx, an upper pad Xy on the lower pad Xx, and an ohmic pad Xz between the lower and upper pads Xx and Xy. The lower pad Xx may include an active pad AP and an active spacer AS. The active pad AP may include a portion of the active pattern ACT, which is surrounded by the active spacer AS. With reference to some example embodiments, the active pattern ACT may be defined as another portion of the active pattern ACT except the portion of the active pattern ACT unless otherwise stated, for the purpose of ease and convenience in explanation. The active spacer AS may be disposed on the word line WL to cover a portion of the word line WL. The upper pad Xy may cover the active pad AP and the active spacer AS.

For example, the active pad AP may include silicon (e.g., single-crystalline silicon). For example, the active spacer AS may include silicon (e.g., single-crystalline silicon, polysilicon, etc.). For example, the bit line node contact DC may include at least one of silicon (e.g., doped polysilicon) and a metal material (e.g., one or more of Ti, Mo, W, Cu, Al, Ta, Ru, Ir, etc.), and for example, the bit line node contact DC may include the metal material.

A filling insulation pattern FI may be provided on the device isolation pattern STI. The filling insulation pattern FI may surround the storage node pad XPS and the bit line node pad XPB. The filling insulation pattern FI may cover top surfaces of the device isolation pattern STI and the word line WL. The filling insulation pattern FI may include an insulating material (e.g., at least one of silicon oxide (SiO₂) and silicon nitride (SiN)).

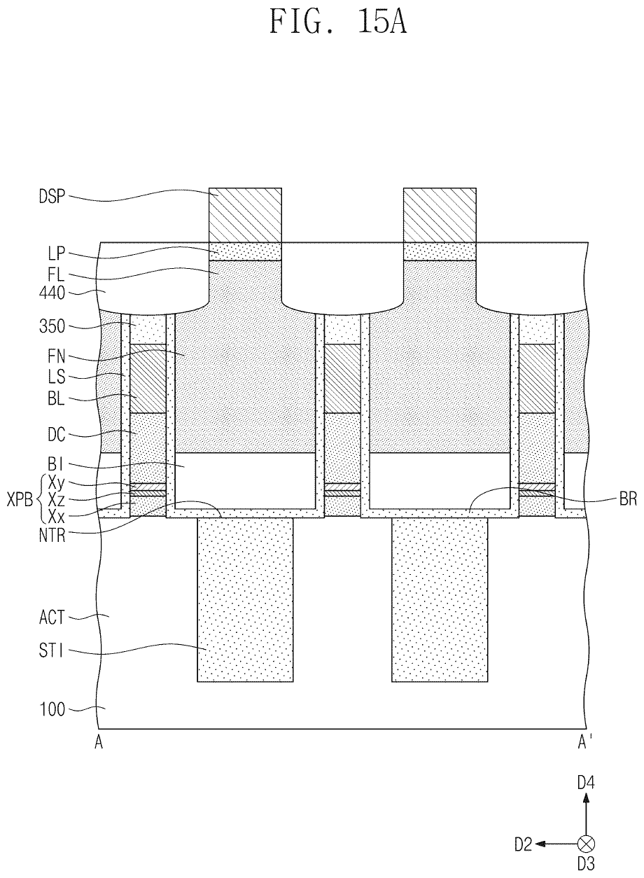

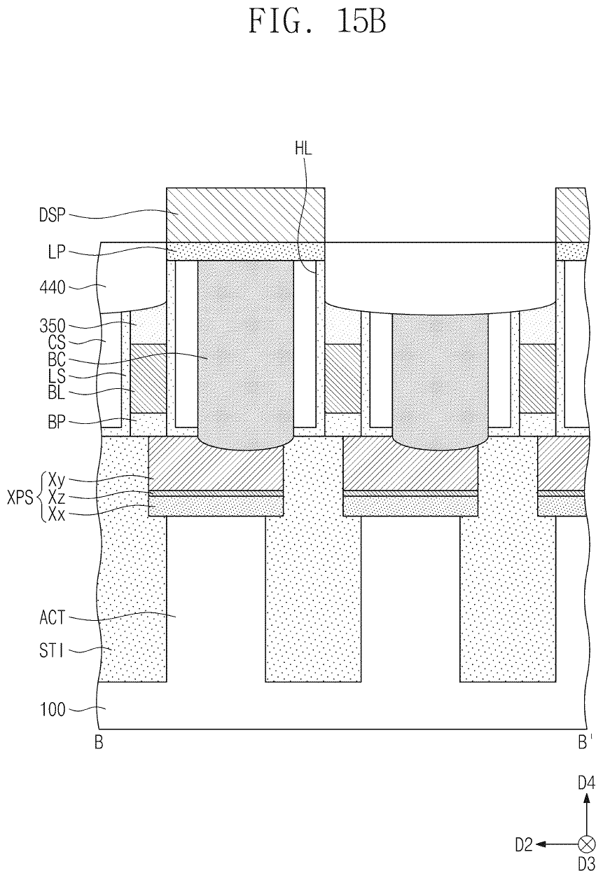

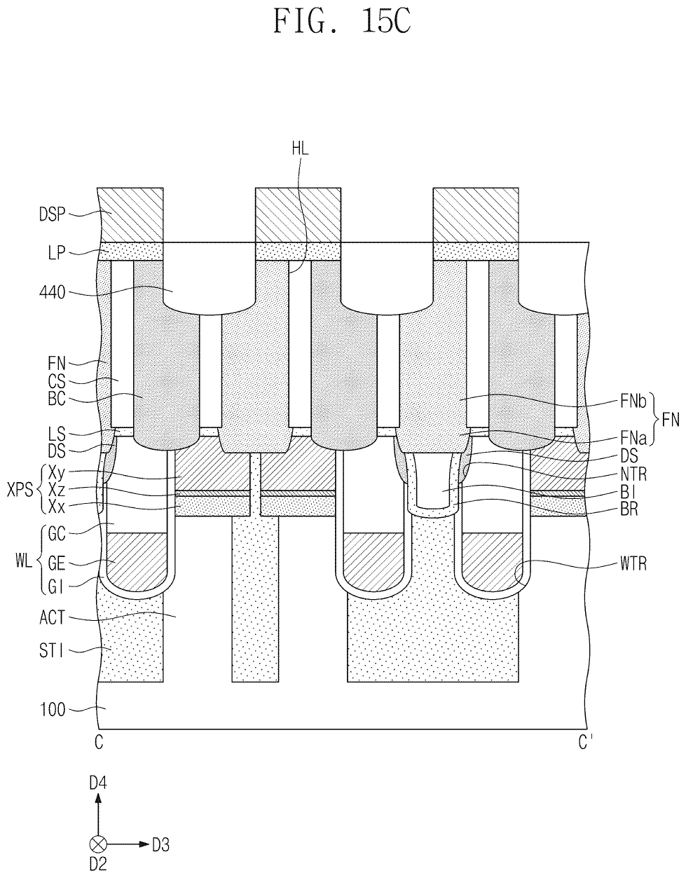

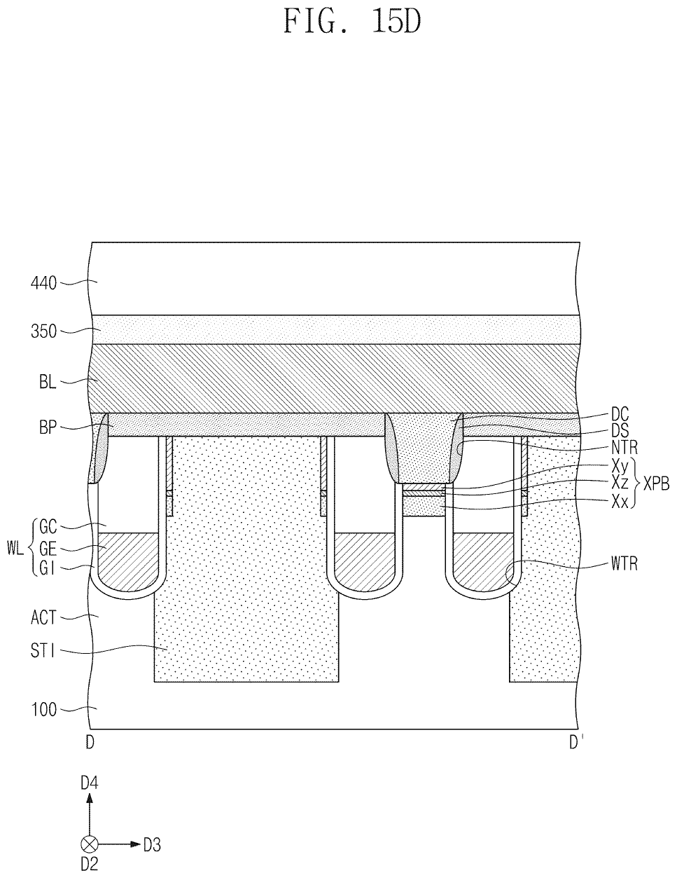

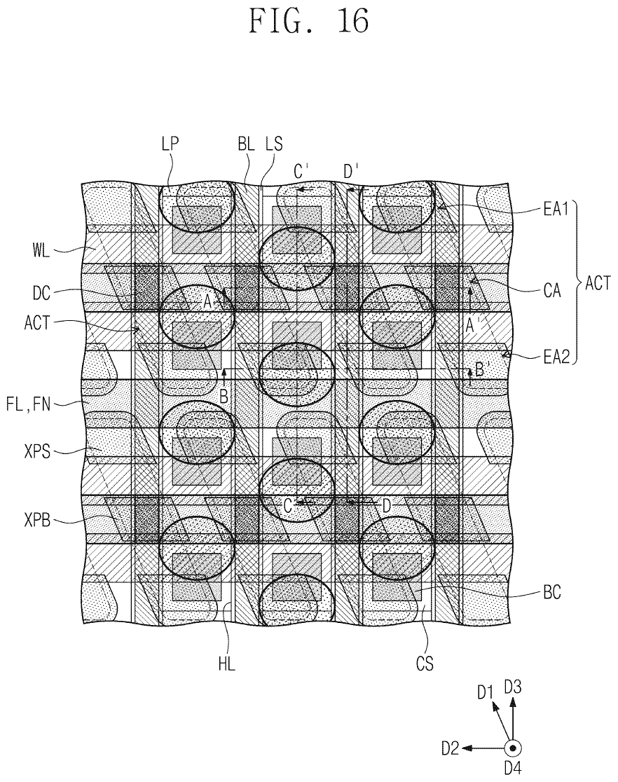

FIG. 14 is a plan view illustrating a semiconductor device according to various example embodiments of inventive concepts. FIGS. 15A, 15B, 15C and 15D are cross-sectional views corresponding to lines A-A′, B-B′, C-C′ and D-D′ of FIG. 14, respectively.

Referring to FIGS. 14 to 15D, a storage node pad XPS and a bit line node pad XPB may be surrounded by the device isolation pattern STI. The storage node pad XPS and the bit line node pad XPB may penetrate the device isolation pattern STI in the fourth direction D4. The storage node pad XPS may cover a top surface of the first or second edge portion EA1 or EA2 of the active pattern ACT. The bit line node pad XPB may cover a top surface of the center portion CA of the active pattern ACT.

The word line WL may penetrate the storage node pad XPS and the bit line node pad XPB in the second direction D2. For example, the storage node pad XPS and the bit line node pad XPB may not vertically overlap with the word line WL. For example, the bit line node contact DC may include at least one of silicon (e.g., doped polysilicon) and a metal material (e.g., one or more of Ti, Mo, W, Cu, Al, Ta, Ru, Ir, etc.), and in some example embodiments, the bit line node contact DC may include the metal material.

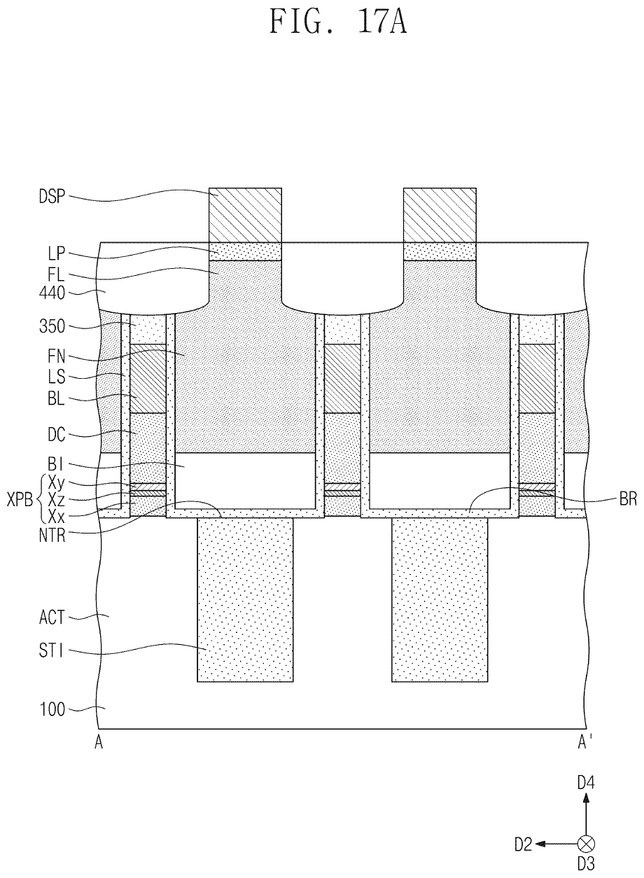

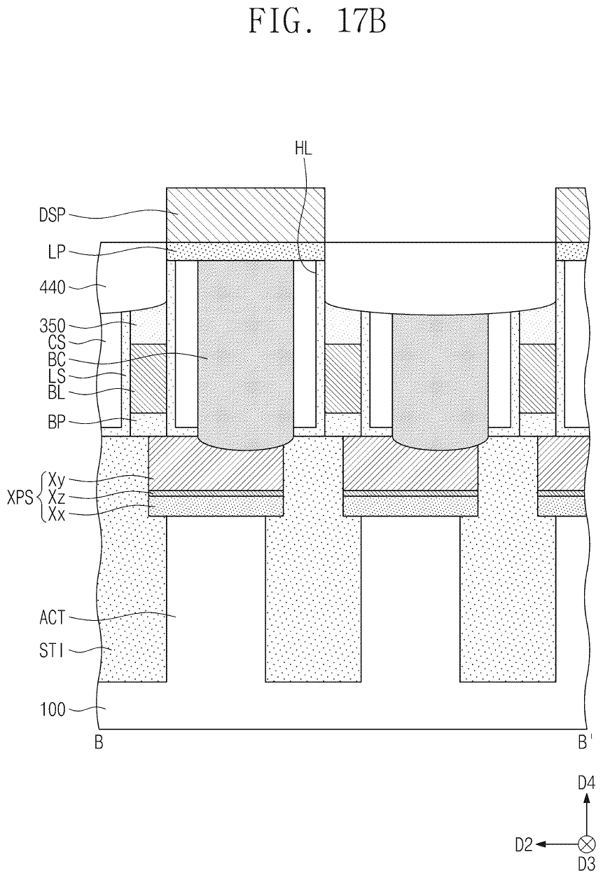

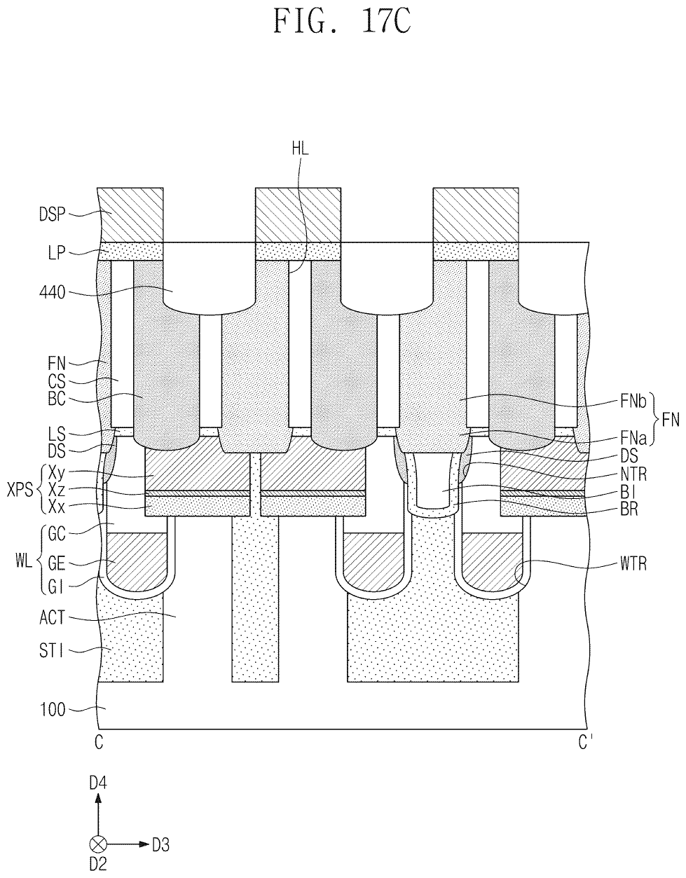

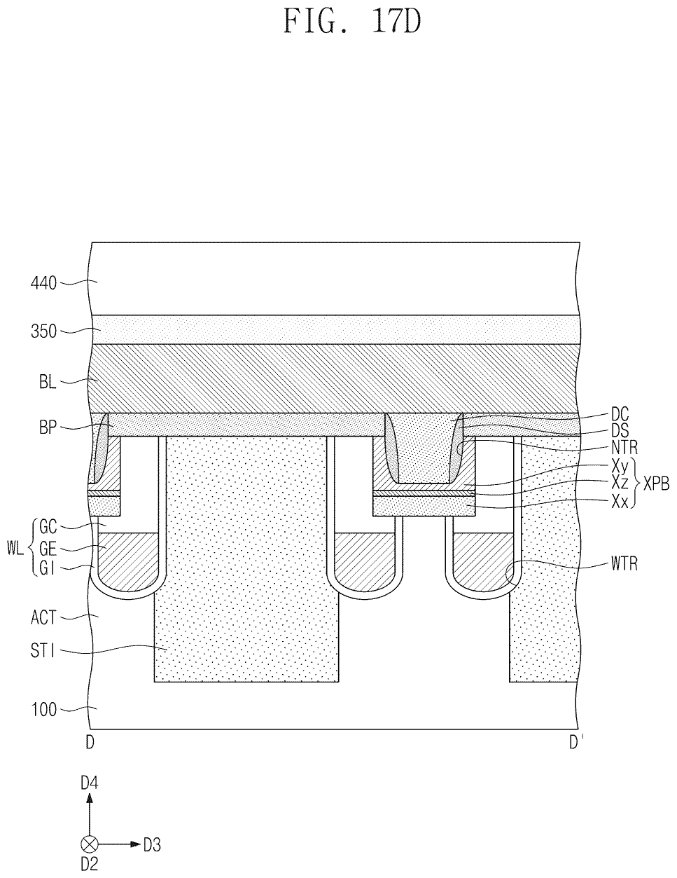

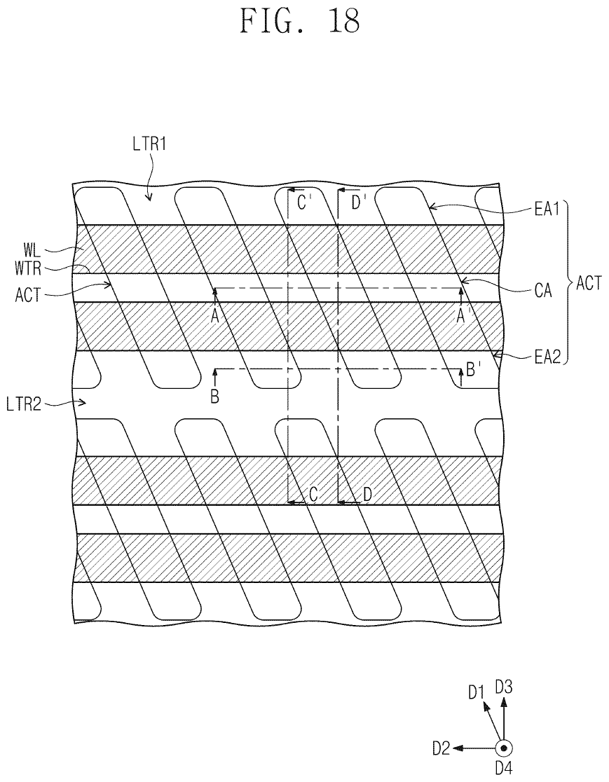

FIG. 16 is a plan view illustrating a semiconductor device according to various example embodiments of inventive concepts. FIGS. 17A, 17B, 17C and 17D are cross-sectional views corresponding to lines A-A′, B-B′, C-C′ and D-D′ of FIG. 16, respectively.

Referring to FIGS. 16 to 17D, the storage node pad XPS and the bit line node pad XPB may be surrounded by the device isolation pattern STI. The storage node pad XPS and the bit line node pad XPB may penetrate the device isolation pattern STI in the fourth direction D4. The storage node pad XPS may cover the top surface of the first or second edge portion EA1 or EA2 of the active pattern ACT. The bit line node pad XPB may cover the top surface of the center portion CA of the active pattern ACT.

The storage node pad XPS and the bit line node pad XPB may be disposed on the word line WL to cover portions of the word line WL. For example, the storage node pad XPS and the bit line node pad XPB may vertically overlap with the portions of the word line WL. For example, the bit line node contact DC may include at least one of silicon (e.g., doped polysilicon) and a metal material (e.g., one or more of Ti, Mo, W, Cu, Al, Ta, Ru, Ir, etc.), and for example, the bit line node contact DC may include the metal material.

Hereinafter, methods of manufacturing or fabricating semiconductor devices according to various example embodiments of inventive concepts will be described with reference to FIGS. 18 to 50D. However, the descriptions to the same features as mentioned above will be omitted and differences from the aforementioned features will be mainly described, for the purpose of ease and convenience in explanation.

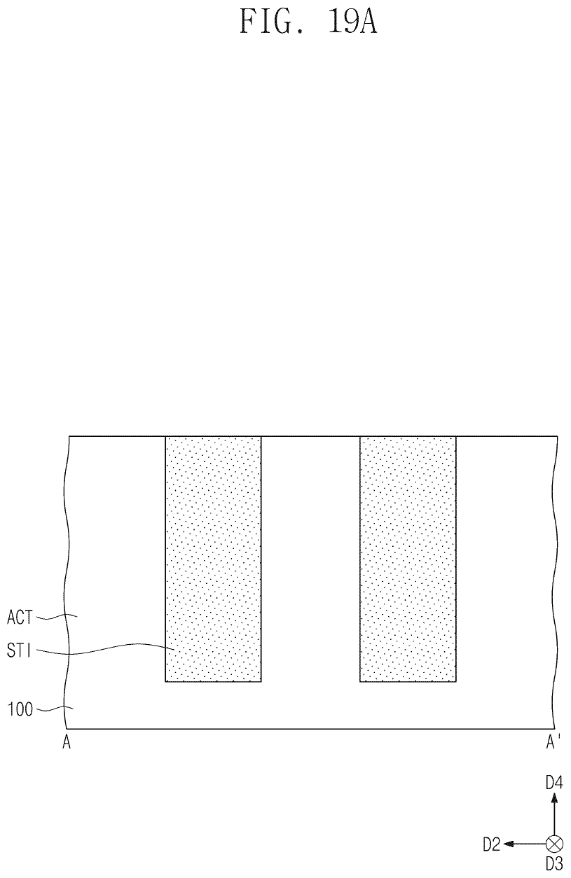

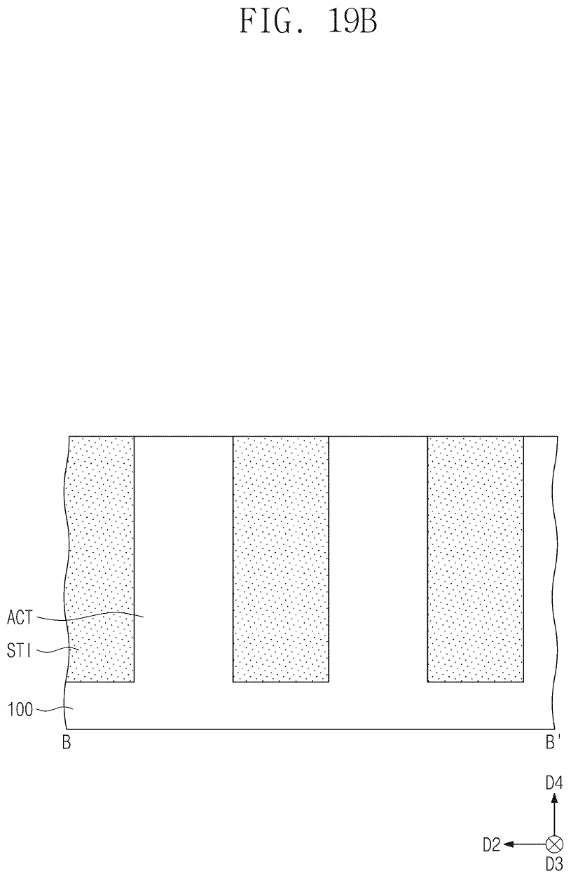

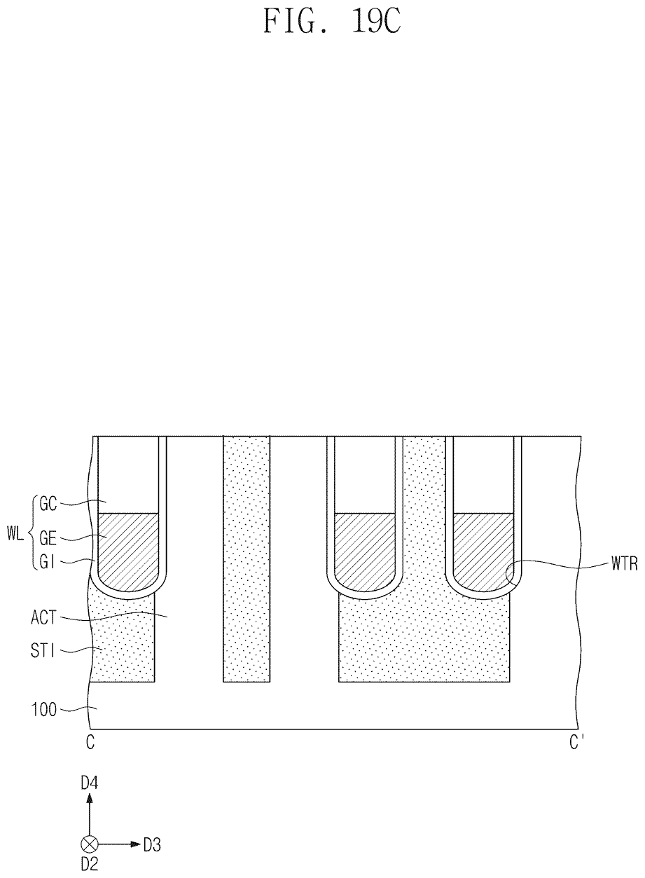

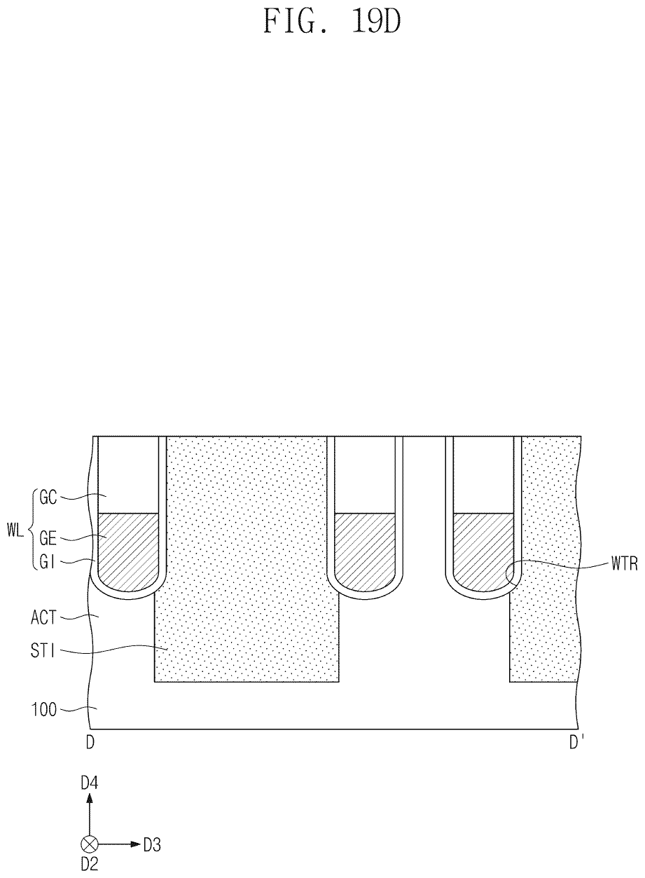

FIGS. 18 to 29D are views illustrating a method of manufacturing the semiconductor device of FIGS. 1 to 3D. More particularly, FIGS. 18, 20, 22, 24, 26 and 28 are plan views illustrating a method of manufacturing the semiconductor device described with reference to FIGS. 1 to 3D. FIGS. 19A, 21A, 23A, 25A, 27A and 29A are cross-sectional views corresponding to lines A-A′ of FIGS. 18, 20, 22, 24, 26 and 28, respectively. FIGS. 19B, 21B, 23B, 25B, 27B and 29B are cross-sectional views corresponding to lines B-B′ of FIGS. 18, 20, 22, 24, 26 and 28, respectively. FIGS. 19C, 21C, 23C, 25C, 27C and 29C are cross-sectional views corresponding to lines C-C′ of FIGS. 18, 20, 22, 24, 26 and 28, respectively. FIGS. 19D, 21D, 23D, 25D, 27D and 29D are cross-sectional views corresponding to lines D-D′ of FIGS. 18, 20, 22, 24, 26 and 28, respectively.

Referring to FIGS. 18 to 19D, a substrate 100 may be prepared. The substrate may or may not be doped and/or may or may not have impurity regions defined. A removal process such as an etching process may be performed on the substrate 100, and thus active patterns ACT may be formed. A trench region may be formed between the active patterns ACT.

The removal process may include forming mask patterns on the substrate 100 by using an exposure process, and etching the substrate 100 using the mask patterns as etch masks. In some example embodiments, the exposure process and the etching process may be alternately repeated a plurality of times; however, example embodiments are not limited thereto. For example, line patterns and first line trench regions LTR1, which extend in the first direction D1, may be formed using first exposure and etching processes. Thereafter, second exposure and etching processes may be performed on the line patterns. By the second exposure and etching processes, second line trench regions LTR2 extending in the second direction D2 may be formed, and each of the line patterns may be divided into the active patterns ACT arranged in a line in the first direction D1.

A device isolation pattern STI may be formed to fill the first and second line trench regions LTR1 and LTR2. The formation of the device isolation pattern STI may include performing one or more of a physical vapor deposition (PVD) process, a chemical vapor deposition (CVD) process, a spin-on dielectric (SOD) process, or an atomic layer deposition (ALD) process.

Thereafter, a word line WL may be formed to intersect the active pattern ACT and the device isolation pattern STI. The formation of the word line WL may include forming a mask pattern on the active pattern ACT and the device isolation pattern STI, performing an anisotropic etching process such as a dry-etching process using the mask pattern as an etch mask to form a word line trench region WTR, and filling the word line trench region WTR with the word line WL.

For example, the filling of the word line trench region WTR with the word line WL may include conformally depositing a gate dielectric pattern GI on an inner surface of the word line trench region WTR, filling the word line trench region WTR with a conductive layer, performing an etch-back process and/or a polishing process on the conductive layer to form a gate electrode GE, and forming a gate capping pattern GC filling a remaining portion of the word line trench region WTR on the gate electrode GE.

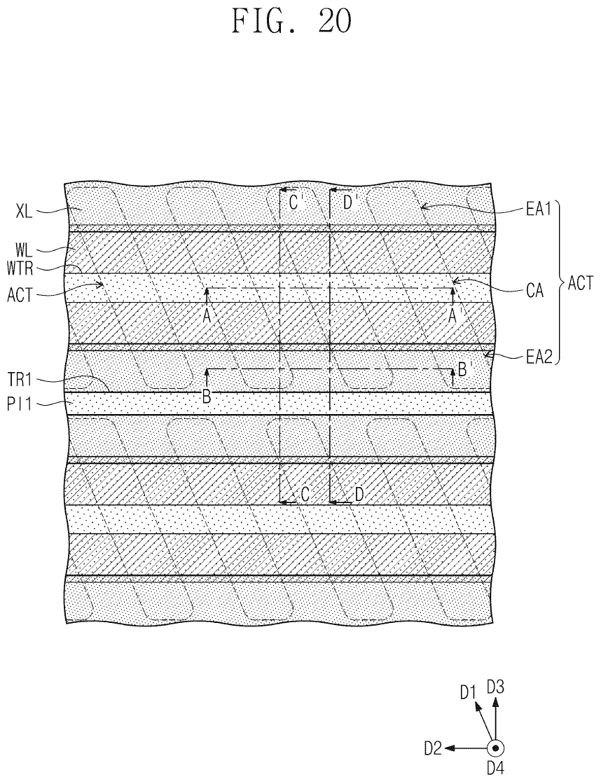

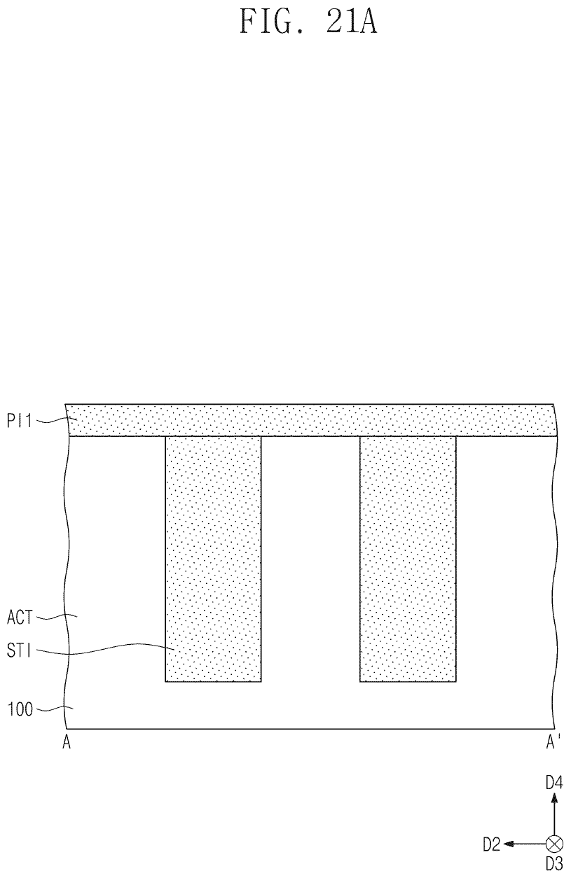

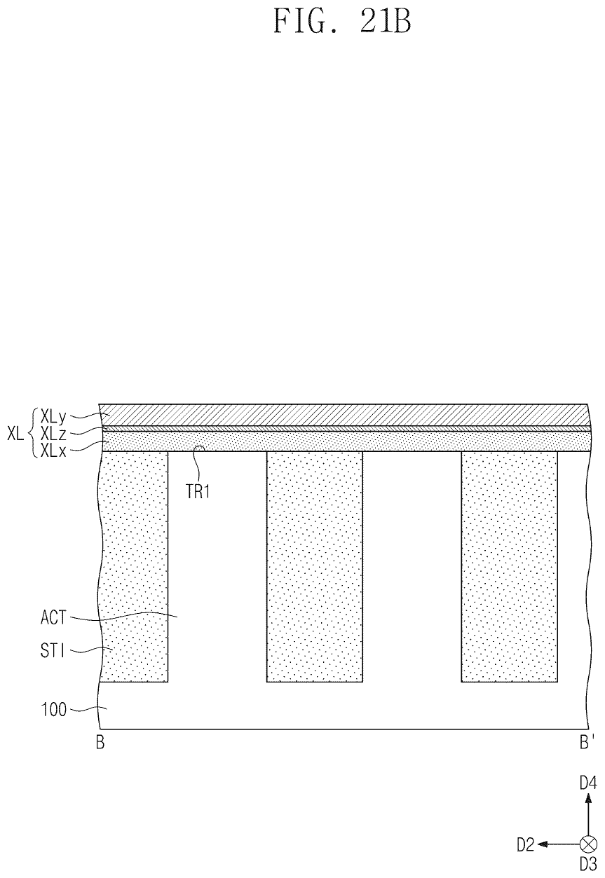

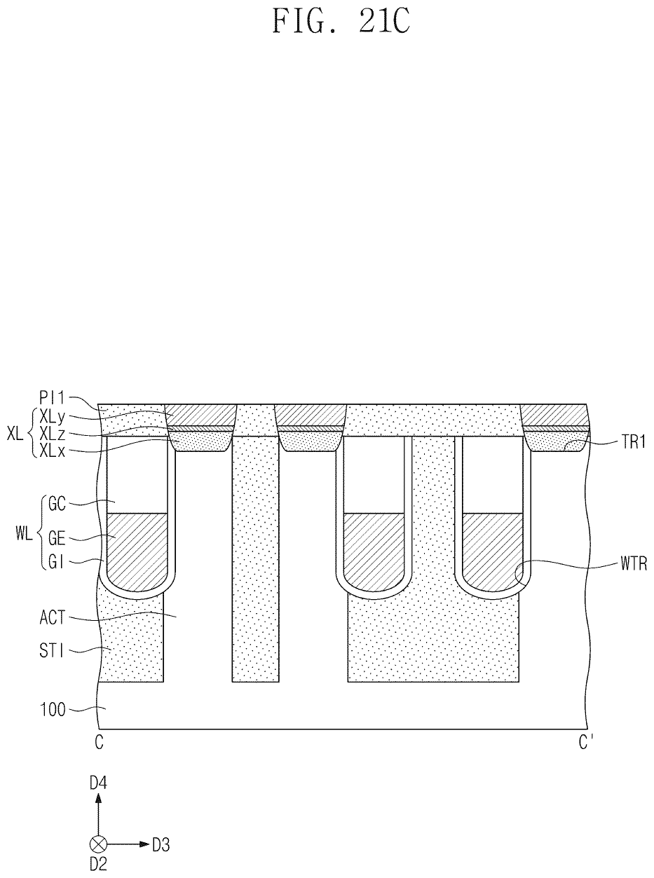

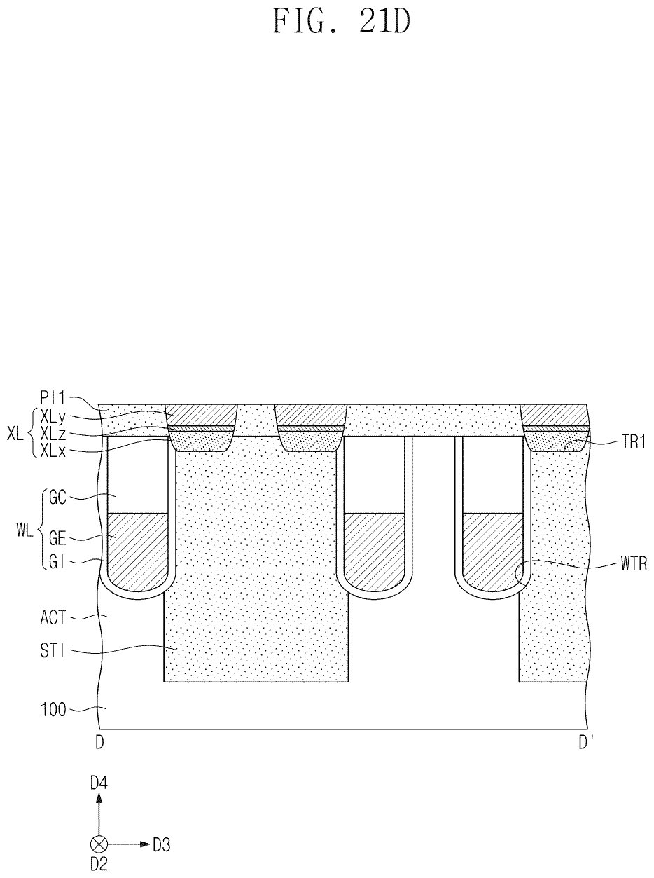

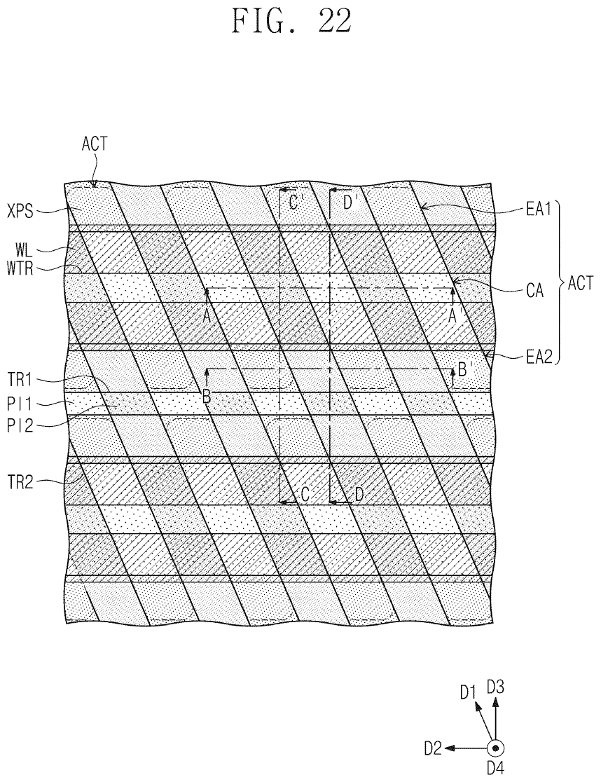

Referring to FIGS. 20 to 21D, a first pad insulating pattern PI1 may be formed on the active pattern ACT and the device isolation pattern STI. The formation of the first pad insulating pattern PI1 may include forming a first pad insulating layer (not shown) on an entire top surface of the substrate 100, and etching the first pad insulating layer by an anisotropic etching process to form first pad insulating patterns PI1 and first trench regions TR1. Each of the first pad insulating patterns PI1 and the first trench regions TR1 may extend in the second direction D2. The first and second edge portions EA1 and EA2 of the active patterns ACT may be exposed by the first trench regions TR1.

A width of the first trench region TR1 in the third direction D3 may be changed depending on a level such as a vertical level. For example, the width of the first trench region TR1 in the third direction D3 may decrease as a level decreases.

Pad lines XL may be formed to fill the first trench regions TR1, respectively. The pad lines XL may extend in the second direction D2 in the first trench regions TR1. The pad lines XL may cover the exposed first and second edge portions EA1 and EA2 of the active patterns ACT. Each of the pad lines XL may include a lower pad line XLx, an upper pad line XLy on the lower pad line XLx, and an ohmic pad line XLz between the lower and upper pad lines XLx and XLy.

The pad lines XL may be formed using an engraving process. For example, the first pad insulating layer may be etched to form the first pad insulating patterns PI1 and the first trench regions TR1, and the first pad insulating patterns PI1 may be used as a mold for forming the pad lines XL. Since the first trench regions TR1 are formed by etching the first pad insulating layer, the width of the first trench region TR1 in the third direction D3 may be changed depending on a level. For example, the width of the first trench region TR1 in the third direction D3 may decrease as a level decreases. Thus, a width of the pad line XL in the third direction D3 may also decrease as a level decreases.

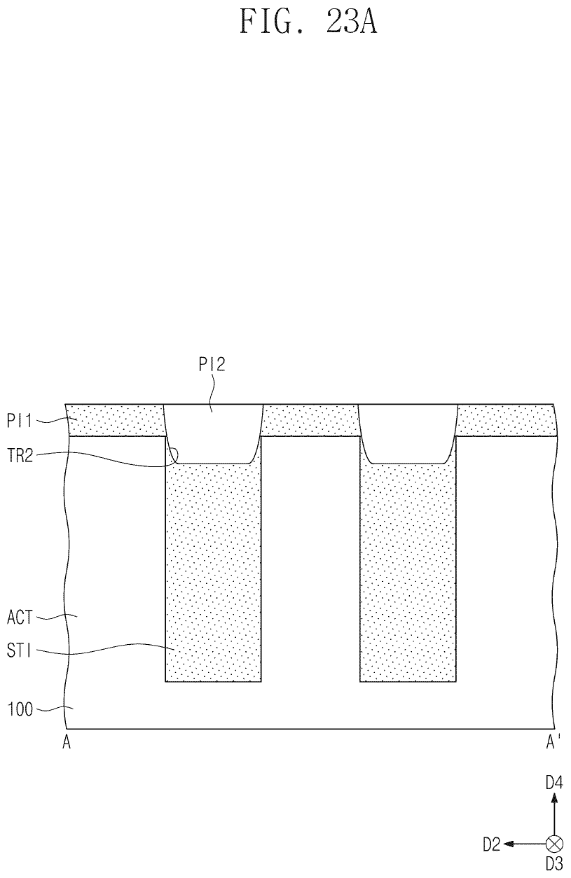

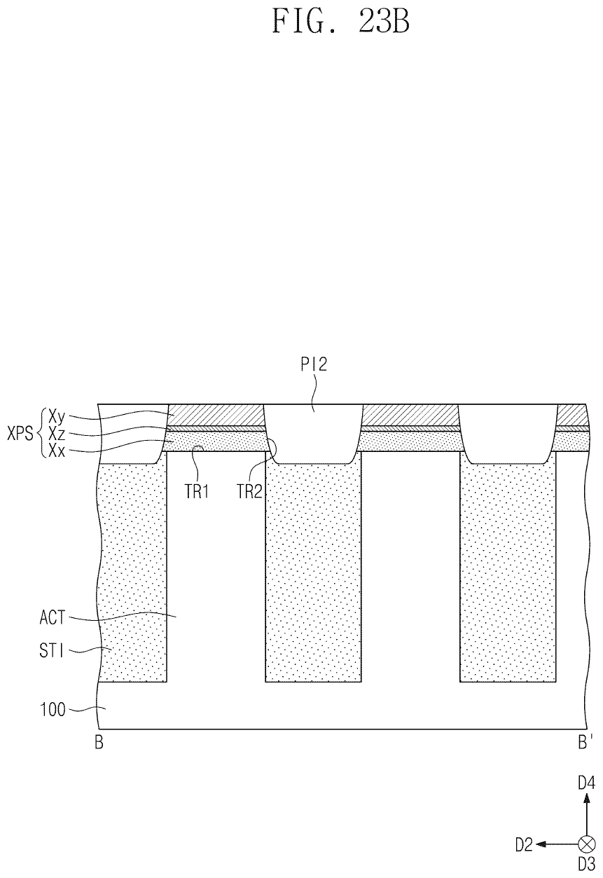

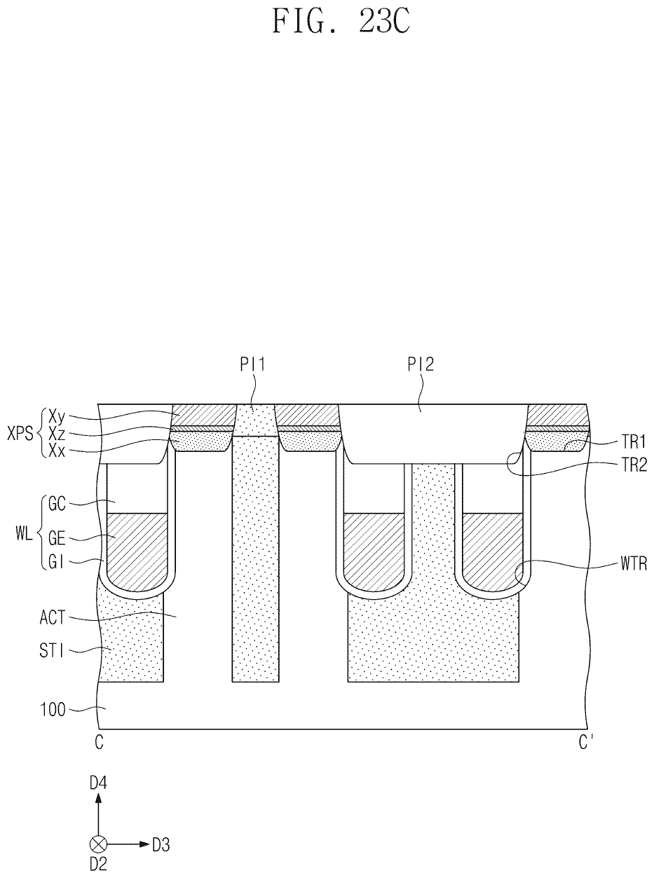

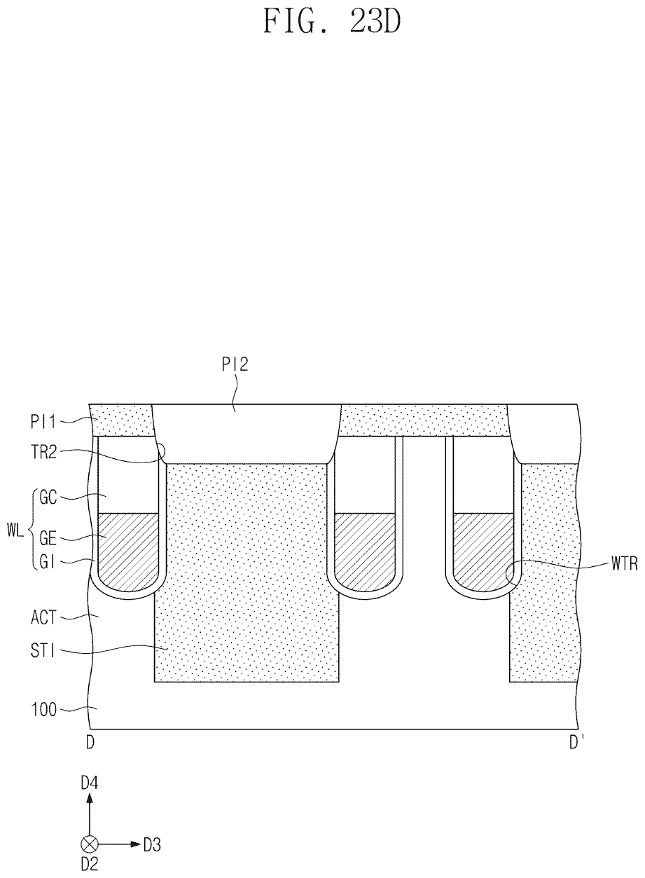

Referring to FIGS. 22 to 23D, storage node pads XPS may be formed by etching the pad lines XL. The etching of the pad lines XL may include forming second trench regions TR2 dividing each of the pad lines XL into a plurality of the storage node pads XPS. The second trench regions TR2 may extend in the first direction D1. The second trench regions TR2 may intersect the first pad insulating pattern PI1 in the first direction D1.

After the etching process, remaining portions of the lower, upper and ohmic pad lines XLx, XLy and XLz of the pad line XL may be formed into a lower pad Xx, an upper pad Xy and an ohmic pad Xz of the storage node pad XPS, respectively.

Second pad insulating patterns PI2 may be formed to fill the second trench regions TR2, respectively. The second pad insulating patterns PI2 may extend in the first direction D1 in the second trench regions TR2. The storage node pads XPS may cover the first and second edge portions EA1 and EA2 of the active patterns ACT.

The storage node pads XPS may be formed by an embossing process using the pad lines XL. In other words, the pad lines XL may be first formed, and then, each of the pad lines XL may be etched to form the storage node pads XPS. Since the second trench regions TR2 are formed by etching the pad lines XL, a width of the second trench region TR2 in the second direction D2 may be changed depending on a level. For example, the width of the second trench region TR2 in the second direction D2 may decrease as a level decreases. Thus, a width of the second pad insulating pattern PI2 in the second direction D2 may also decrease as a level decreases. On the contrary, a width of the storage node pad XPS in the second direction D2 may increase as a level (a vertical level) decreases.

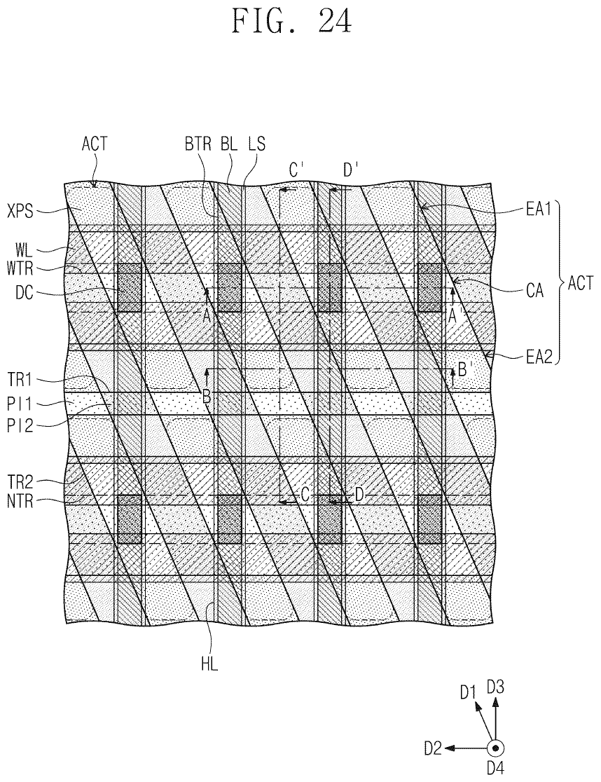

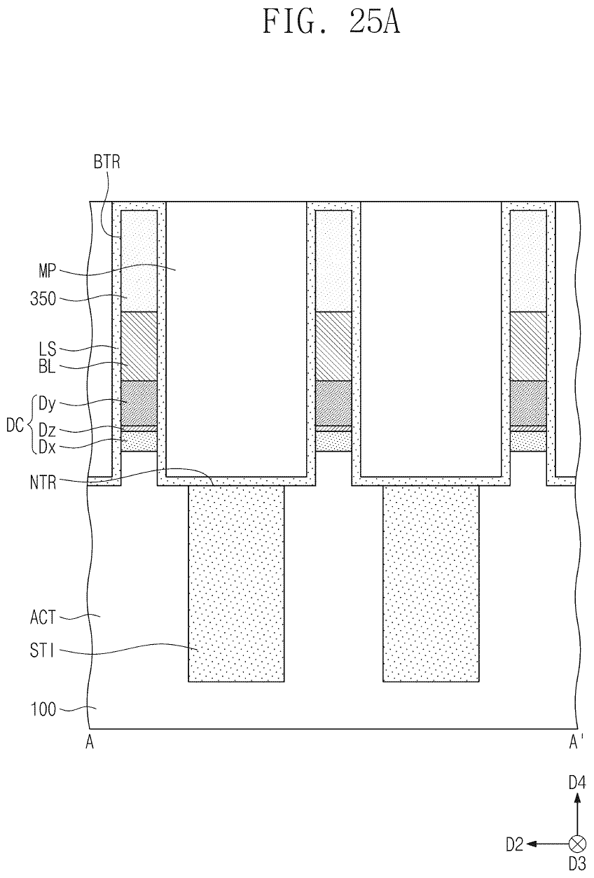

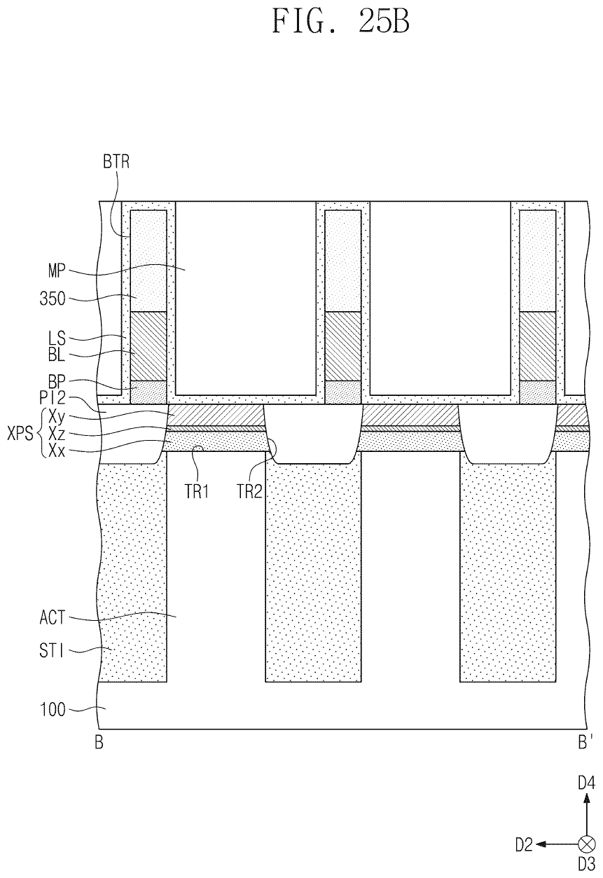

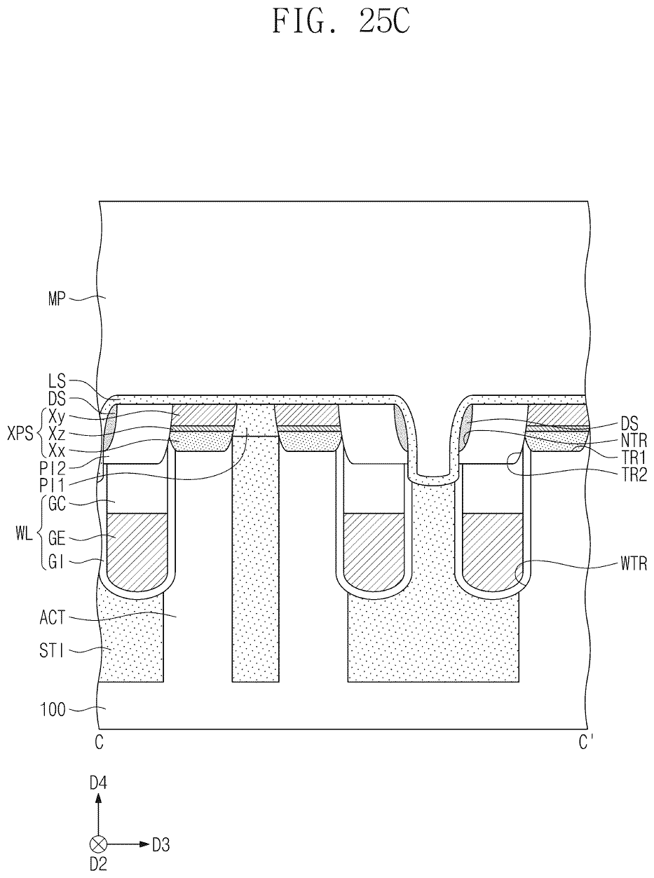

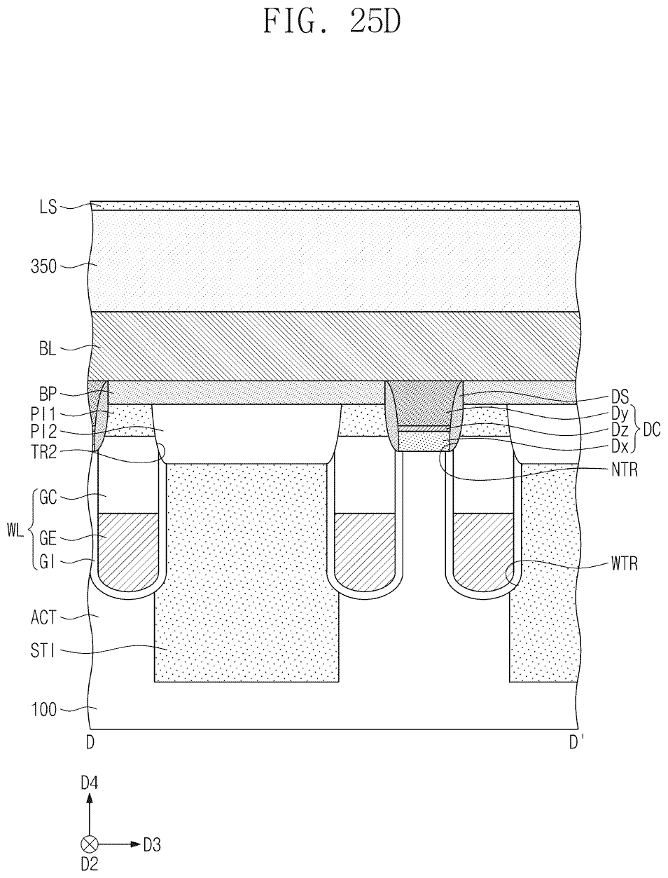

Referring to FIGS. 24 to 25D, a buffer layer (not shown) may be formed to cover an entire top surface of the substrate 100. For example, the buffer layer may include two or more stacked buffer layers, but embodiments of inventive concepts are not limited thereto.

Thereafter, the buffer layer and the first pad insulating pattern PI1 may be etched to form node trench regions NTR. The node trench regions NTR may extend in the second direction D2 and may be spaced apart from each other in the third direction D3. The node trench regions NTR may be formed on the center portions CA of the active patterns ACT. The center portions CA of the active patterns ACT may be exposed by the node trench regions NTR.

Bit line node contact spacers DS may be formed to conformally cover inner side surfaces of the node trench regions NTR. A bit line node contact layer (not shown) may be formed to fill the node trench regions NTR. A bit line layer (not shown) and a bit line capping layer (not shown) may be sequentially formed to cover an entire top surface of the substrate 100.

Thereafter, a bit line capping pattern 350, a bit line BL and a bit line node contact DC may be formed using an etching process. The bit line capping pattern 350, the bit line BL and the bit line node contact DC may be formed from the bit line capping layer, the bit line layer and the bit line node contact layer by the etching process, respectively. In this process, an upper portion of the buffer layer may also be etched.

In the formation of the bit lines BL, bit line trench regions BTR may be formed between the bit lines BL. The bit line trench regions BTR may be spaced apart from each other in the second direction D2 and may extend in the third direction D3. Bottom surfaces of the node trench regions NTR and a portion of the buffer layer may be exposed by the bit line trench regions BTR.

A line spacer LS may be formed on a side surface of the bit line BL. The formation of the line spacer LS may include removing the exposed portion of the buffer layer to form a buffer pattern BP, and conformally depositing the line spacer LS on an entire top surface of the substrate 100. In the process of forming the buffer pattern BP, the exposed bottom surface of the node trench region NTR may further be recessed, and the storage node pad XPS may be exposed. The line spacer LS may cover inner surfaces of the bit line trench regions BTR, the exposed bottom surfaces of the node trench regions NTR, and the bit line node contact spacers DS.

Thereafter, a mold pattern MP may be formed between the bit lines BL adjacent to each other. The mold pattern MP may fill the bit line trench region BTR. The mold pattern MP may be provided in plurality. The mold patterns MP may extend in the third direction D3 and may be spaced apart from each other in the second direction D2. For example, the mold pattern MP may include at least one of silicon oxide (SiO₂) and carbon (C).

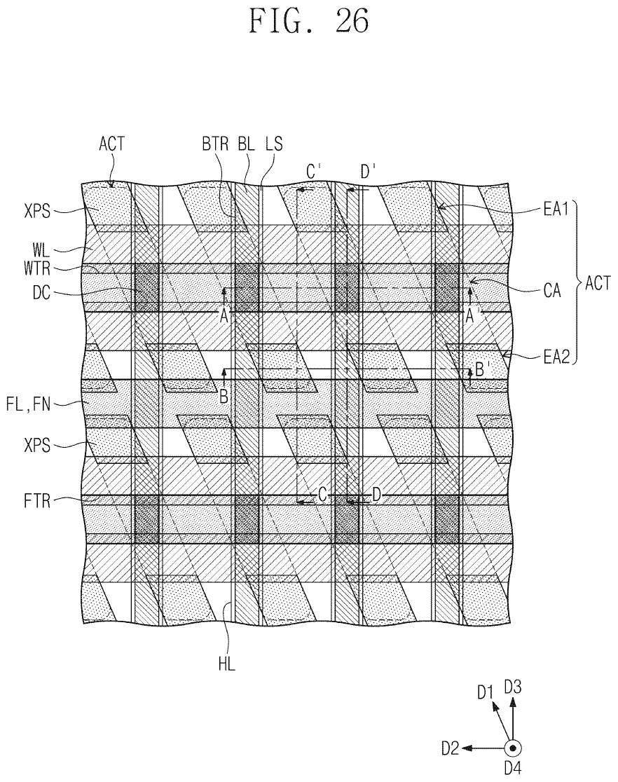

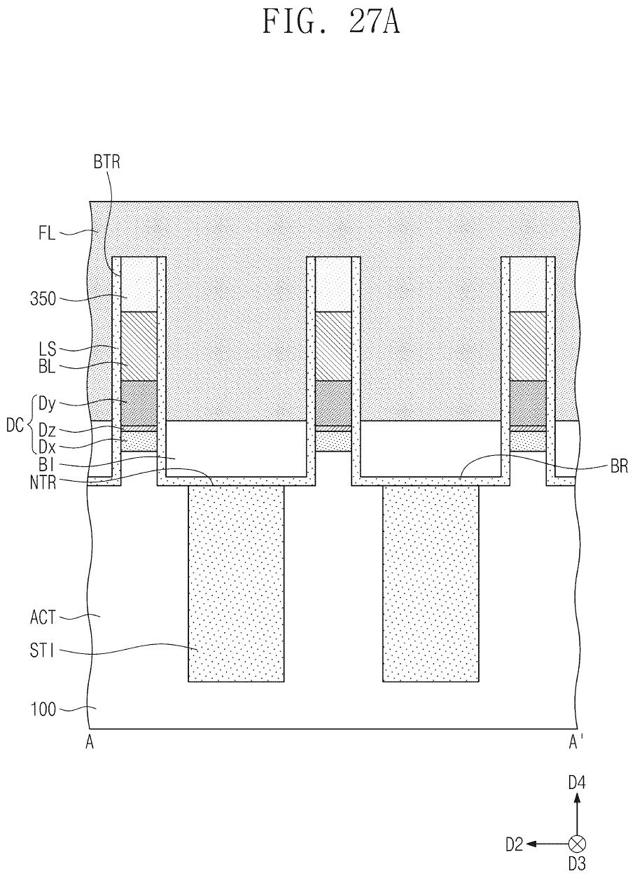

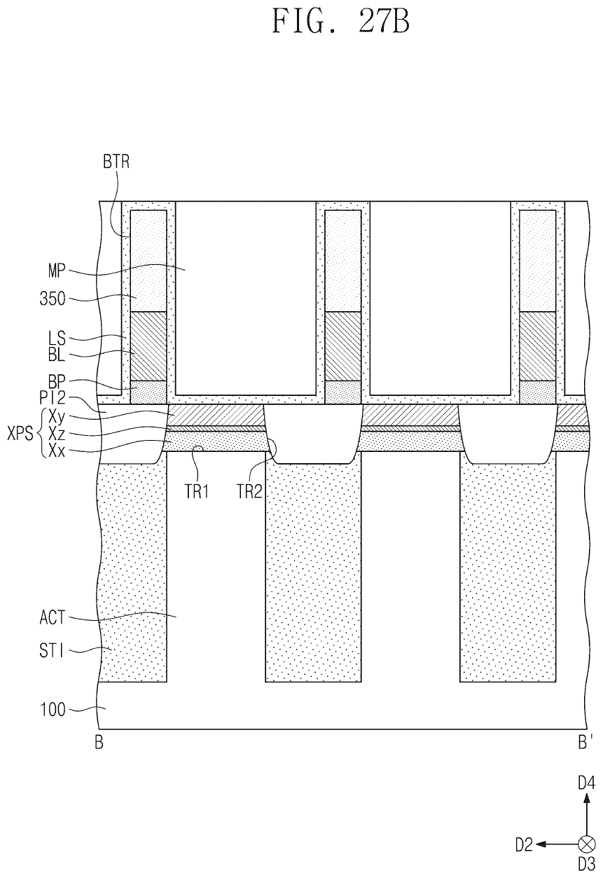

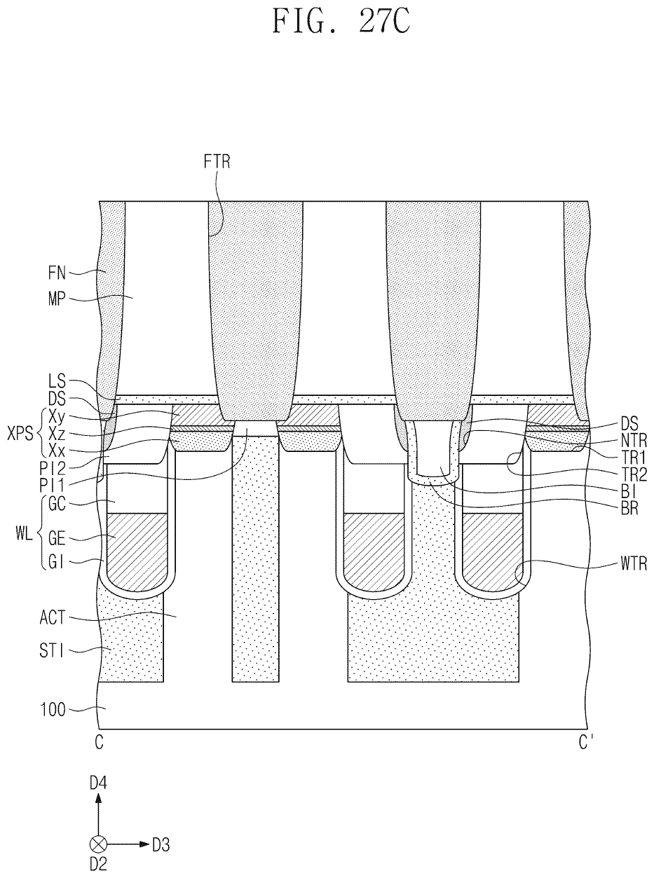

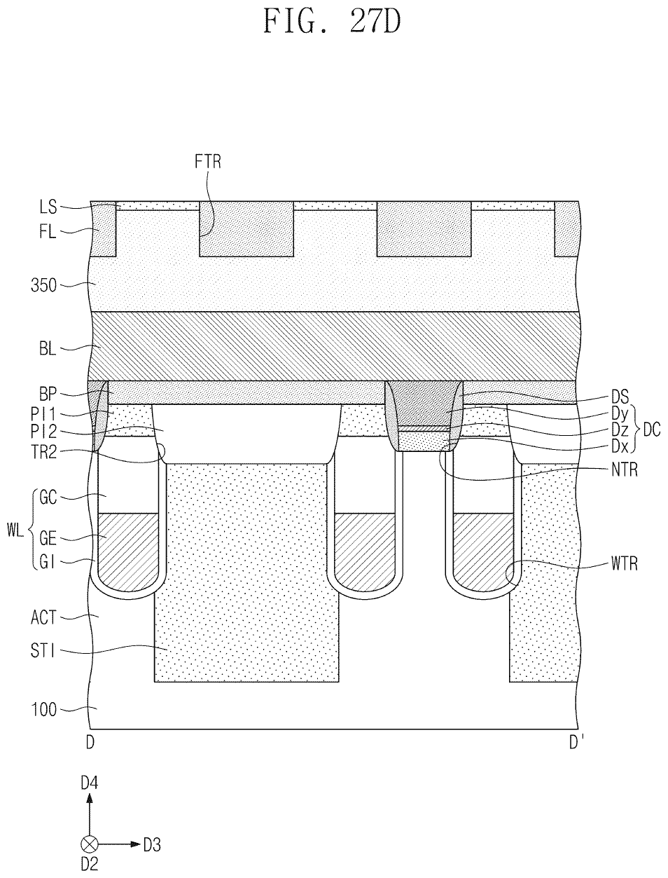

Referring to FIGS. 26 to 27D, fence patterns FN and fence lines FL may be formed. In FIG. 26, the first and second pad insulating patterns PI1 and PI2 and the first, second and node trench regions TR1, TR2 and NTR of FIG. 24 are omitted for the purpose of ease and convenience in explanation and illustration.

The formation of the fence patterns FN and the fence lines FL may include etching the mold patterns MP and the bit line capping patterns 350 to form fence trench regions FTR, forming a fence layer (not shown) on an entire top surface of the substrate 100, and removing an upper portion of the fence layer to form the fence patterns FN and the fence lines FL which fill the fence trench regions FTR. Each of the mold patterns MP may be divided into a plurality of mold patterns MP spaced apart from each other in the third direction D3 by the fence trench regions FTR. The fence trench regions FTR may extend in the second direction D2 and may be spaced apart from each other in the third direction D3.

In the formation of the fence trench regions FTR, a bottom surface of the fence trench region FTR may have a groove due to an etch selectivity of the mold patterns MP and the bit line capping patterns 350. Thus, a bottom surface of the fence trench region FTR formed between the bit lines BL may be formed at a level lower than a bottom surface of the fence trench region FTR formed on the bit line capping pattern 350.

For example, in the formation of the fence trench regions FTR, a portion of the mold pattern MP and a portion of the line spacer LS may not be etched but may remain in the node trench region NTR. The portion of the mold pattern MP may be formed into a buried insulating pattern BI, and the portion of the line spacer LS may be formed into a buried liner BR.

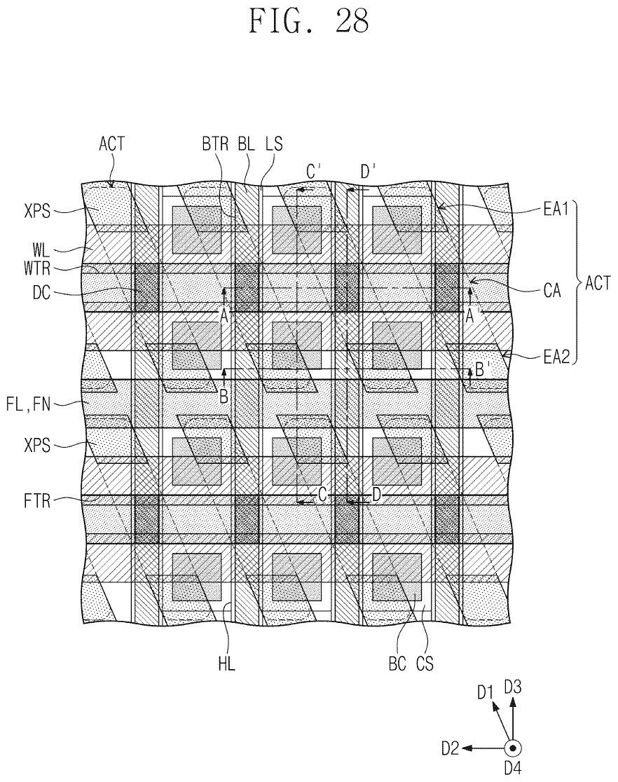

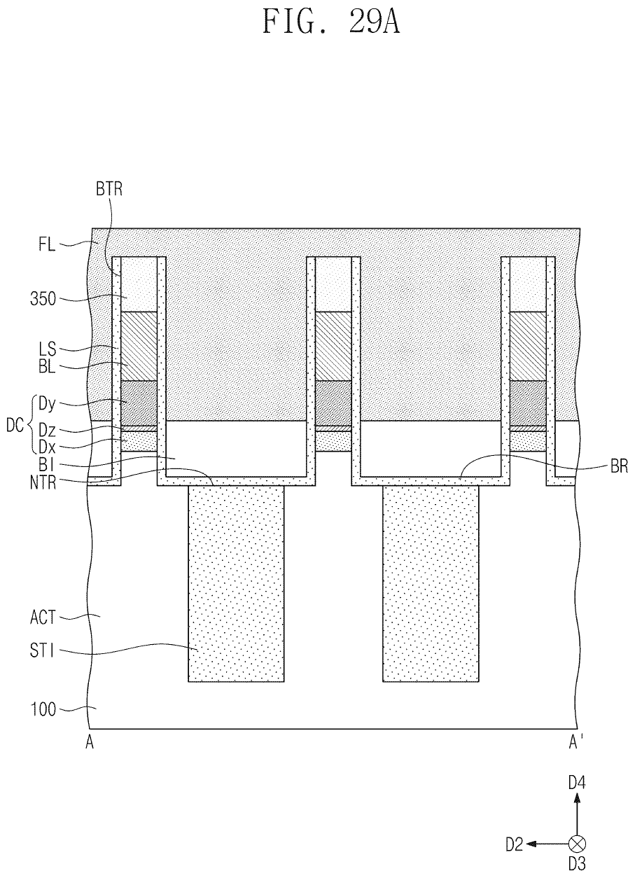

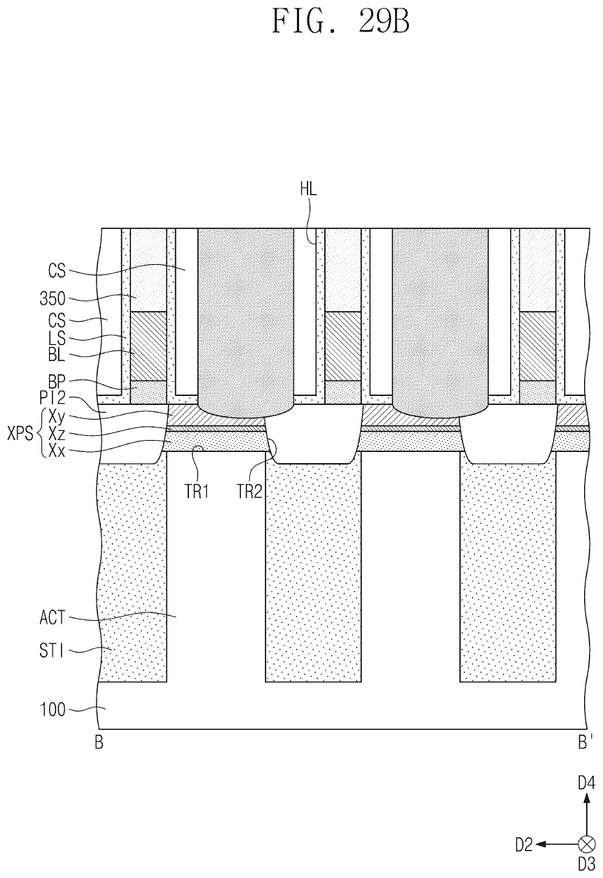

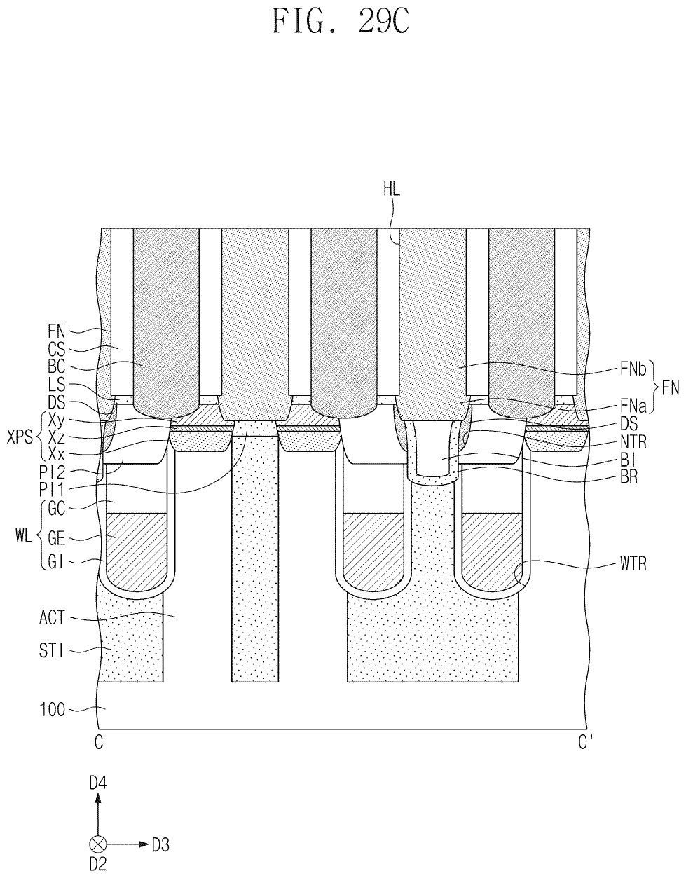

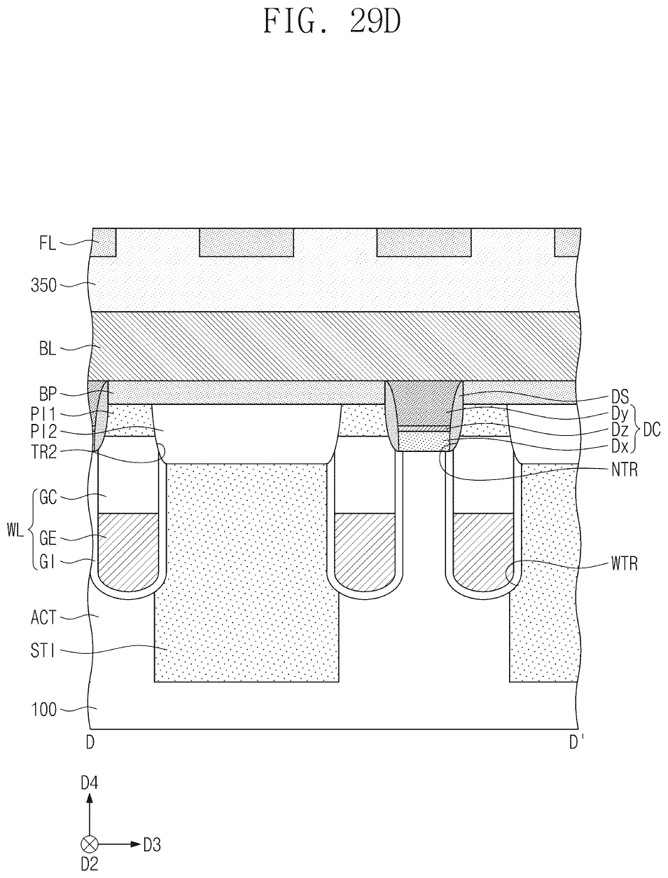

Referring to FIGS. 28 to 29D, the mold pattern MP may be removed. For example, the removing of the mold pattern MP may include performing a wet etching process of selectively removing the mold pattern MP. In this process, a portion of the fence pattern FN may also be removed. Thus, the fence pattern FN may include a lower fence pattern FNa and an upper fence pattern FNb of which widths in the third direction D3 are different from each other.

After the removal process, a hole HL may be defined between the bit lines BL adjacent to each other and between the fence patterns FN adjacent to each other in the third direction D3. A closed spacer CS may be formed to cover an inner side surface of the hole HL. For example, the formation of the closed spacer CS may include forming a closed spacer layer (not shown) covering an entire top surface of the substrate 100, and performing an anisotropic etching process on the closed spacer layer. The closed spacer layer may be removed from a bottom surface of the hole HL by the anisotropic etching process. In some example embodiments, the line spacer LS may further be removed from the bottom surface of the hole HL by the anisotropic etching process or an additional etching process. In some example embodiments, an upper portion of the storage node pad XPS may be recessed.

A storage node contact BC may be formed in the hole HL. The storage node contact BC may be formed to fill a remaining portion of the hole HL. The formation of the storage node contact BC may include depositing a storage node contact layer (not shown) on an entire top surface of the substrate 100, and removing an upper portion of the storage node contact layer to divide the storage node contact layer into the storage node contacts BC. In some example embodiments, each of the deposition and removal processes may be performed once. In certain example embodiments, the deposition and removal processes may be alternately performed a plurality of times.

Referring again to FIGS. 1 to 3D, landing pads LP may be formed on the storage node contacts BC, respectively. The formation of the landing pads LP may include sequentially forming a landing pad layer (not shown) and mask patterns (not shown) which cover top surfaces of the storage node contacts BC, and dividing the landing pad layer into a plurality of the landing pads LP by an anisotropic etching process using the mask patterns as etch masks.

Thereafter, a filling pattern 440 may be formed in an empty region formed by the removal of the landing pad layer. The filling pattern 440 may be formed to surround each of the landing pads LP in a plan view. A data storage pattern DSP may be formed on each of the landing pads LP.

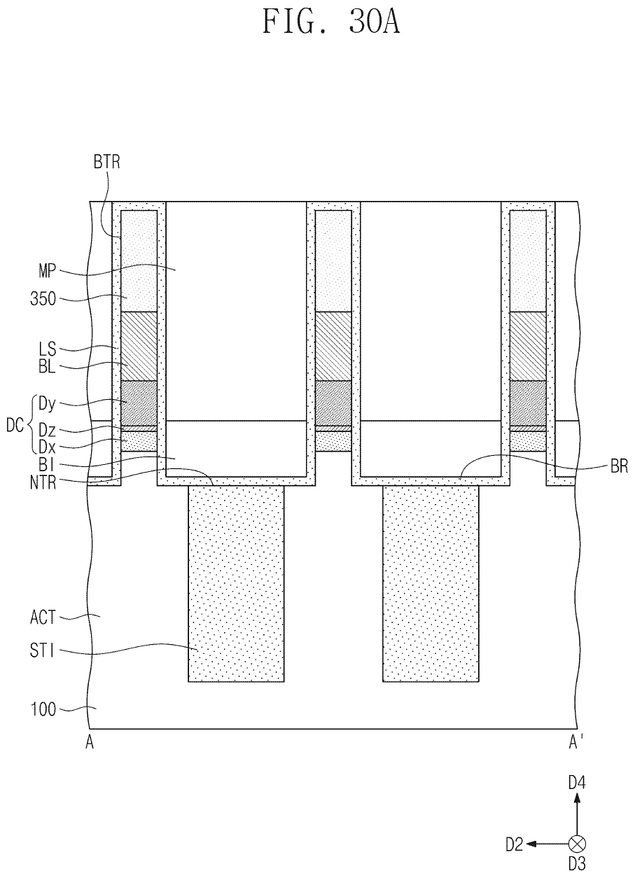

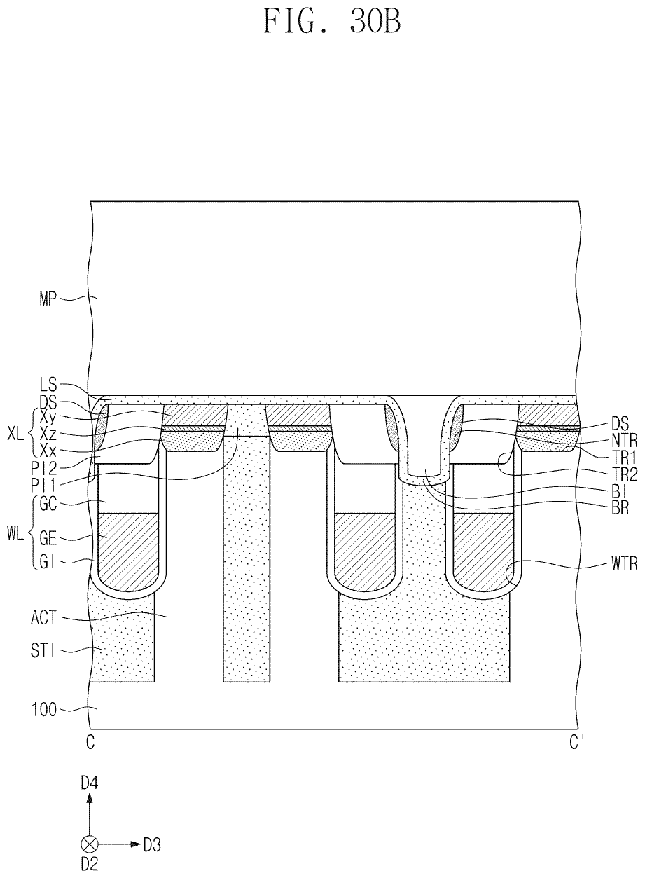

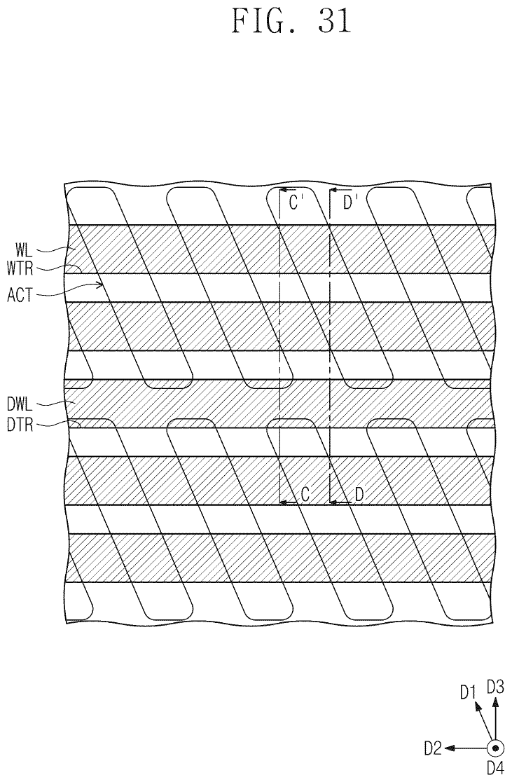

FIGS. 30A and 30B are views illustrating a method of manufacturing the semiconductor device of FIGS. 1 to 3D.

Referring to FIGS. 30A and 30B, in manufacturing the semiconductor device described with reference to FIGS. 1 to 3D, the buried insulating pattern BI and the mold pattern MP may be formed using different processes, unlike the descriptions mentioned with reference to FIGS. 24 to 27D. More particularly, after the formation of the line spacer LS, the buried insulating pattern BI may be formed to fill the node trench regions NTR. Thereafter, the mold pattern MP may be formed to cover the buried insulating pattern BI.

For example, the line spacer LS may include at least one of silicon oxide (SiO₂), silicon nitride (SiN), silicon oxycarbide (SiOC), and silicon oxy-carbonitride (SiOCN), and in particular, the line spacer LS may include silicon oxide. Since the line spacer LS includes silicon oxide having a low dielectric constant, an interference phenomenon between the bit line BL and the storage node contact BC may be minimized. For example, the mold pattern MP may include at least one of silicon oxide (SiO₂) and carbon (C), and in particular, the mold pattern MP may include carbon. Since the mold pattern MP includes carbon, the line spacer LS including silicon oxide may not be removed in the removal of the mold pattern MP described with reference to FIGS. 28 to 29D. For example, the buried insulating pattern BI may include a material different from that of the mold pattern MP. For example, the buried insulating pattern BI may include at least one of silicon oxide (SiO₂) and silicon nitride (SiN), and in particular, the buried insulating pattern BI may include silicon nitride.

Thereafter, the semiconductor device described with reference to FIGS. 1 to 3D may be manufactured using the aforementioned method of manufacturing a semiconductor device.

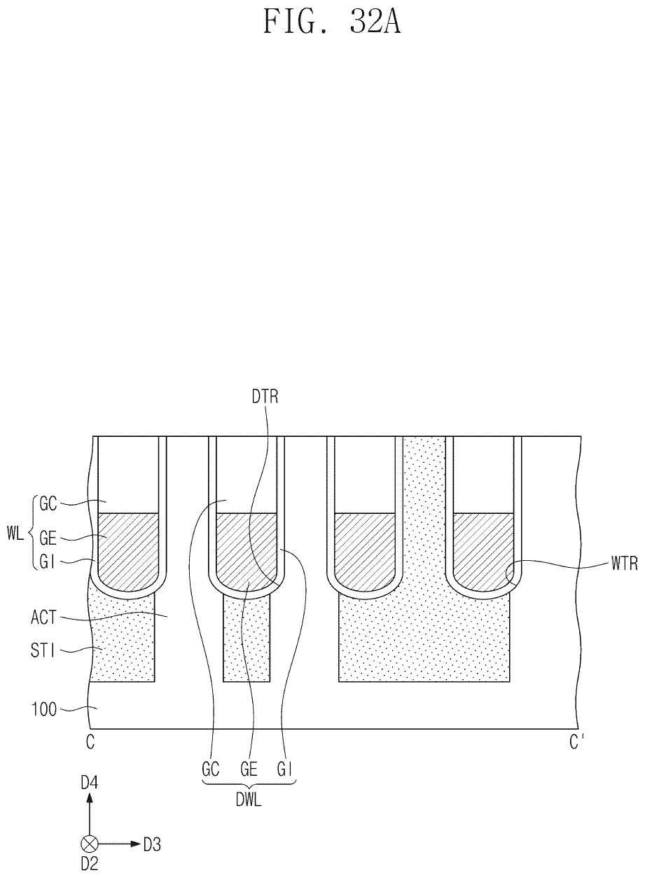

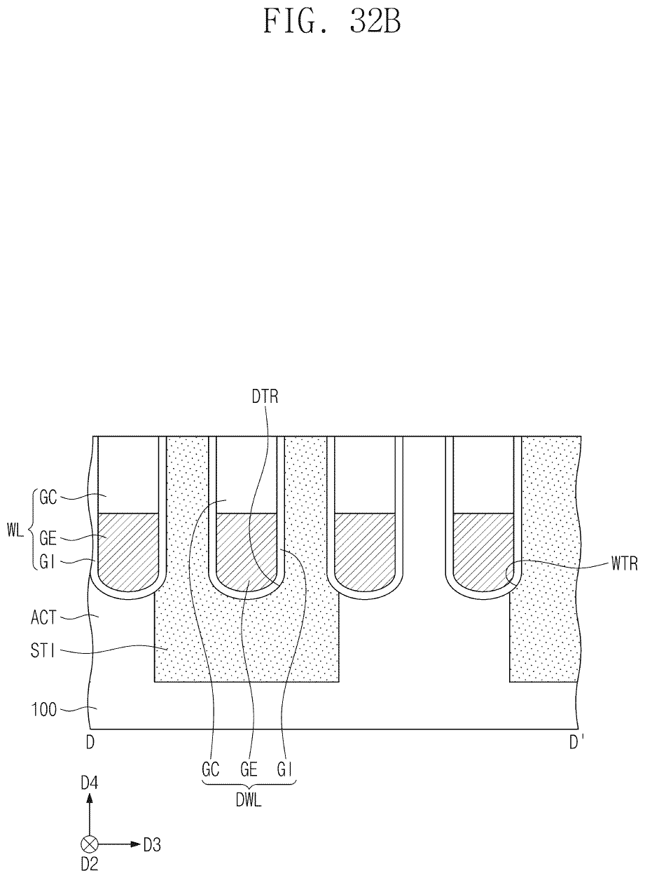

FIGS. 31 to 32B are views illustrating a method of manufacturing the semiconductor device of FIGS. 4 to 5B.

Referring to FIGS. 31 to 32B, a dummy word line DWL may also be formed in the process of forming the word line WL described with reference to FIGS. 18 to 19D. The formation of the dummy word line DWL may include forming a dummy word line trench region DTR together with the word line trench region WTR, conformally depositing a gate dielectric pattern GI on an inner surface of the dummy word line trench region DTR, filling the dummy word line trench region DTR with a conductive layer, performing an etch-back process and/or a polishing process on the conductive layer to form a gate electrode GE, and forming a gate capping pattern GC filling a remaining portion of the dummy word line trench region DTR on the gate electrode GE.

Thereafter, the semiconductor device described with reference to FIGS. 4 to 5B may be manufactured using the aforementioned method of manufacturing a semiconductor device.

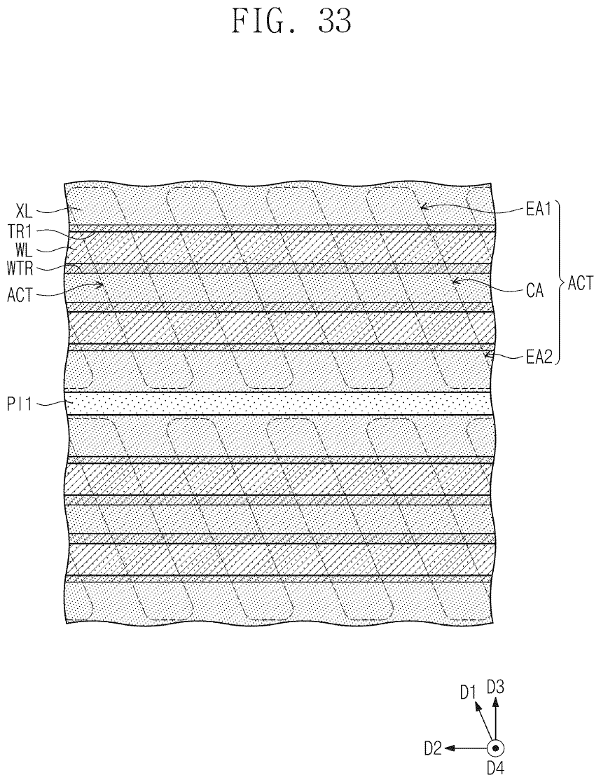

FIG. 33 is a plan view illustrating a method of manufacturing the semiconductor device of FIG. 6.

Referring to FIG. 33, in the formation of the first trench regions TR1 described with reference to FIGS. 20 to 21D, the first trench regions TR1 may further be formed on the center portions CA of the active patterns ACT. The center portions CA of the active patterns ACT may be exposed by the first trench regions TR1.

The pad lines XL may further be formed on the center portions CA of the active patterns ACT. The pad lines XL may fill the first trench regions TR1 on the center portions CA of the active patterns ACT. Each of the pad lines XL on the center portions CA of the active patterns ACT may be divided into bit line node pads XPB by the formation of the second pad insulating patterns PI2.

Thereafter, the semiconductor device described with reference to FIG. 6 may be manufactured using the aforementioned method of manufacturing a semiconductor device.

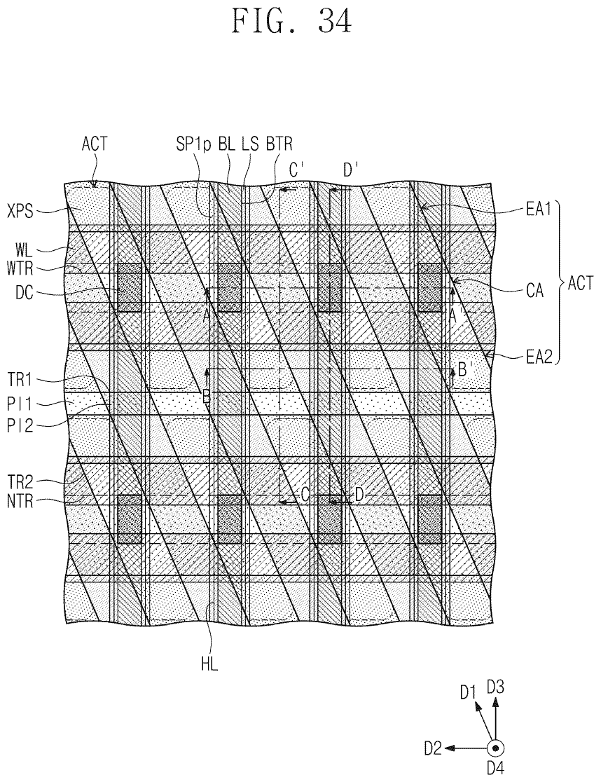

FIGS. 34 to 39D are views illustrating a method of manufacturing the semiconductor device of FIGS. 7 to 8D.

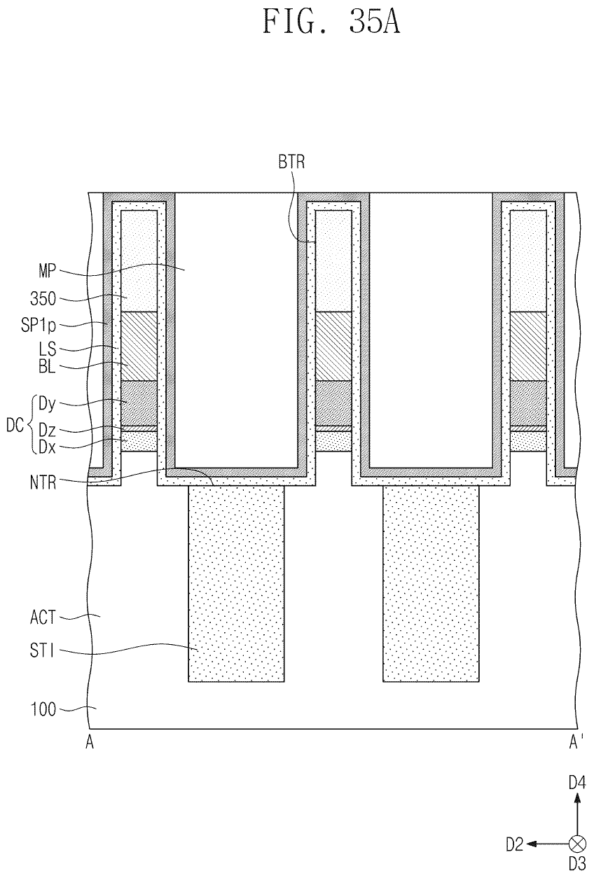

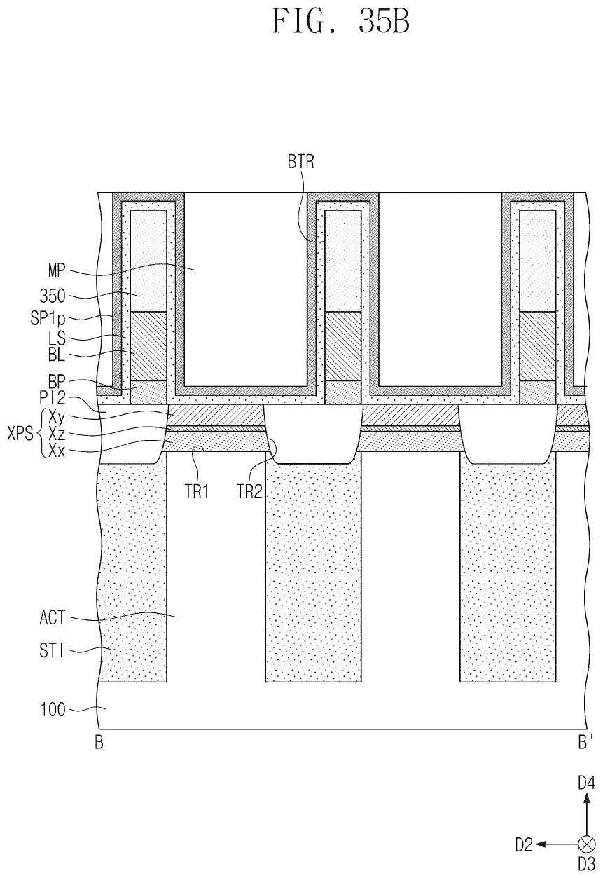

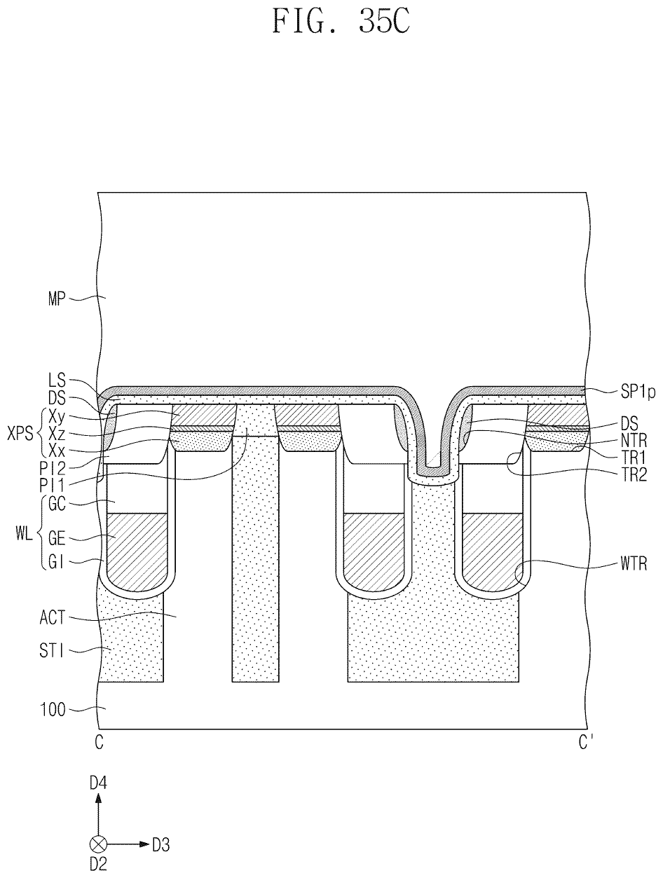

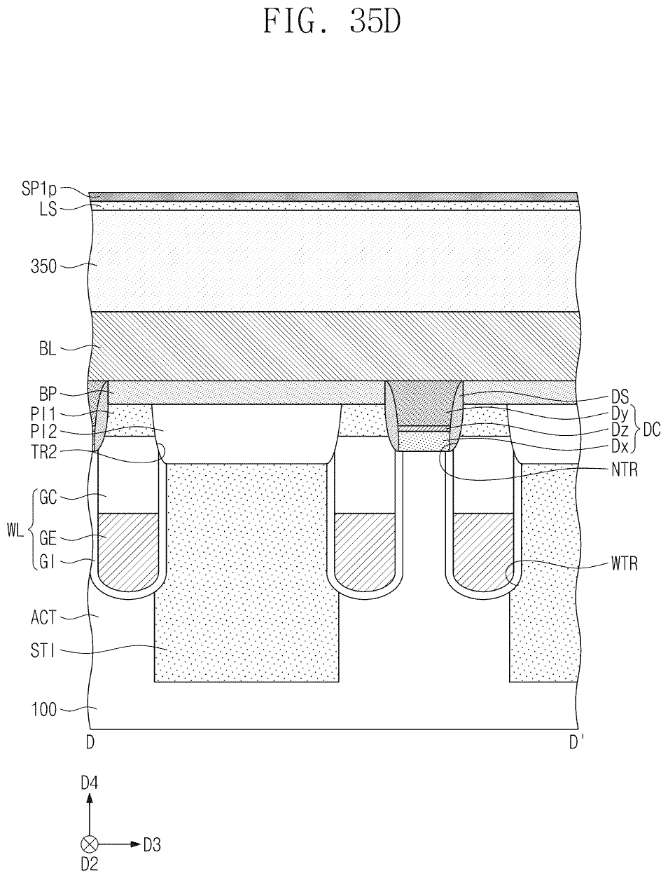

Referring to FIGS. 34 to 35D, a first sacrificial layer SP1p may be formed after the formation of the line spacer LS described with reference to FIGS. 24 to 25D. The first sacrificial layer SP1p may be deposited, e.g. conformally deposited on an entire top surface of the substrate 100. For example, the first sacrificial layer SP1p may be conformally deposited on an inner surface of the bit line trench region BTR. For example, the first sacrificial layer SP1p may further be deposited on an inner surface of the node trench region NTR. The first sacrificial layer SP1p may extend in the third direction D3. Thereafter, the mold pattern MP may be formed between the bit lines BL adjacent to each other. The mold pattern MP may fill the bit line trench region BTR.

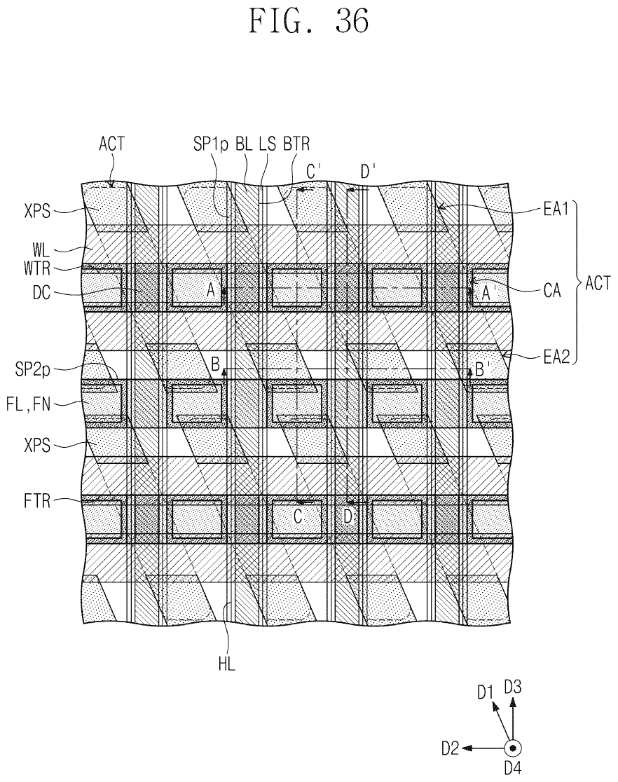

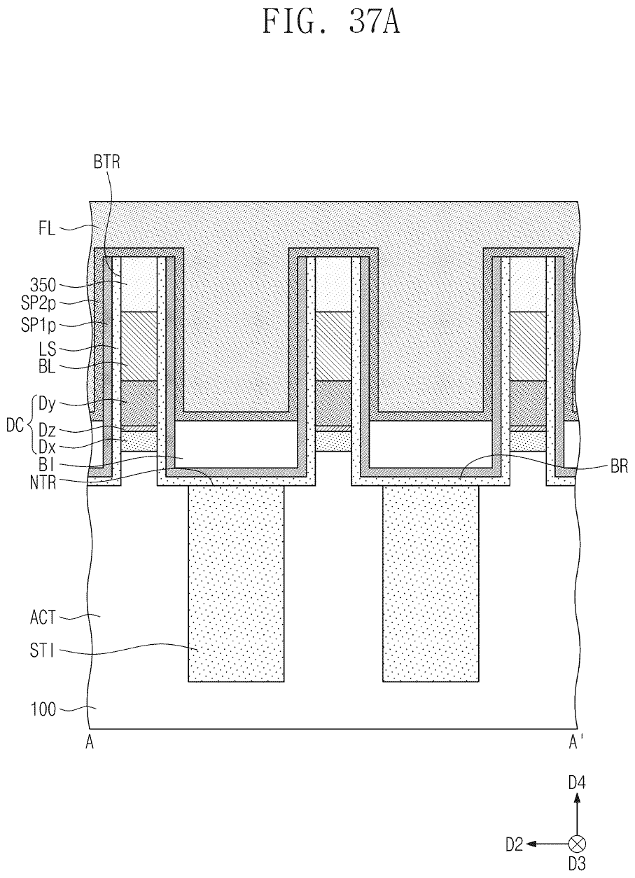

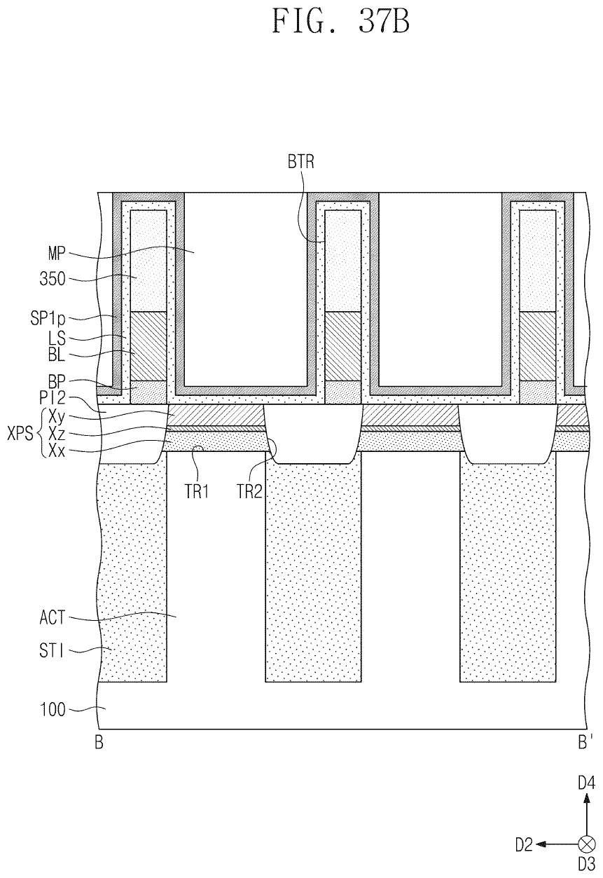

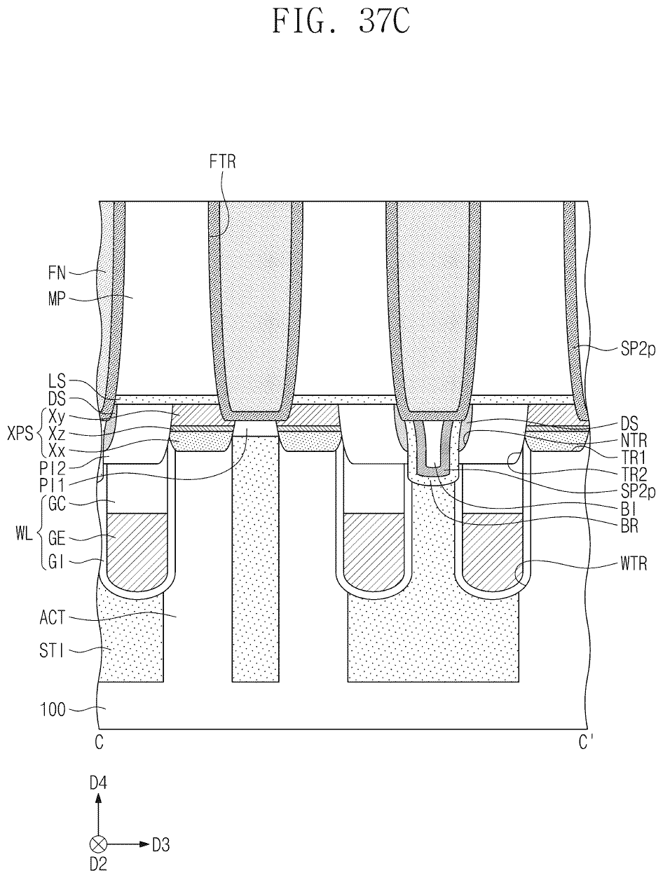

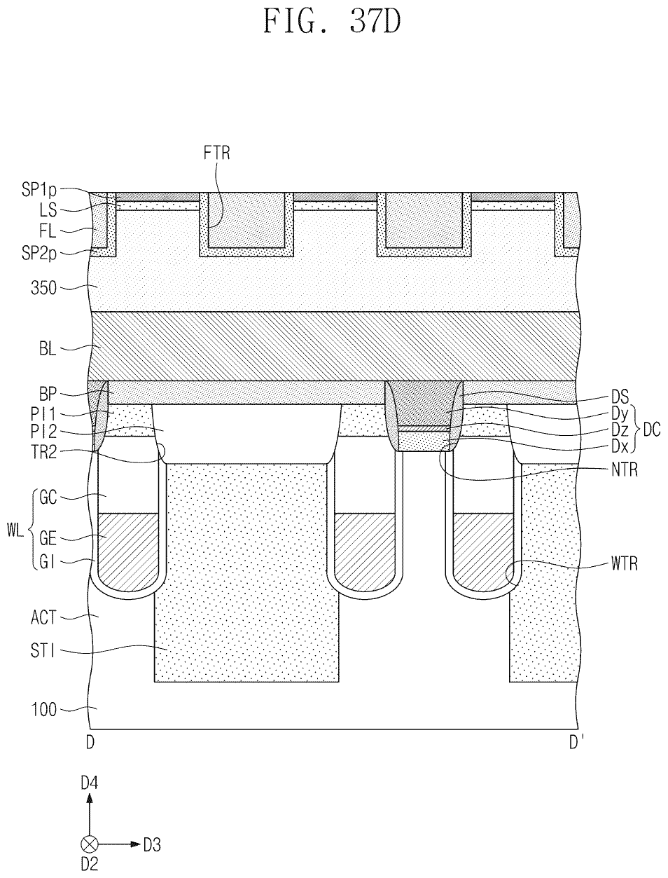

Referring to FIGS. 36 to 37D, the fence trench regions FTR may be formed by etching the mold patterns MP and the bit line capping patterns 350. In FIG. 36, the first and second pad insulating patterns PI1 and PI2 and the first, second and node trench regions TR1, TR2 and NTR of FIG. 34 are omitted for the purpose of ease and convenience in explanation and illustration.

A second sacrificial layer SP2p may be formed on inner surfaces of the fence trench regions FTR. The second sacrificial layer SP2p may be conformally deposited on the inner surfaces of the fence trench regions FTR. The second sacrificial layer SP2p may be disposed between the bit lines BL adjacent to each other and between the mold patterns MP adjacent to each other in the third direction D3.

For example, in the formation of the fence trench regions FTR, the buried insulating pattern BI may be formed, and the second sacrificial layer SP2p may cover the buried insulating pattern BI. Thereafter, the fence patterns FN and the fence lines FL may be formed to fill the fence trench regions FTR. The fence patterns FN may be surrounded by the second sacrificial layer SP2p.

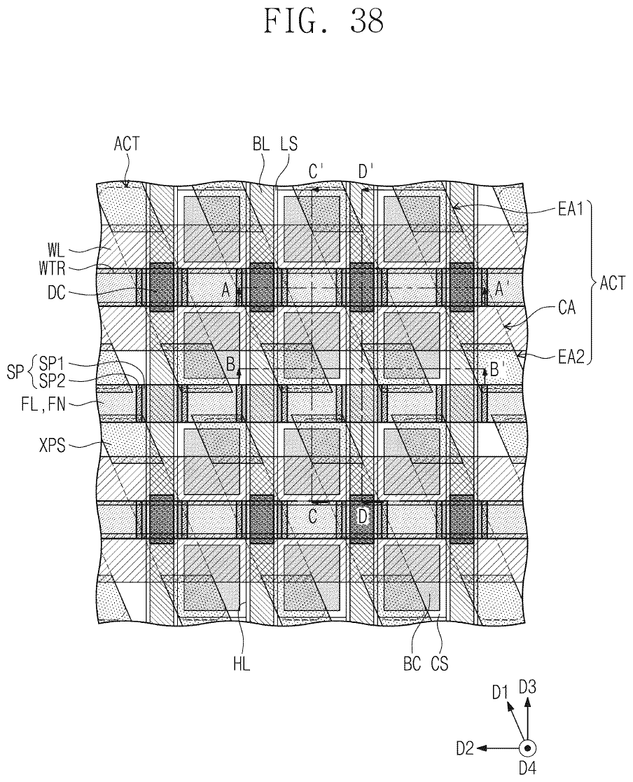

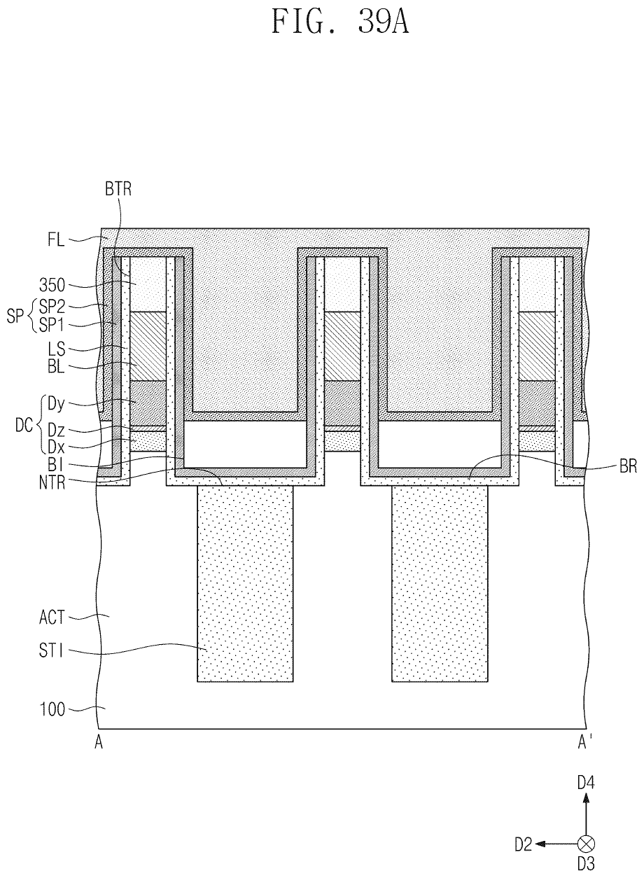

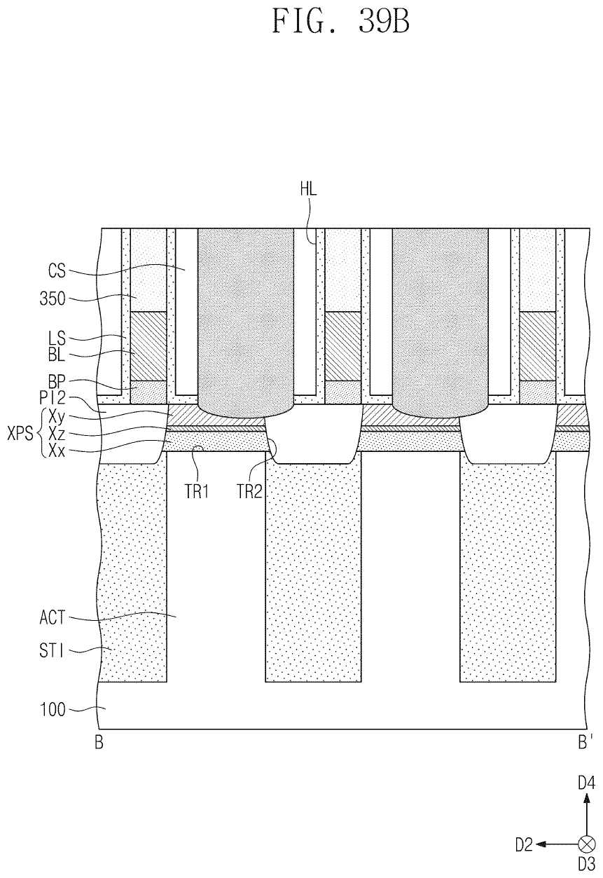

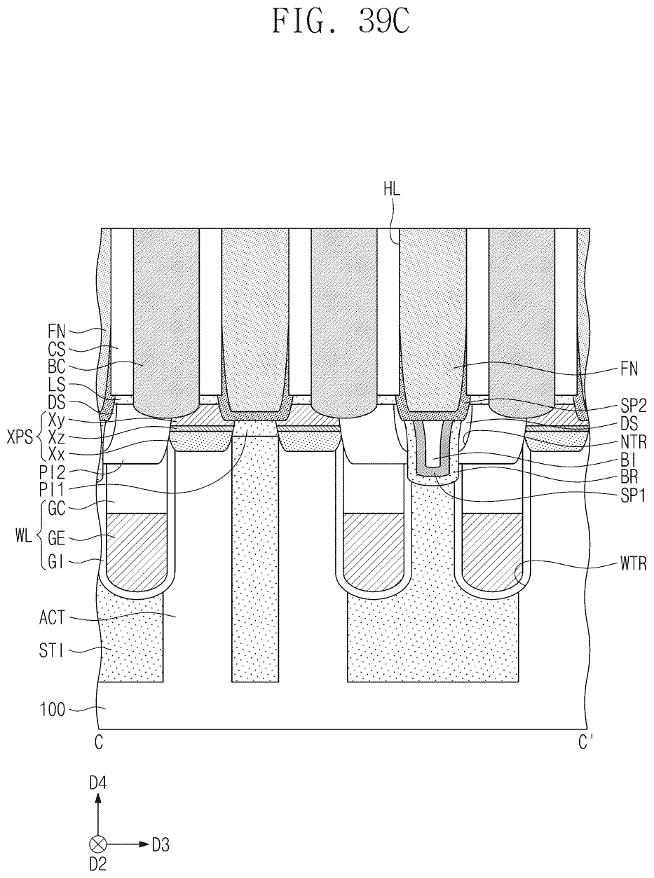

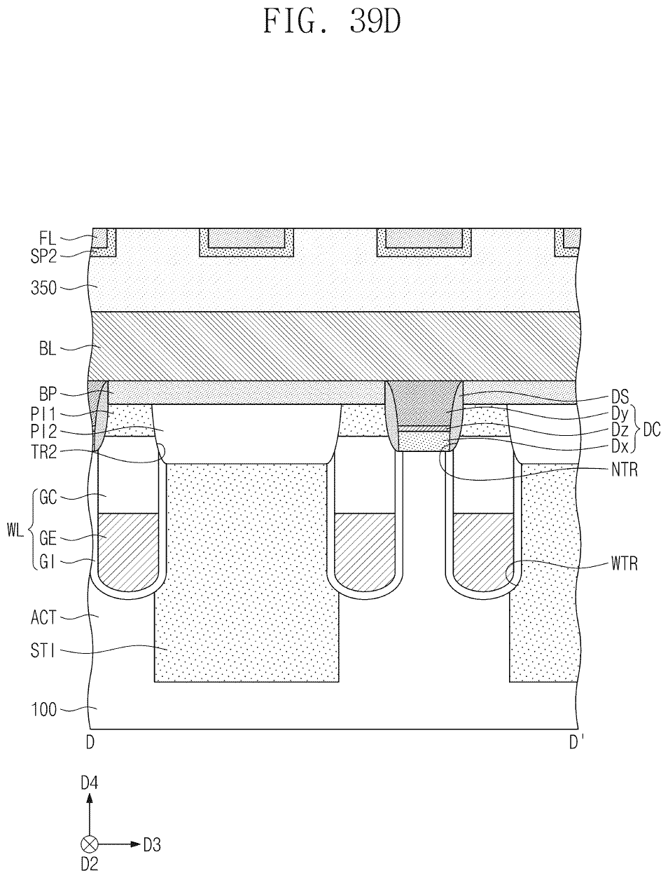

Referring to FIGS. 38 to 39D, the mold pattern MP may be removed to form the hole HL. At this time, the first and second sacrificial layers SP1p and SP2p may prevent or reduce the line spacer LS from being removed together with the mold pattern MP. In the case in which the line spacer LS includes a material having a low dielectric constant, removal of the line spacer LS may be prevented or reduced to minimize or reduce an interference phenomenon between the bit line BL and the storage node contact BC.

Thereafter, a removal process may be performed on the first and second sacrificial layers SP1p and SP2p. For example, the removal process may include a wet etching process, and an etching solution may remove the first and second sacrificial layers SP1p and SP2p by using the hole HL as an etching path. At this time, etching of the line spacer LS and the fence pattern FN may be reduced or minimized using an etch selectivity. A first sacrificial pattern SP1 and a second sacrificial pattern SP2 may be formed from the first and second sacrificial layers SP1p and SP2p by the removal process.

Thereafter, the semiconductor device described with reference to FIGS. 7 to 8D may be manufactured using the aforementioned method of manufacturing a semiconductor device.

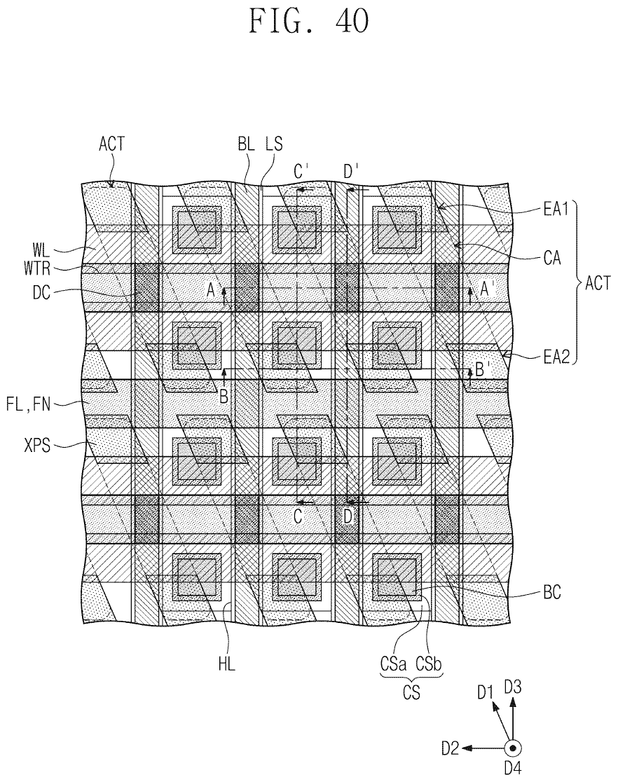

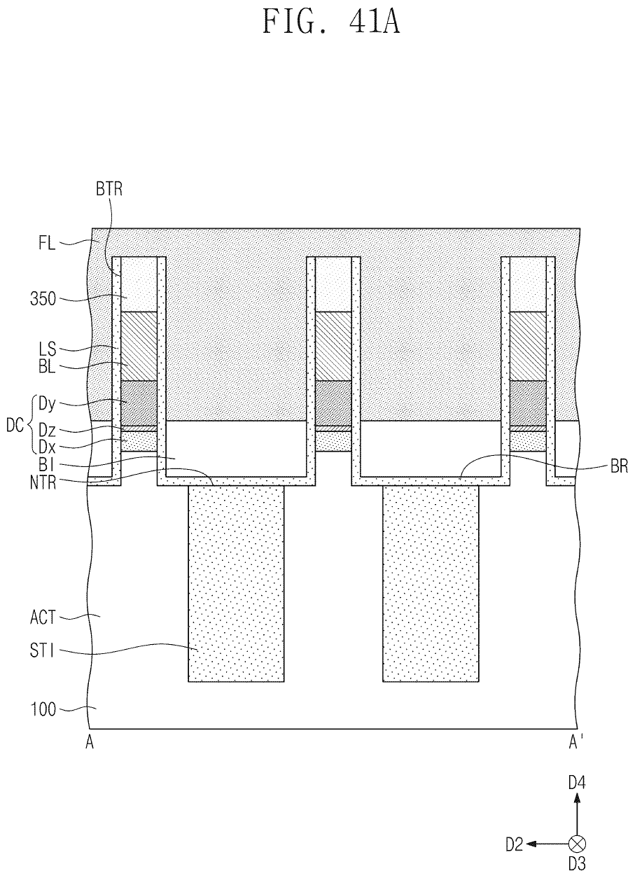

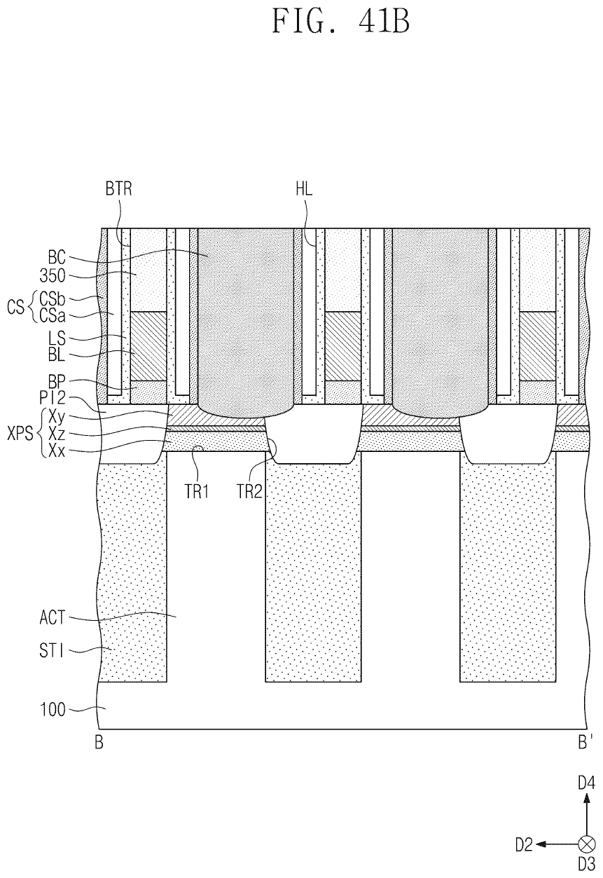

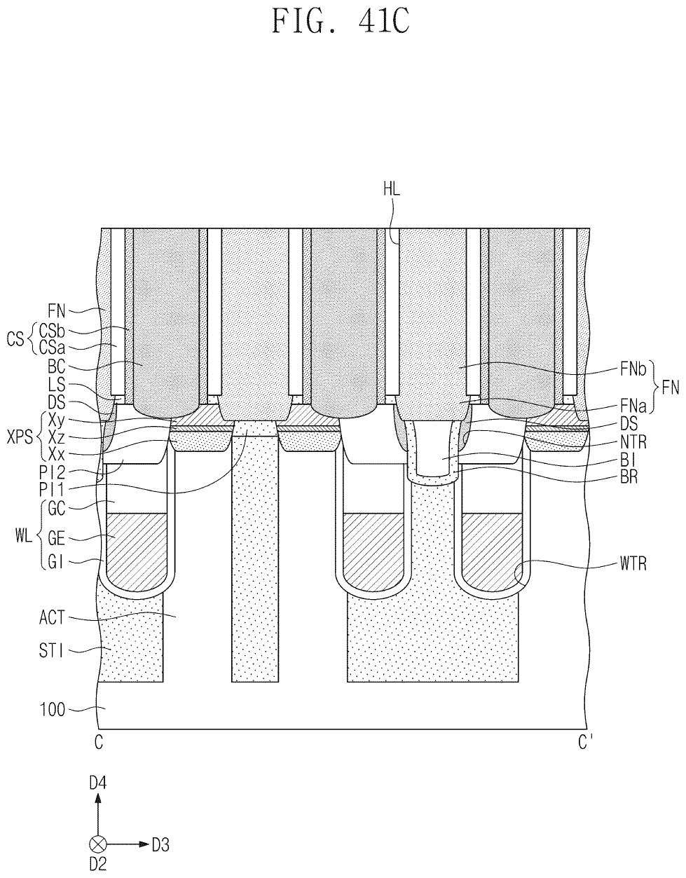

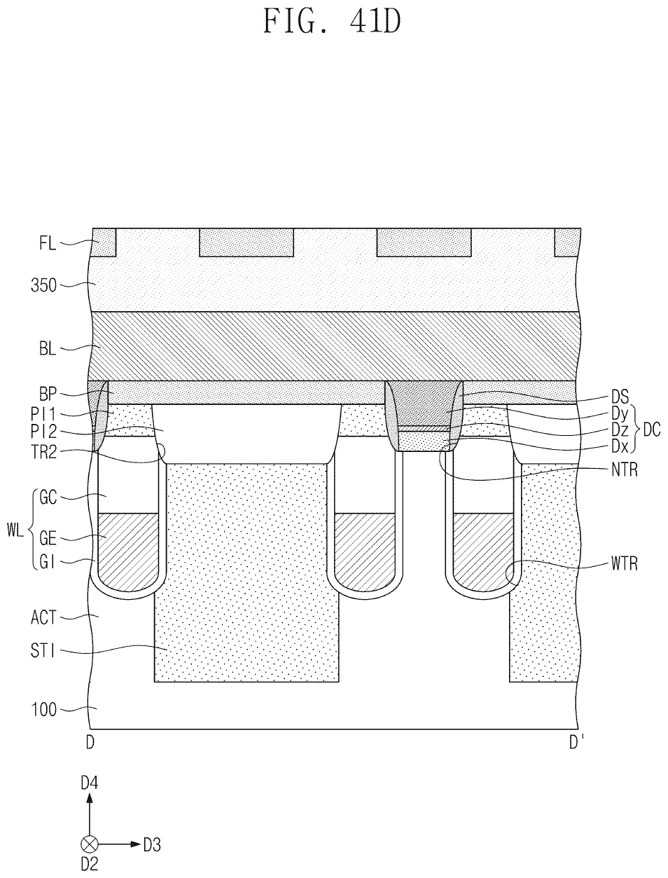

FIGS. 40 to 41D are views illustrating a method of manufacturing the semiconductor device of FIGS. 9 to 10D.

Referring to FIGS. 40 to 41D, after the formation of the hole HL described with reference to FIGS. 28 to 29D, a closed spacer CS including a first closed sub-spacer CSa and a second closed sub-spacer CSb may be formed. The formation of the closed spacer CS may include forming a first closed sub-spacer layer (not shown) covering an inner surface of the hole HL, removing the first closed sub-spacer layer on a bottom surface of the hole HL to form the first closed sub-spacer CSa, forming a second closed sub-spacer layer (not shown) covering the inner surface of the hole HL, and removing the second closed sub-spacer layer on the bottom surface of the hole HL to form the second closed sub-spacer CSb. Each of the removal of the first closed sub-spacer layer and the removal of the second closed sub-spacer layer may include performing an anisotropic etching process.

Thereafter, the semiconductor device described with reference to FIGS. 9 to 10D may be manufactured using the aforementioned method of manufacturing a semiconductor device.

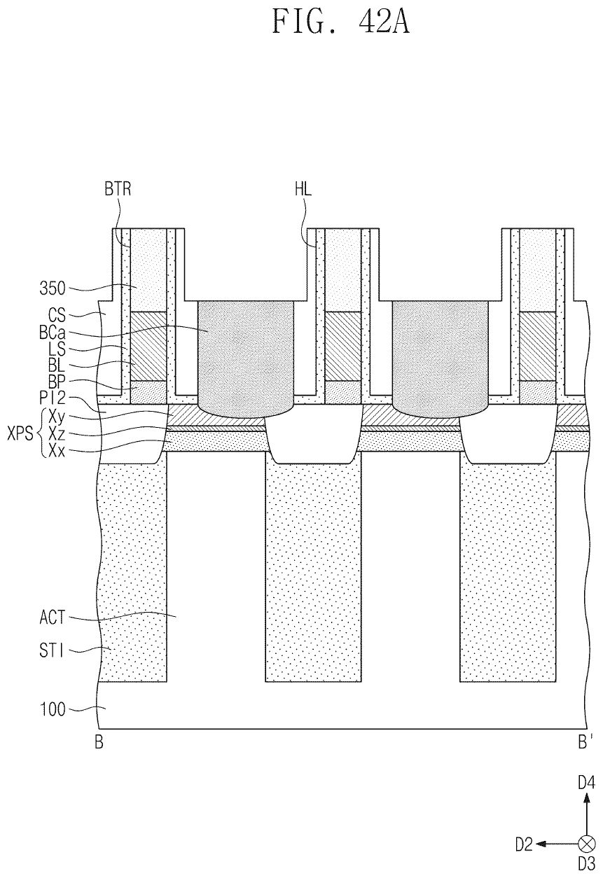

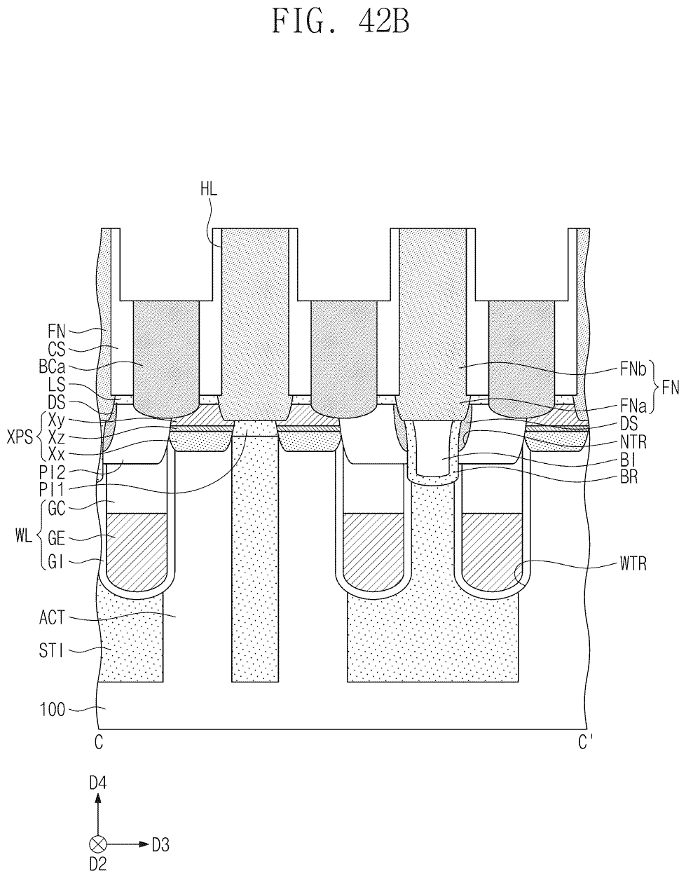

FIGS. 42A and 42B are cross-sectional views illustrating a method of manufacturing the semiconductor device of FIGS. 11A and 11B.

Referring to FIGS. 42A and 42B, when the storage node contact BC described with reference to FIGS. 28 to 29D is formed, the deposition process of the storage node contact layer and the removal process of its upper portion may be performed a plurality of times.

More particularly, a first storage node contact layer (not shown) may be deposited to cover an entire top surface of the substrate 100. The first storage node contact layer may fill the hole HL. Thereafter, an upper portion of the first storage node contact layer may be removed to form lower storage node contacts BCa. A top surface of the lower storage node contact BCa may be located at a lower level than a top surface of the bit line capping pattern 350. The removal of the upper portion of the first storage node contact layer may include performing an etch-back process on the first storage node contact layer. In this process, at least a portion of an upper portion of the closed spacer CS may also be removed. For example, the upper portion of the closed spacer CS may be a portion of the closed spacer CS, which surrounds the upper portion of the first storage node contact layer.

Referring again to FIGS. 11A and 11B, a second storage node contact layer (not shown) may be deposited to cover an entire top surface of the substrate 100 and may fill the hole HL. Thereafter, an upper portion of the second storage node contact layer may be removed to form upper storage node contacts BCb. The lower storage node contact BCa and the upper storage node contact BCb may constitute the storage node contact BC.

Thereafter, the semiconductor device described with reference to FIGS. 11A to 11B may be manufactured using the aforementioned method of manufacturing a semiconductor device.

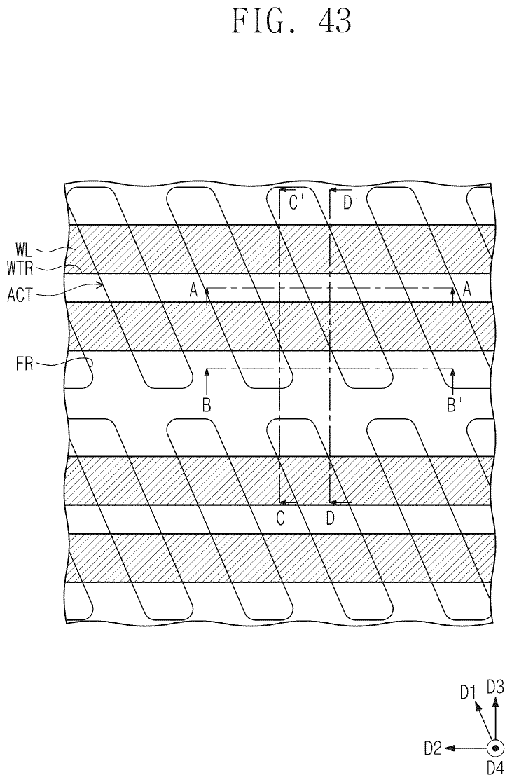

FIGS. 43 to 46D are views illustrating a method of manufacturing the semiconductor device of FIGS. 12 to 13D.

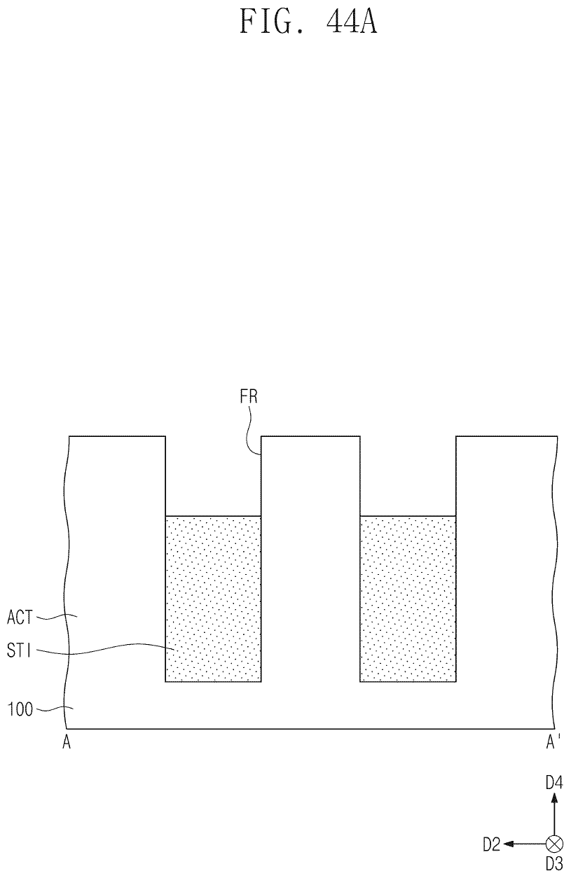

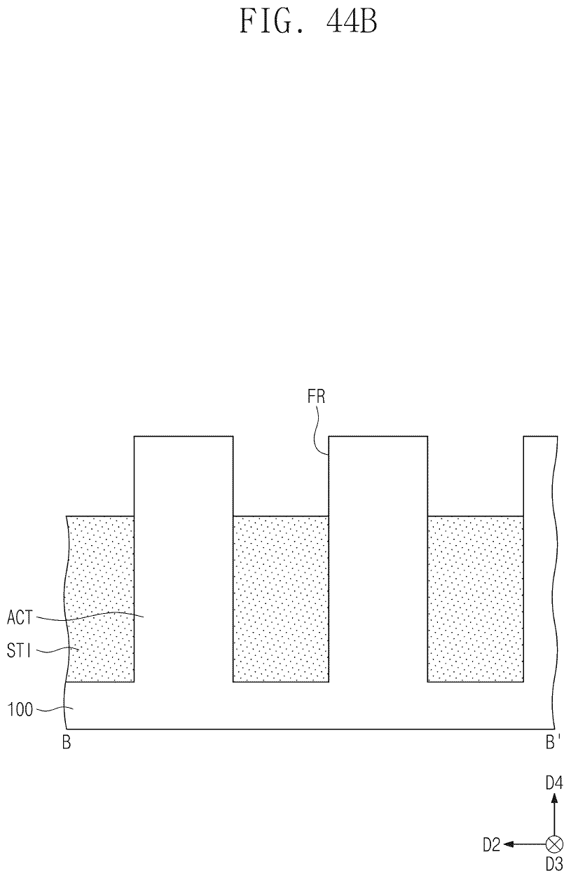

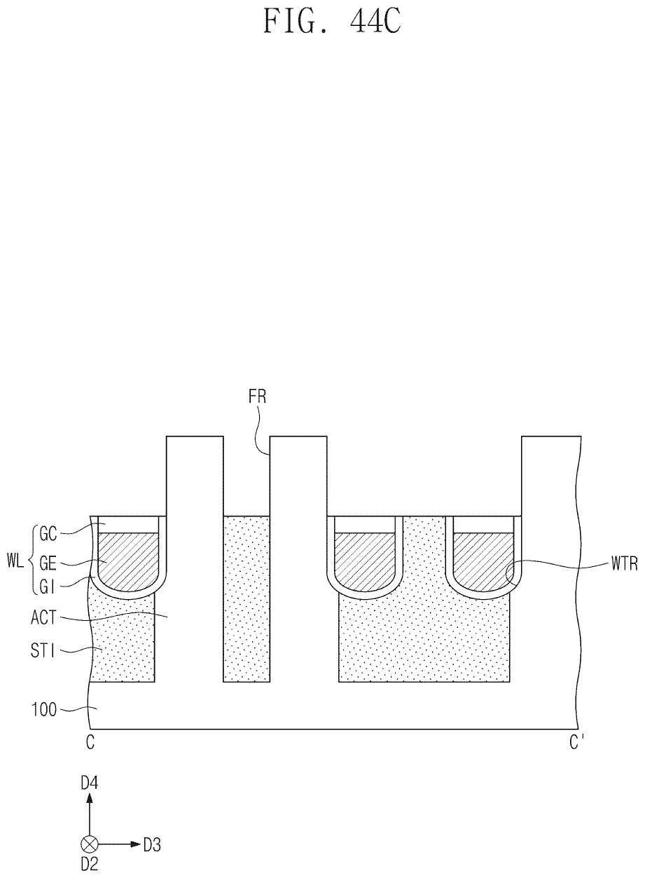

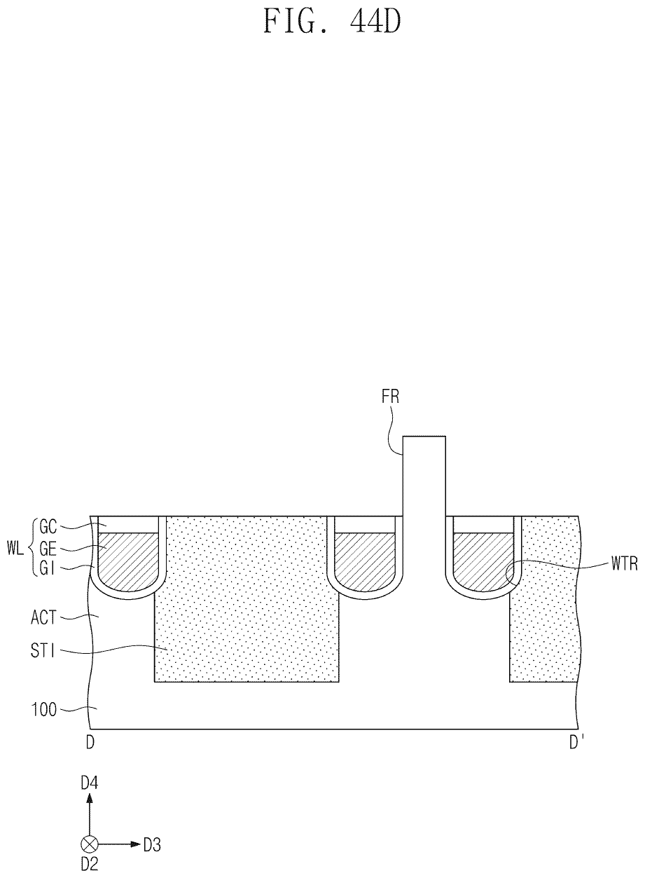

Referring to FIGS. 43 to 44D, after the formation of the word lines WL described with reference to FIGS. 18 to 19D, an upper portion of the device isolation pattern STI and an upper portion of the word line WL (e.g., an upper portion of the gate capping pattern GC) may be removed to form a field recess region FR. The field recess region FR may be a region surrounded by upper portions of the active patterns ACT. The upper portions of the active patterns ACT may be portions of the active patterns ACT, which are located at a level higher than a top surface of the device isolation pattern STI and a top surface of the word line WL. Side surfaces of the upper portions of the active patterns ACT may be exposed by the field recess region FR.

The removal of the upper portion of the device isolation pattern STI and the upper portion of the word line WL may be performed using an etch recipe having an etch selectivity with respect to the active patterns ACT. Thus, even though an exposure process for a patterning process is not performed, the upper portion of the device isolation pattern STI and the upper portion of the word line WL may be selectively removed. In addition, the upper portions of the active patterns ACT may remain.

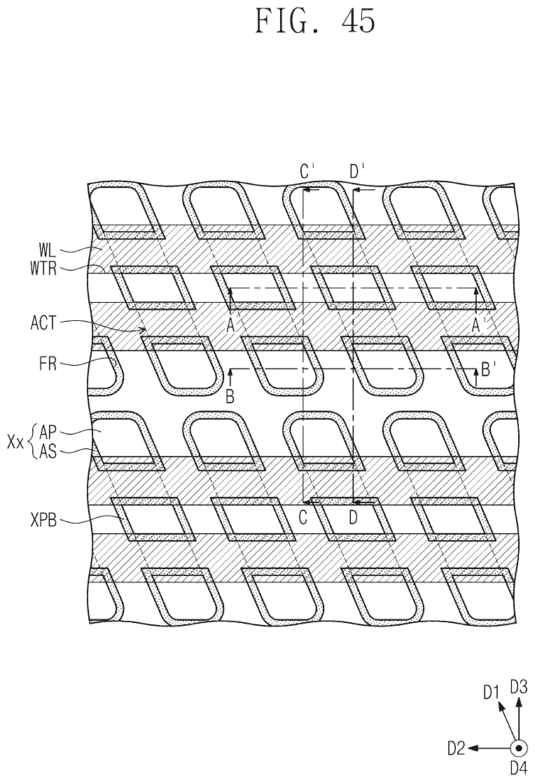

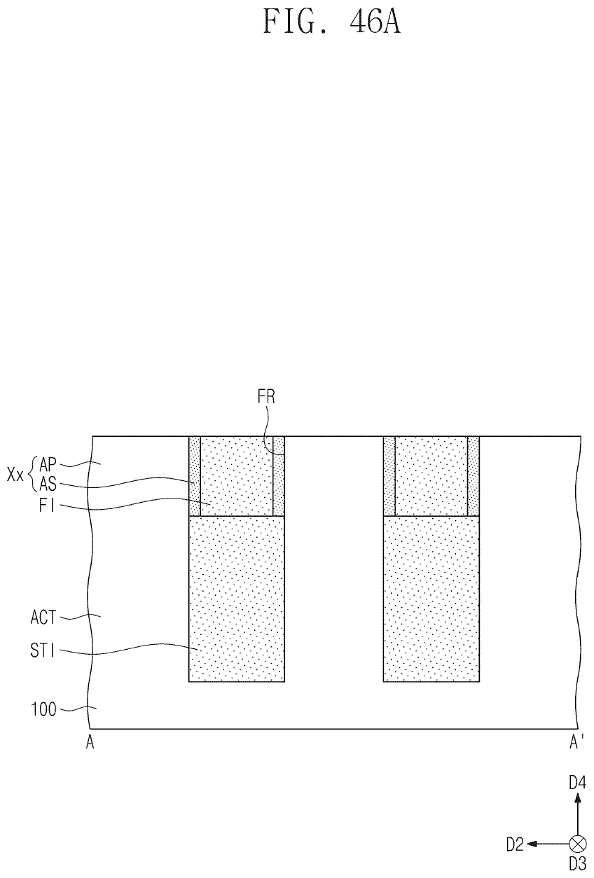

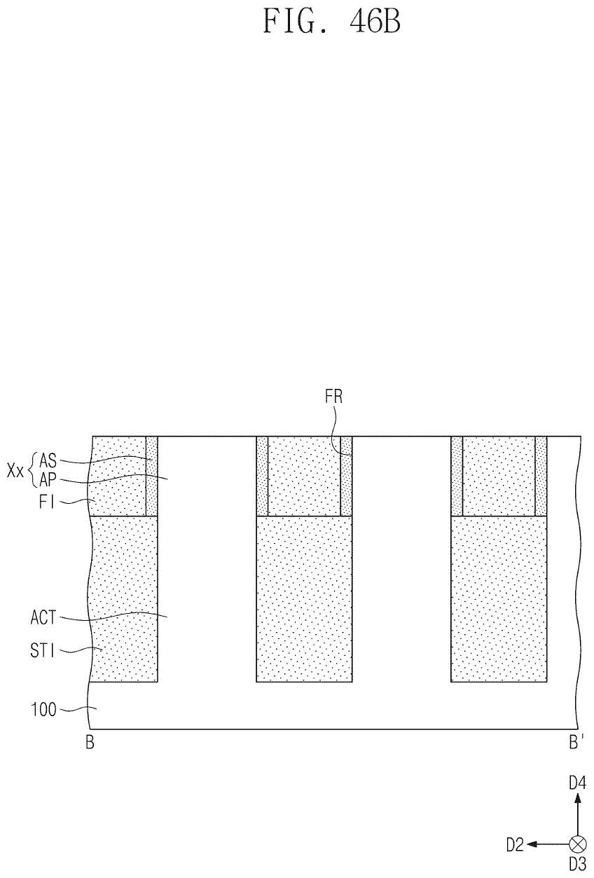

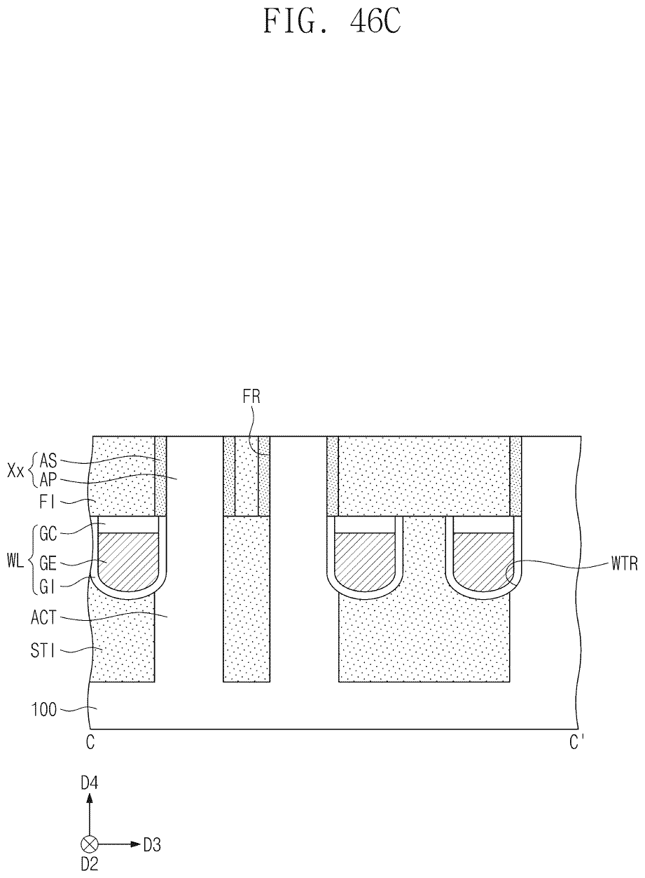

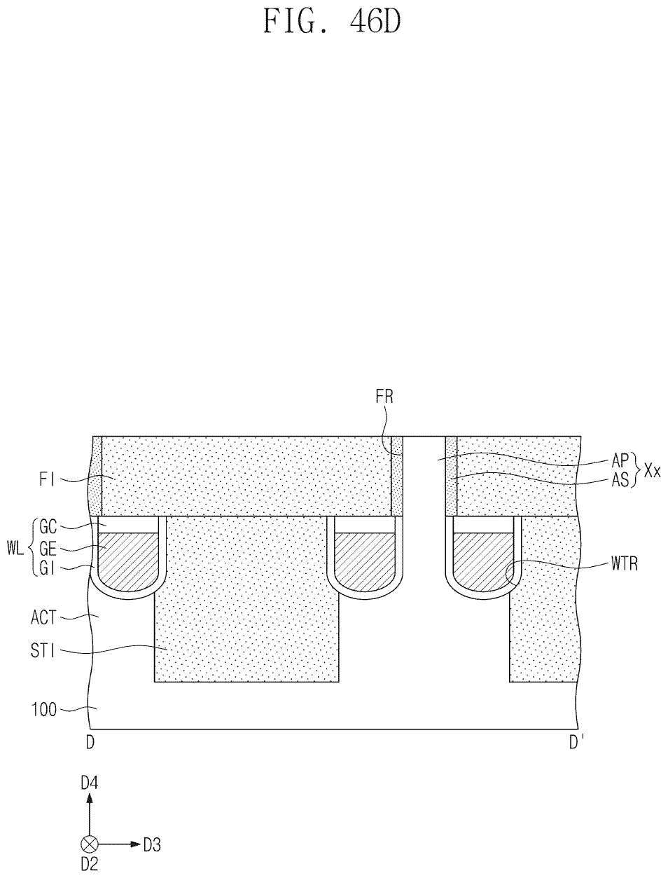

Referring to FIGS. 45 to 46D, lower pads Xx of a storage node pad XPS and a bit line node pad XPB may be formed. The formation of the lower pads Xx of the storage node pad XPS and the bit line node pad XPB may include forming active spacers AS surrounding side surfaces of the upper portions of the active patterns ACT. Here, the upper portions of the active patterns ACT, which are surrounded by the active spacers AS, may be defined as active pads AP.

A filling insulation pattern FI may be formed in the field recess region FR. The filling insulation pattern FI may be formed to fill a remaining portion of the field recess region FR. The formation of the filling insulation pattern FI may include forming a filling insulation layer (not shown) covering an entire top surface of the substrate 100, and removing an upper portion of the filling insulation layer to form the filling insulation pattern FI. Top surfaces of the lower pads Xx may be exposed by the removal of the upper portion of the filling insulation layer.

Referring again to FIGS. 12 to 13D, the lower pads Xx may be recessed. Ohmic pads Xz and upper pads Xy may be formed in regions formed by the recessing of the lower pads Xx. Thus, storage node pads XPS and bit line node pads XPB may be formed. Thereafter, the semiconductor device described with reference to FIGS. 12 to 13D may be manufactured using the aforementioned method of manufacturing a semiconductor device.

However, in the case of using the manufacturing method described with reference to FIGS. 43 to 46D, the process of forming the storage node pad XPS described with reference to FIGS. 20 to 23D may be omitted.

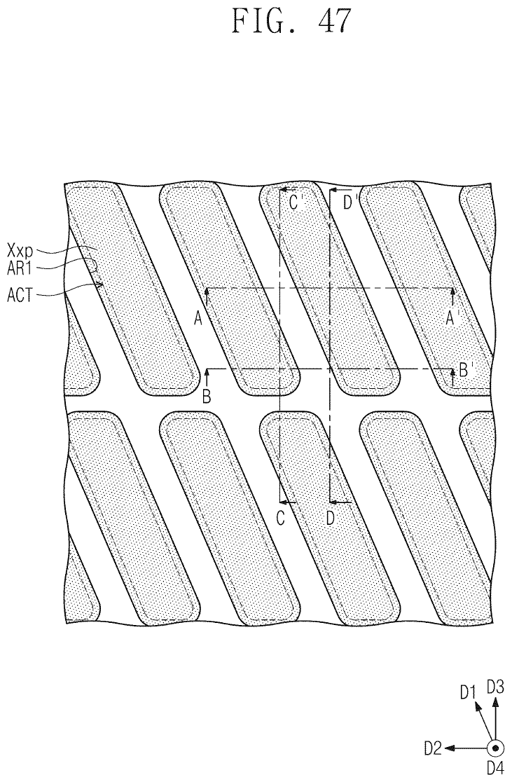

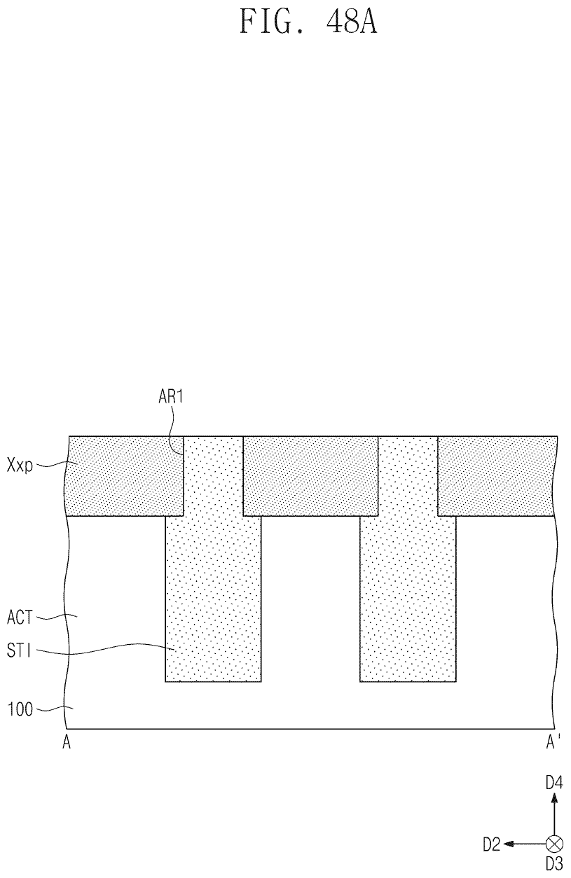

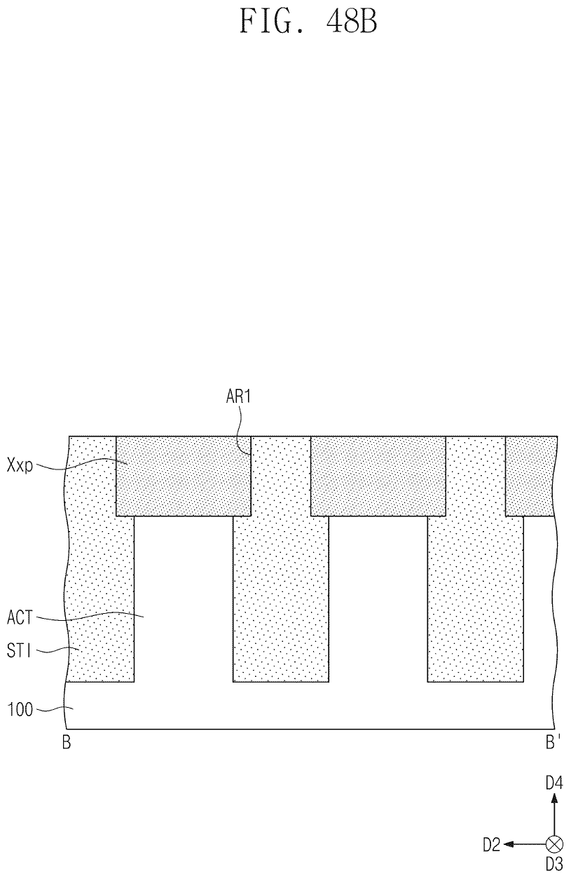

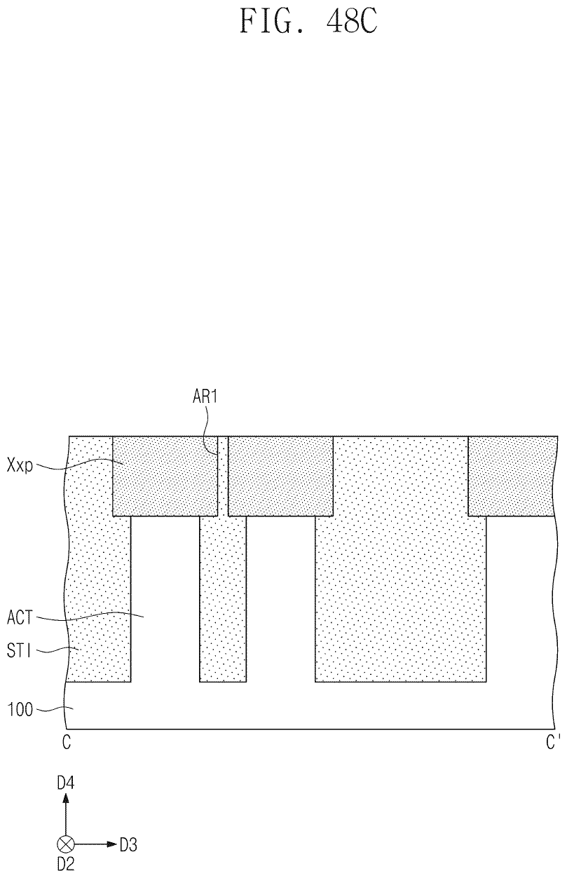

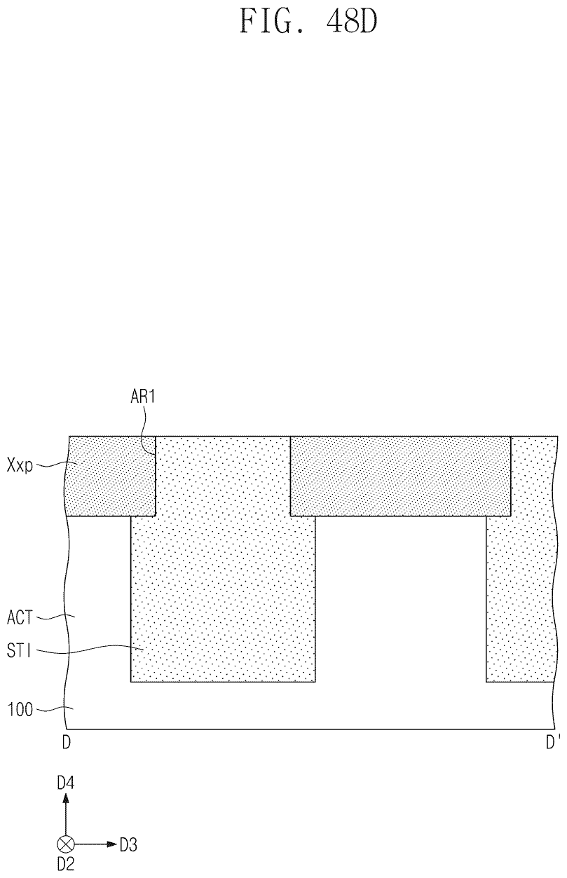

FIGS. 47 to 48D are views illustrating a method of manufacturing the semiconductor device of FIGS. 14 to 15D.

Referring to FIGS. 47 to 48D, upper portions of the active patterns ACT may be removed after the formation of the active patterns ACT and the device isolation pattern STI described with reference to FIGS. 18 to 19D. Thus, first active recess regions AR1 may be formed. The first active recess regions AR1 may be regions surrounded by an upper portion of the device isolation pattern STI.

The removal of the upper portions of the active patterns ACT may be performed using an etch recipe having an etch selectivity with respect to the device isolation pattern STI. Thus, even though an exposure process for a patterning process is not performed, the upper portions of the active patterns ACT may be selectively removed. In addition, the upper portion of the device isolation pattern STI may remain.

Thereafter, each of the first active recess regions AR1 may be horizontally expanded. In this process, a portion of the upper portion of the device isolation pattern STI may be removed. The first active recess regions AR1 may expose top surfaces of the active patterns ACT, respectively.

Preliminary lower pads Xxp may be formed in the first active recess regions AR1, respectively. For example, the preliminary lower pads Xxp may fill the first active recess regions AR1. The preliminary lower pads Xxp may be formed on the active patterns ACT. For example, the preliminary lower pads Xxp may completely cover top surfaces of the active patterns ACT. Each of the preliminary lower pads Xxp may extend in the first direction D1, and the preliminary lower pads Xxp may be spaced apart from each other in the second and third directions D2 and D3.

Referring again to FIGS. 14 to 15D, the preliminary lower pads Xxp may be recessed. Preliminary ohmic pads (not shown) and preliminary upper pads (not shown) may be formed in regions formed by the recessing of the preliminary lower pads Xxp. Thus, preliminary node pads (not shown) may be formed. Each of the preliminary node pads may cover each of the active patterns ACT.

Next, the word lines WL may be formed using the method described with reference to FIGS. 18 to 19D. Each of the preliminary node pads may be divided into two storage node pads XPS and one bit line node pad XPB by a pair of the word lines WL. Thereafter, the semiconductor device described with reference to FIGS. 14 to 15D may be manufactured using the aforementioned method of manufacturing a semiconductor device.

However, in the case of using the manufacturing method described with reference to FIGS. 47 to 48D, the process of forming the storage node pad XPS described with reference to FIGS. 20 to 23D may be omitted.

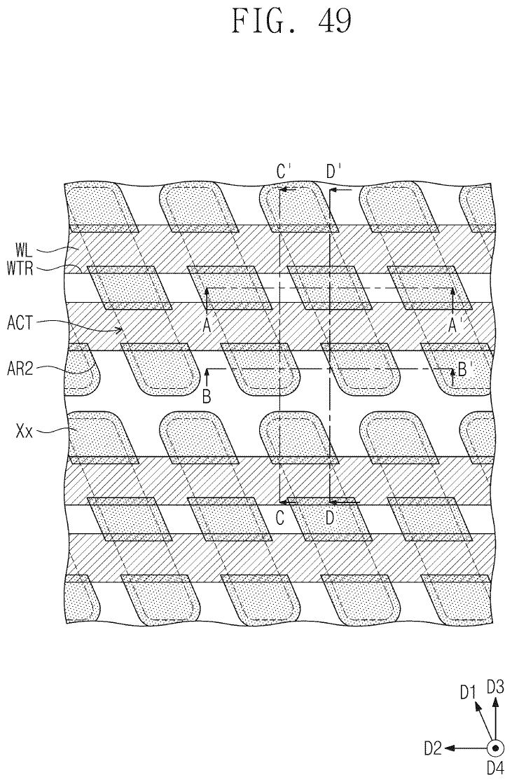

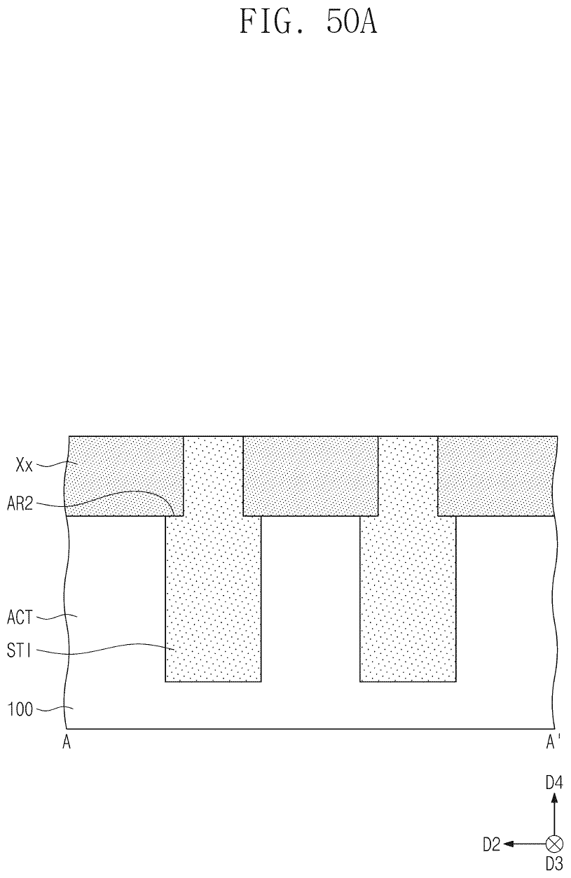

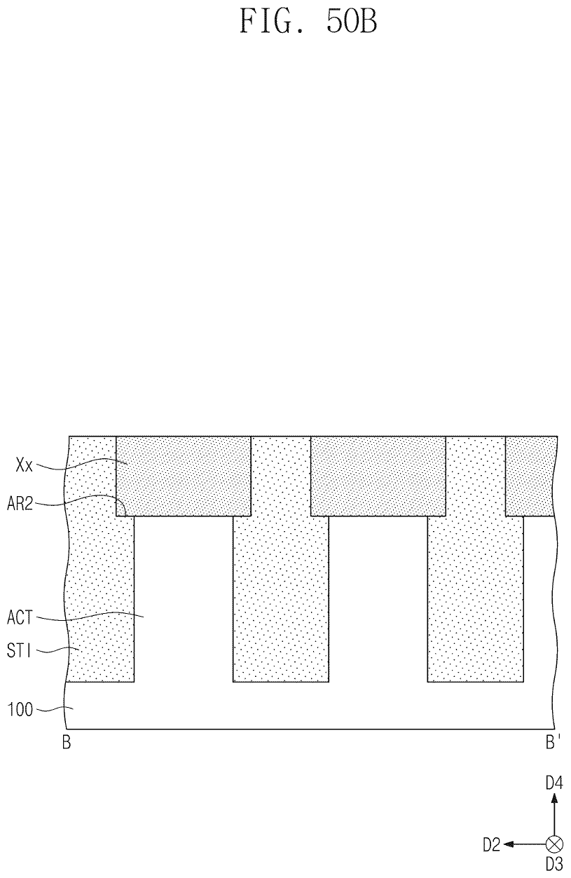

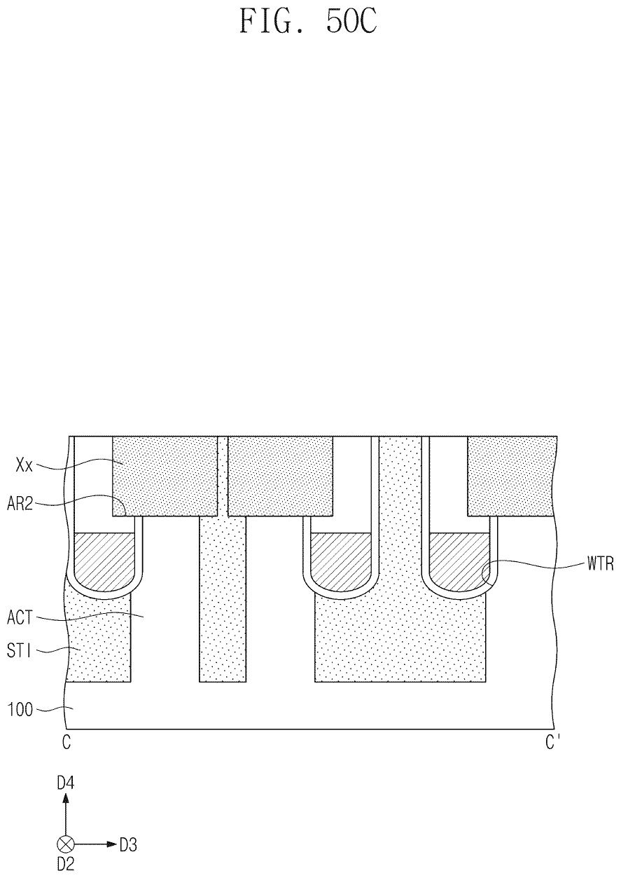

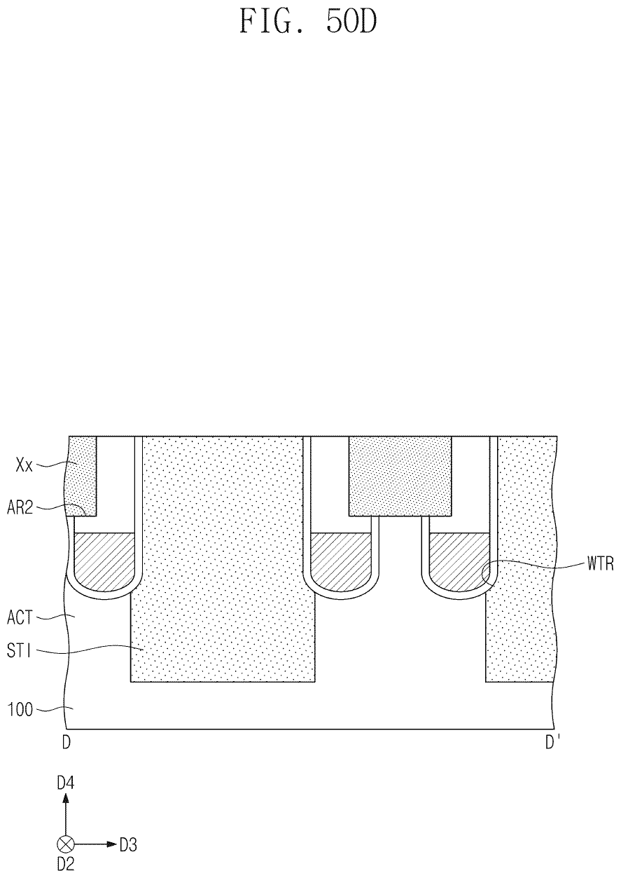

FIGS. 49 to 50D are views illustrating a method of manufacturing the semiconductor device of FIGS. 16 to 17D.

Referring to FIGS. 49 to 50D, after the formation of the word lines WL described with reference to FIGS. 18 to 19D, upper portions of the active patterns ACT may be removed to form second active recess regions AR2. The second active recess region AR2 may be a region surrounded by an upper portion of the device isolation pattern STI and an upper portion of the word line WL.

The removal of the upper portions of the active patterns ACT may be performed using an etch recipe having an etch selectivity with respect to the device isolation pattern STI and the word line WL. Thus, even though an exposure process for a patterning process is not performed, the upper portions of the active patterns ACT may be selectively removed. In addition, the upper portion of the device isolation pattern STI and the upper portion of the word line WL may remain.

Thereafter, each of the second active recess regions AR2 may be horizontally expanded. In this process, the upper portion of the device isolation pattern STI and the upper portion of the word line WL may be partially removed. The second active recess regions AR2 may expose top surfaces of the active patterns ACT. For example, the first and second edge portions EA1 and EA2 and the center portion CA of the active pattern ACT may be exposed by the second active recess regions AR2, respectively. Thereafter, lower pads Xx may be formed to fill the second active recess regions AR2, respectively.

Referring again to FIGS. 16 to 17D, the lower pads Xx may be recessed. Ohmic pads Xz and upper pads Xy may be formed in regions formed by the recessing of the lower pads Xx. Thus, the storage node pads XPS and the bit line node pads XPB may be formed. Thereafter, the semiconductor device described with reference to FIGS. 16 to 17D may be manufactured using the aforementioned method of manufacturing a semiconductor device.

However, in the case of using the manufacturing method described with reference to FIGS. 49 to 50D, the process of forming the storage node pad XPS described with reference to FIGS. 20 to 23D may be omitted.

According to the inventive concepts, the arrangement of the components in the semiconductor device may be simplified. As a result, difficulty of a patterning process, etc. of manufacturing the semiconductor device may be reduced to easily manufacture the semiconductor device. In addition, the components may be relatively simply arranged to improve the integration density of the semiconductor device.

Furthermore, the contact resistance between the storage node contact including the metal material and the edge portion of the active pattern including silicon may be reduced by the storage node pad. As a result, the electrical characteristics and reliability of the semiconductor device may be improved.

While various example embodiments of inventive concepts have been particularly shown and described, it will be understood by one of ordinary skill in the art that variations in form and detail may be made therein without departing from the spirit and scope of the attached claims. Furthermore, example embodiments are not necessarily mutually exclusive with one another. For example, some example embodiments may include one or more features described with reference to one or more figures, and may also include one or more other features described with reference to one or more other figures.

1. A semiconductor device comprising:
a first active pattern and a second active pattern extending in a first direction and arranged in a second direction intersecting the first direction, each of the first and second active patterns including a first edge portion and a second edge portion spaced apart from each other in the first direction;
a first storage node pad and a first storage node contact sequentially arranged on the first edge portion of the first active pattern; and
a second storage node pad and a second storage node contact sequentially arranged on the second edge portion of the second active pattern,
wherein each of the first and second storage node contacts includes a metal material.

2. The semiconductor device of claim 1, wherein each of the first and second storage node pads independently include at least one of silicon and a metal material.

3. The semiconductor device of claim 1, further comprising:
a fence pattern between the first and second storage node contacts,
wherein the fence pattern separates the first and second storage node contacts from each other in a third direction intersecting the first and second directions.

4. The semiconductor device of claim 3, wherein the fence pattern includes at least one of silicon oxide, silicon nitride, silicon oxycarbide, and silicon oxy-carbonitride.

5. (canceled)

6. The semiconductor device of claim 1, further comprising:
a first closed spacer surrounding the first storage node contact in a plan view; and
a second closed spacer surrounding the second storage node contact in a plan view.

7. The semiconductor device of claim 6, wherein each of the first and second closed spacers independently include at least one of silicon oxide, silicon nitride, silicon oxycarbide, and silicon oxy-carbonitride.

8. The semiconductor device of claim 6, wherein the first closed spacer comprises:
a first closed sub-spacer surrounding the first storage node contact in a plan view; and a second closed sub-spacer between the first storage node contact and the first closed sub-spacer, and
wherein the first closed sub-spacer and the second closed sub-spacer include different materials.

9. The semiconductor device of claim 1, further comprising:
a first bit line on the first active pattern extending in a third direction intersecting the first and second directions; and
a second bit line on the second active pattern extending in the third direction,
wherein the first storage node contact and the second storage node contact are between the first bit line and the second bit line.

10. The semiconductor device of claim 9, further comprising:
line spacers disposed between the first bit line and the first storage node contact and between the second bit line and the first storage node contact, respectively.

11. The semiconductor device of claim 9, further comprising:
a fence pattern between the first and second storage node contacts; and
sacrificial patterns disposed between the first bit line and the fence pattern and between the second bit line and the fence pattern, respectively.

12. (canceled)

13. The semiconductor device of claim 1, further comprising:
a third active pattern adjacent to the second active pattern in a third direction intersecting the first and second directions; and
a dummy word line extending in the second direction between the second active pattern and the third active pattern.

14. The semiconductor device of claim 1, wherein
each of the first active pattern and the second active pattern further includes a center portion between the respective first edge portion and the respective second edge portion, and the semiconductor device further comprises:
a bit line node pad on each of the center portions of the first active pattern and the second active pattern.

15. A semiconductor device comprising:
a first active pattern and a second active pattern extending in a first direction and arranged in a second direction intersecting the first direction, each of the first and second active patterns including a first edge portion and a second edge portion spaced apart from each other in the first direction;
a first storage node pad and a first storage node contact sequentially arranged on the first edge portion of the first active pattern;
a second storage node pad and a second storage node contact sequentially arranged on the second edge portion of the second active pattern;
a first closed spacer surrounding the first storage node contact in a plan view; and
a second closed spacer surrounding the second storage node contact in a plan view.

16. The semiconductor device of claim 15, wherein each of the first and second storage node contacts includes a metal material.

17. The semiconductor device of claim 15, wherein each of the first and second storage node pads independently include at least one of silicon and a metal material.

18. The semiconductor device of claim 15, wherein the first closed spacer comprises:
a first closed sub-spacer surrounding the first storage node contact; and
a second closed sub-spacer between the first storage node contact and the first closed sub-spacer, and
wherein the first closed sub-spacer and the second closed sub-spacer include different materials.

19. The semiconductor device of claim 15, further comprising:
a fence pattern between the first and second storage node contacts,
wherein the fence pattern is spaced apart from the first storage node contact by the first closed spacer and is spaced apart from the second storage node contact by the second closed spacer.

20. The semiconductor device of claim 15, further comprising:
a first bit line on the first active pattern and extending in a third direction intersecting the first and second directions; and
a line spacer extending from between the first bit line and the second storage node contact into between the first bit line and the first storage node contact.

21. A semiconductor device comprising:
a first active pattern and a second active pattern extending in a first direction and arranged in a second direction intersecting the first direction, each of the first and second active patterns including first and second edge portions spaced apart from each other in the first direction and a center portion between the first and second edge portions;
a pair of word lines extending in the second direction to intersect the first active pattern and the second active pattern;
a first storage node pad and a first storage node contact sequentially provided on the first edge portion of the first active pattern;
a second storage node pad and a second storage node contact sequentially provided on the second edge portion of the second active pattern;
a first bit line on the first active pattern and extending in a third direction intersecting the first and second directions;
a second bit line extending in the third direction on the second active pattern;
a fence pattern between the first storage node contact and the second storage node contact;
landing pads on the first storage node contact and the second storage node contact; and
data storage patterns on the landing pads, wherein
the first edge portion of the first active pattern and the first edge portion of the second active pattern are adjacent to each other in the second direction,
the first edge portion of the first active pattern and the second edge portion of the second active pattern are adjacent to each other in the third direction, and
each of the first and second storage node contacts includes a metal material.

22. The semiconductor device of claim 21, wherein each of the landing pads is shifted from a corresponding one of the first and second storage node contacts in the third direction or an opposite direction to the third direction.

23-28. (canceled)
